(19) United States
(12) Patent Application Publication
(10) Pub. No.: US 2026/0305177 A1
(43) Pub. Date: Oct. 1, 2026

(54) LEAD ZIRCONATE TITANATE (PZT) SOLUTION PHASE DIAGRAM AND CRYSTAL GROWTH NEAR THERMODYNAMIC EQUILIBRIUM

(71) Applicant: Quest Integrity USA, LLC, Stafford, TX (US)

(72) Inventors: Vincent Fratello, Bellevue, WA (US); Song Won Ko, Portland, OR (US)

(73) Assignee: Quest Integrity USA, LLC, Stafford, TX (US)

(21) Appl. No.: 19/480,405

(22) PCT Filed: May 10, 2024
(86) PCT No.: PCT/US2024/028945

§ 371 Date: Oct. 31, 2025

Related U.S. Application Data
(60) Provisional application No. 63/501,169, filed on May 10, 2023.

(51) Int. Cl. H10N 30/853; C30B 7/08; H10N 30/095

(52) U.S. Cl. CPC H10N 30/8554; C30B 7/08; H10N 30/095

(57) ABSTRACT

To grow a lead zirconate titanate (PZT) crystal from a system in thermodynamic equilibrium, thermodynamic equilibrium was established, which had not been done previously. Solvent phase diagrams were measured, and the results fit to a model that allows extrapolation to a variety of solvent systems and solute concentrations. Innovative phosphate solvents were developed. In an embodiment, the present disclosure provides methods for growing PZT single crystals from a single-phase solution near the thermodynamic equilibrium with a very low undercooling wherein the solution is in thermodynamic equilibrium with the growing crystal of composition PbZr_{X}Ti_{(1-X)}O₃ at a saturation temperature T_{S}. In an embodiment, the present disclosure provides methods for achieving a two-phase liquid-solid system in thermodynamic equilibrium wherein the solution is in equilibrium with solid PbZr_{X}Ti_{(1-X)}O₃ at a temperature T and methods to grow PbZr_{X}Ti₍₁₋ₓ₎O₃ single crystals of the desired composition X from such a system.

### CROSS-REFERENCE TO RELATED APPLICATION

This application claims the benefit of U.S. Provisional Patent Application No. 63/501,169, filed May 10, 2023, the contents of which is hereby incorporated by reference in its entirety.

### BACKGROUND

### Lead Zirconate Titanate

Lead zirconate titanate (PZT) of composition Pb(ZrxTi₁₋ₓ)O₃ is the dominant piezoelectric material in non-destructive evaluation (NDE) applications because of its high efficiency, high-power capability, good performance over a wide temperature range, and robustness. PZT is a perovskite solid solution between lead zirconate PbZrO₃ (PZ) and lead titanate PbTiO₃ (PT) with Pb²⁺ on the large twelve-coordinated cube-octahedral site and Zr⁴⁺ and Ti⁴⁺ on the smaller six-coordinated octahedral site. The crystal structure of lead titanate is tetragonal and that of lead zirconate is rhombohedral. The solid solutions of PZ-doped PT and PT-doped PZ have the structure of the host until the compositions approach the center of the phase diagram as is shown in FIG. 1. At the center of the phase diagram, these structures become unstable with monoclinic structures appearing (not plotted). This region is called the morphotropic phase boundary (MPB) and is conventionally stated to be centered at X=0.52 atoms per formula unit of Zr. Compositions in this vicinity are the ones of primary interest for NDE applications. The Zr fraction in atoms per formula unit on the octahedral site in the solid, Zr/(Zr+Ti), is commonly denoted as x or X in the literature and may also be given as Xs in this work to avoid ambiguity with XL=[ZrO₂]_{L}/([ZrO₂]_{L}+[TiO₂]_{L}), the fraction of octahedral species in the liquid. This may refer variously to the fraction of Zr relative to Ti, the fraction of ZrO₂ relative to TiO₂, or the fraction of PZ relative to PT without distinction. This notation is not universal with some authors referring to the Ti fraction as x and the Zr fraction as 1-x as is reflected in their paper titles. For the present disclosure, those values were converted to the present notation where X is the fraction of Zr.

PZT is non-congruent, meaning it cannot be grown from a melt of the same composition. Attempts to grow this material near the MPB by flux/solution growth have been made for over sixty years, but to date only small crystals of inconsistent composition have been achieved by non-scalable methods owing in part to the constraints of three-dimensional growth from a point nucleus, the difference in solubility between TiO₂ and ZrO₂, and unstable growth conditions from high solvent evaporation, melt supercooling, and slow-cooling methods.

To grow PZT crystals, it is first important to understand the solution phase diagram of PZT.

### Historical Work

Phase Diagrams of PbO—ZrO₂, PbO—TiO₂, and PbO—ZrO₂—TiO₂

Per the phase diagram in FIG. 2A from Fushimi and Ikeda, zirconium oxide and lead oxide form a non-congruently melting compound lead zirconate PbZrO₃ (PZ) from an off-stoichiometry high temperature solution with a stability range from a solution composition range of 1.3% ZrO₂ at 956° C. to 6.5% ZrO₂ at 1570° C.

In contrast, per FIG. 2B, lead oxide and titanium oxide form lead titanate PbTiO₃ (PT), a congruently melting compound with continuous TiO₂ solubility in a solution with PbO up to a concentration of 50% TiO₂ (1294° C.).

Fushimi and Ikeda drew a straight line between the two saturation concentrations and estimated the distribution coefficient to get hypothetical phase diagram sections as in FIGS. 3A-3C.

### High Temperature Solution and Flux Growth of Pzt

High Temperature Solution (HTS) growth of PZT crystals has been attempted previously with various solvents.

So called “self-fluxes” where lead oxide is both part of the solvent and part of the solute, such as with an excess of lead oxide (PbO or Pb₃O₄), a PbO—B₂O₃ mixture with and without additional constituent(s), and a mixture of PbO with other constituents.

Other examples include halide solvents, usually in combination with PbO. PbF₂ has a higher vapor pressure than PbO and higher solubility of ZrO₂, which moves the eutectic closer to the center of the phase diagram resulting in more phase separation. PbCl₂ has the highest vapor pressure of the lead-based solvents. KF dissociates and reacts with PbO to form PbF₂ with the problems listed above.

PbMoO₄ as a solvent resulted in phase separation of the PZT.

Pb₃(PO₄)₂ (lead orthophosphate) was previously used as a low concentration additive only and seemed to promote better crystals.

These studies included specific techniques of slow cooling, localized cooling, solvent evaporation, and top-seeded solution growth, all of which utilize high solubility of PZT for success. The solutions were initially equilibrated at a higher temperature to put all the constituents into solution. Commonly the Zr/Ti ratio in the melt is controlled by varying the starting Zr/Ti ratio at a constant total Zr+Ti concentration, which involves decreasing the Ti concentration as the Zr concentration increases. Many experiments started with equal fractions of Zr and Ti in the melt, which the present disclosure proves incorrect to achieve crystals with near equal fractions at the MPB in thermodynamic equilibrium. TABLE I summarizes the HTS solvents and methods that have been used to date.

TABLE I
Growth parameters of HTS PZT crystal growth.

| | | | | | X_{L} | X | |
|---|---|---|---|---|---|---|---|
| Solvent | Method | T(start) | T(end) | C. | (melt) | (crystal) | Reference |
| PbO (excess) | Phase | 1100° C. | Const. | Various | Various | Zr rich | Fushimi [1] |
| | diagram | 1200° C. | | | | | |
| | studies | 1300° C. | | | | | |
| PbO (excess) | Slow cool | 1170° C. | 950° C. | 0.25 | FIG. 4 | FIG. 4 | Clarke [2] |
| PbO (excess) | Slow cool | 1170° C. | 950° C. | 0.15 | 0.4 | 0.06 | Hatanaka [3] |
| PbO—B₂O₃ | TSSG | 1050° C. | 950° C. | 0.14-0.17 | 0.4 in | 0.2-0.65 | Xie [4] |
| (4:1 mol.) | slow cool | | | | nutrient | | |
| | | | | | pellets | | |
| PbO—PbF₂ | Slow cool | 1200° C. | 800° C. | 0.15 | FIG. 5A | FIG. 5A | Fushimi [5] |
| (50:50 start | | | | | | | |
| 60:40 end) | | | | | | | |
| KF—PbF₂ | Slow cool | 1200° C. | 800° C. | 0.15 | FIG. 5B | FIG. 5B | Fushimi [5] |
| (50:50 start | | | | | | | |
| 70:30 end) | | | | | | | |
| KF—PbF₂ | Slow cool | 1150° C. | 950° C. | 0.10 | Various | 0-0.4 | Fushimi [6] |
| | | | | | | and 0.85 | |

[1] S. Fushimi and T. Ikeda, “Phase Equilibrium in the System PbO—TiO₂—ZrO₂.” J. Am. Ceram. Soc. 50: 119 (1967).
[2] R. Clarke and R. W. Whatmore, “The Growth and Characterization of PbZrₓTi₁₋ₓO₃ Single Crystals,” J. Cryst. Growth 33: 29 (1976).
[3] T. Hatanaka and H. Hasegawa, “Observation of Domain Structures in Tetragonal Pb(ZrₓTi₁₋ₓ)O₃ Single Crystals by Chemical Etching Method,” Jpn. J. App. Phys. 31: 3245 (1992).
[4] Y. Xie, “Synthesis and Characterization of Piezo-ferroelectric Lead Zirconate-Titanate (PZT) Single Crystals and Related Ternary Ceramics,” Ph.D. thesis, Simon Fraser University, 2013.
[5] S. Fushimi and T. Ikeda, “Single Crystals of Lead Zirconate Titanate Solid Solutions,” Japan. J. Appl. Phys. 3: 171 (1964).
[6] S. Fushimi and T. Ikeda, “Optical Study of Lead Zirconate-Titanate,” J. Phys. Soc. Japan 20 (1965) 2007.

Some authors, e.g., Lazar et al. (I. Lazar, R. W. Whatmore, A. Majchrowski, A. M. Glazer, D. Kajewski, J. Koperski, A. Soszynski, J. Piecha, B. Loska, and K. Roleder, “Ultrahigh Piezoelectric Strains in PbZr₁₋ₓTixO₃ Single Crystals with Controlled Ti Content Close to the Tricritical Point,” Materials 2022, 15, 6708 and references therein), have grown PZT with X=0.87-1.0 for purposes of investigating the tricritical point in that composition range. It will be understood by those knowledgeable in the art, that this is simply growing PZ with a small titanium doping and is in no way similar or relevant to trying to grow PZT near the morphotropic phase boundary as will be seen in FIG. 4B and FIG. 5. A comprehensive list of these efforts is given in Lazar's paper and Perez (J. A. Pérez de la Torre, “Obtaining and characterization of single crystals and ceramics of PZT,” Ph.D. thesis, Universidade de Aveiro, Departamento de Engenharia Cerâmica e do Vidro (2009)).

Other authors have used a technique called flux growth (TABLE II), which differs from solution growth in that the constituents are not fully dissolved. The mixture is more a slush or slurry than a fully dissolved solution. Because these are often covered melts, the exact nature of the mixture at the growth temperature is not visible or recorded by the authors. In the flux method, crystal growth does not occur by nucleation and growth, but rather by transport of various nutrients between particulates that results in growth of larger crystallites at the expense of smaller ones. PbO—KF—PbCl₂ and other halide fluxes have been used for this application but have very high vapor pressures at the growth temperature and as much as 2/3 of the flux may evaporate during the growth run. Although crystals near the MPB were achieved, this technique is only capable of achieving a mass of many small crystals. It should be noted that some authors use the term flux interchangeably with solvent, as can be seen in their titles, but the present disclosure makes a distinction.

TABLE II
Growth parameters of flux PZT crystal growth.

| | | | | | X_{L} | X | |
|---|---|---|---|---|---|---|---|
| Solvent | Method | Tₛₜₐᵣₜ | T_{end} | C | (melt) | (crystal) | Reference |
| PbO—KF—PbCl₂—B₂O₃ | Slow cool flux | 1150° C. | 950° C. | | | 0.49 and 0.55 | Perez [7.8] |
| (KF)_{0.4}(PbF₂)_{0.6} | Slow cool flux | Var. | Var. | Var. | 0.5 | 0.26 | Tsuzuki [9] |
| (NaF)_{1/3}(PbF₂)_{2/3} | Slow cool flux | Var. | Var. | Var. | 0.5 | 0.4 | Tsuzuki [9] |
| (KF)_{0.30}(PbF₂)_{0.66} | Slow cool flux | 1115° C. | 800° C. | 0.15 | 0.5 | 0.45 | Tsuzuki [10] |
| (Pb₃(PO₄)₂)_{0.04} | covered | | | | | | |
| PbO-KF-PbCl₂ (or | Slow cool flux | 1000° C. | 900° C. | | | 0.52 with | Fujii [11] |
| PbF₂) | | | | | | ZrO₂ crystals | |
| PbO-B₂O₃ 15:1 | Isothermal | 1017- | Const. | 0.1 | | 0.65-0.93 + | Eknadiosiants [12] |
| | | 967° C. | | | | PbTiO₃ | |
| (PbO)_{0.4}(PbMoO₄)_{0.6} | Slow cool | Var. | Var. | Var. | 0.5 | 0.28 | Tsuzuki [9] |

[7] J. A. Pérez de la Torre, “Obtaining and characterization of single crystals and ceramics of PZT.” Ph.D. thesis, Universidade de Aveiro, Departamento de Engenharia Ceramica e do Vidro (2009).
[8] J. A. Perez, M. R. Soares, P. Q. Mantas, H. Amorin, M. E. V. Costa and A. M. R. Senos, “Growth of lead zirconate titanate single crystals by the high temperature solution method,” Mat. Sci. Forum 514-516 (2006) 284.
[9] K. Tsuzuki, et al., “Growth of Pb(Zr—Ti)O₃ Single Crystal by Flux Method,” Japan. J. Appl. Phys. 7 (1968) 953.
[10] K. Tsuzuki, et al., “The Growth of Ferroelectric Pb(ZrₓTi₁₋ₓ)O₃ Single Crystals,” Japan. J. Appl. Phys. 12 (1973) 1500.
[11] S. Fujii, Y. Sugie, Y. Takahashi and H. Fujiwara, “Growth of PZT crystal by using PbO—PbF—PbCl₂ flux,” J. Ceram. Soc. Jpn. 99 (1991) 507.
[12] E. I. Eknadiosiants, V. Z. Borodin, V. G. Smotrakov, V. V. Eremkin and A. N. Pinskaya, “Domain Structure of Rhombohedral PbTiₓZr₁₋ₓO₃ Crystals,” Ferroelectrics 111 (1990) 283.

Clarke and Whatmore varied the [TiO₂]₀ and [ZrO₂]₀ concentrations in the initial powder charge in a PbO solvent with varying starting octahedral component ratios X₀=[ZrO₂]₀/([TiO₂]₀+[ZrO₂]₀) having misinterpreted the phase diagram proposed by Fushimi and Ikeda (FIGS. 3A-3C). These are given with the subscript 0 here to denote the starting charge composition because it is unlikely the charge is fully melted as they suggest. They stated that at 1150° C., the ZrO₂ single solubility alone is 1% in lead oxide (from the phase diagram of Fushimi and Ikeda in FIG. 1 it is estimated to be more like 1.8%). The TiO₂ single solubility alone is 25% at 1150° C., and they estimated that Zr_{X0}Ti_{(1-X0)}O₂ has a solubility concentration of C=25-24X₀% for various X₀ zirconia fractions in the melt. This gives melt concentrations of [ZrO₂]₀=0.25X₀-0.24X₀² and [TiO₂]₀=0.25-0.49X₀+0.24X₀². The erroneous implication of this formulation is that the addition of TiO₂ increases the solubility of ZrO₂ and by a very large amount with [ZrO₂]₀ peaking at 0.065, which is more than six times the solubility of ZrO₂ with no TiO₂ present. These concentrations are shown in TABLE III and FIG. 4A.

TABLE III
Melt design of [PbO]_{(1-C)}[ZrO₂]_{CX0}[TiO₂]_{C(1-X0)} melts from
Clarke and Whatmore. with X in the resulting
PbZrXₓTi_{1-X}O₃ crystals. (R. Clarke and R. W. Whatmore,
“The Growth and Characterization of PbZrₓTi₁₋ₓO₃
Single Crystals,” J. Cryst. Growth 33:29 (1976))

| X₀ | [ZrO₂]₀ | [TiO₂]₀ | C | X |
|---|---|---|---|---|
| 0.00 | 0.000 | 0.250 | 0.250 | 0.00 |
| 0.10 | 0.023 | 0.203 | 0.226 | 0.03 |
| 0.13 | 0.028 | 0.193 | 0.220 | 0.13 |
| 0.15 | 0.032 | 0.182 | 0.214 | 0.24 |
| 0.20 | 0.040 | 0.162 | 0.202 | 0.68 |
| 0.30 | 0.053 | 0.125 | 0.178 | 0.83 |
| 0.40 | 0.062 | 0.092 | 0.154 | 0.86 |
| 0.50 | 0.065 | 0.065 | 0.130 | 0.91 |
| 0.53 | 0.065 | 0.058 | 0.123 | 0.93 |
| 0.60 | 0.064 | 0.042 | 0.106 | 0.95 |
| 0.73 | 0.055 | 0.021 | 0.076 | 0.97 |
| 0.85 | 0.039 | 0.007 | 0.046 | 0.99 |
| 1.00 | 0.010 | 0.000 | 0.010 | 1.00 |

FIG. 4B shows the Clarke and Whatmore data for Zr fraction in the crystal X versus X₀ in starting charge. An initial interpretation could be a miscibility gap. Growth of the MPB composition X=0.52 appears almost impossible owing to the large gap.

Fluoride solvents such as PbF₂ and KF are different because the solubility of ZrO₂ in fluorides is much higher (A. B. Chase and J. A. Osmer, “Growth of Crystals of ZrO₂ and HfO₂ from PbF₂,” American Mineralogist 51 (1966) 1808), but the solubility of TiO₂ is similar to that in PbO. The fluoride results in FIGS. 5A and 5B show the resulting crystal compositions as a function of the starting lead zirconate fraction in two fluoride solvents. There appears to be a PT-PZ miscibility gap in the center of the crystal composition range.

A plausible phase diagram for the fluoride solvents might look like FIG. 6 with constant PZT concentration of 15 mole % and the sum C=[Ti]_{L}+[Zr]_{L} constant. Because of the similar solubilities of TiO₂ and ZrO₂ in fluoride solvents, this is reasonable and consistent with the result that at an equimolar melt concentration, phase separation occurs.

None of these results reach the level of being a viable process for PZT crystal growth for at least the following reasons. The resultant crystals were typically one to a few millimeters on a side and often thin plates because of the inherent limitations of these crystal growth techniques. High temperatures result in evaporation of PbO, PbF₂, PbCl₂, KF, and NaF among other species. High evaporation rates of one or more species gives a continuously varying chemical environment and unstable growth conditions. Slow-cooling over a wide temperature range, typically 70-220° C., inherently gives a wide variety of growth conditions that are undoubtedly the source of compositional variations. Those authors who do not report compositional variations may only be reporting on a limited sample of crystals or an average value yielded by the characterization method (e.g., x-ray powder diffraction). None of the authors have measured the solubility of PZ and PT, or alternatively ZrO₂ and TiO₂, under the growth conditions. Therefore, it is unknown at what saturation (liquidus) temperature any given melt composition may produce crystals. In fact, it is likely that in most instances not all the zirconia or PZ is dissolved in the melt and any crystal growth may be occurring by the flux method rather than true HTS growth. A diversity of distribution coefficients is seen both above and below unity depending on the choice of solvent, ZrO₂ fraction X relative to TiO₂ in the melt, and other factors that are not properly recorded including actual growth temperature. In some cases, phase separation into Zr-rich and Ti-rich phases is seen. Rane and Navrotsky observed a positive heat of mixing for PZT in a 3Na₂O-4MoO₄ solution consistent with phase separation (M. V. Rane and A. Navrotsky, “Enthalpies of Formation of Lead Zirconate Titanate (PZT) Solid Solutions,” J. Solid State Chem. 161 (2001) 402). However, phase separation is not seen in solid phase sintering.

Thin PZT films have been formed on substrates by a variety of techniques including sputtering, pulsed laser deposition, sol gel technique and liquid phase epitaxy from a wholly liquid high temperature solution (V. J. Fratello U.S. Pat. No. 9,738,990 B2, Aug. 22, 2017). These have been limited in quality and thickness to a few microns or tens of microns owing to the lattice parameter mismatch with the available substrate materials. Because of this mismatch and attendant strain, these films are not at thermodynamic equilibrium.

Therefore, an innovative process for crystal growth is needed.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, the present disclosure provides a system comprising: a single-phase high temperature solution comprising concentrations of free lead oxide [PbO]_{free}, zirconium oxide [ZrO₂], titanium oxide [TiO₂] and dissolved boron oxide complexed with additional oxygen [BO₃³⁺] in thermodynamic equilibrium having a saturation temperature Ts of crystal lead zirconate titanate (PZT) PbZr_{X}Ti₍₁₋ₓ₎O₃ wherein TS is according to:

$${T}_{S} = A - {B [ PbO ]}_{free} + ( C [ {ZrO}_{2} ] + D [ {TiO}_{2} ] ) ( 1 - E [ {BO}_{3}^{3 +} ] )$$

$$wherein$$

$$A = 99 \; 7 \pm 50 ° C . , B = 360 \pm 100 ° C . , C = 29100 \pm 5000 ° C . ,$$

$$D = 14 \; 23 \pm 500 ° C . and E = 3.6 \pm 1 .$$

In an embodiment, the system has a ratio X_{L}=[ZrO₂]/([TiO₂]+[ZrO₂]) in the high-temperature solution in a range of 0.07 and 0.15.

In an embodiment the system has a cation fraction [BO₃³⁺] in a range of 0 and 0.2.

In another aspect, the present disclosure provides a system comprising a solid comprising lead zirconate titanate (PZT) PbZr_{X}Ti_{(1-X)}O₃ in thermodynamic equilibrium with a high-temperature solution comprising lead oxide, zirconium oxide (ZrO₂), and titanium oxide (TiO₂).

In an embodiment, the high-temperature solution is in a state of saturation at a saturation temperature TS and an average temperature of the high-temperature solution is constant to within ±3° C.

In an embodiment, the system has X in the solid in a range of 0.30 and 0.65.

In an embodiment, the system has a ratio X_{L}=[Zr]_{L}/([Ti]_{L}+[Zr]_{L}) in the high-temperature solution in a range of 0.06 and 0.15.

In an embodiment, the high-temperature solution does not comprise a fluoride or chloride constituent,

In an embodiment, the system comprises lead oxide in a form selected from PbO and Pb₃O₄.

In an embodiment, the system comprises a solvent composition of the high temperature solution comprising lead oxide and a Lewis acid component selected from the group consisting of B₂O₃, P₂O₅, V₂O₅, MoO₃, or a combination thereof.

In an embodiment, the system comprises a solvent composition of the high temperature solution comprising lead oxide and a Lewis base component selected from the group consisting of Li₂O, Na₂O, K₂O, or a combination thereof.

In an embodiment, the system comprises a solvent composition selected from PbO, Pb₃O₄, PbO—B₂O₃, Pb₃O₄—B₂O₃, PbO—Li₂O, Pb₃O₄—Li₂O, PbO—Li₂O—B₂O₃, Pb₃O₄—Li₂O—B₂O₃, PbO—Li₂O—MoO₃, Pb₃O₄—Li₂O—MoO₃, PbO—Pb₂P₂O₇, and PbO—PbLiPO₄.

In an embodiment, the system comprises a solvent composition comprising an ionic solution.

In an embodiment, the system comprises a saturation temperature TS in a range of about 950° C. to about 1150° C.

In an embodiment, the system is contained in an inert crucible with low solubility in the high-temperature solution at the saturation temperature Ts.

In an embodiment, the system is contained in a crucible comprising platinum, a platinum alloy, or a dispersion hardened platinum alloy.

In an embodiment, the system comprises a PbZr_{X}Ti₍₁₋ₓ₎O₃ solid, wherein the PbZr_{X}Ti₍₁₋ₓ₎O₃ comprises a higher density than the high-temperature solution.

In an embodiment, for any given solvent and constant solidus composition X, the saturation temperature T_{S} is a function of [TiO₂]_{L}.

In an embodiment, for any given solvent and constant saturation temperature Ts, the solidus composition X is a function of [TiO₂]_{L}.

In an embodiment, a single-phase high temperature solution system comprises concentrations of free lead oxide [PbO]_{free}, zirconium oxide [ZrO₂], titanium oxide [TiO₂] and dissolved boron oxide complexed with additional oxygen [BO₃³⁺] is brought to thermodynamic equilibrium by mixing at a temperature above the saturation temperature T_{S} of lead zirconate titanate (PZT) PbZr_{X}Ti₍₁₋ₓ₎O₃ and cooling to the saturation temperature.

In an embodiment, a two-phase system is brought to thermodynamic equilibration at the saturation temperature T_{S} by the following steps:
a. mixing the powders comprising the composition of the two-phase system to form a charge wherein the composition comprises a sum of the solid composition comprising an amount of excess PbZr_{X}Ti₍₁₋ₓ₎O₃ components [ZrO₂]s, [TiO₂]s, and [PbO]ₛ in proportions to form a solid of composition PbZr_{X}Ti₍₁₋ₓ₎O₃ and the liquid composition that is in thermodynamic equilibrium with the solid composition at a temperature T_{S};
b. heating the charge in a crucible in a vertical furnace to a temperature greater than the saturation temperature of the entire charge including the excess PZT;
c. mixing the fully melted single-phase solution system for a time sufficient to achieve thermodynamic equilibrium with all components in solution; and
d. cooling with stirring to an average melt temperature of T_{S} to allow precipitation of the excess PZT to provide a melted two-phase system.

In an embodiment a two-phase system is brought to thermodynamic equilibration at the saturation temperature T_{S} by the following steps:
a. mixing the powders comprising the composition of the two-phase system to form a charge wherein the composition comprises a sum of the solid composition comprising an amount of excess PbZr_{X}Ti₍₁₋ₓ₎O₃ components [ZrO₂]s, [TiO₂]s, and [PbO]ₛ in proportions to form a solid of composition PbZr_{X}Ti₍₁₋ₓ₎O₃ and the liquid composition that is in thermodynamic equilibrium with the solid composition at a temperature T_{S};
b. heating the charge in a crucible in a vertical furnace to an average melt temperature of T_{S} to provide a melted two-phase system; and
c. mixing the melted two-phase system for a time sufficient to achieve thermodynamic equilibrium.

In another aspect, the present disclosure provides a method growing a PbZr_{X}Ti_{(1-X)}O₃ crystal by top-seeded solution growth with supercooling and slow-cooling, the method comprising:
a. achieving thermodynamic equilibrium in a single-phase high temperature solution system by mixing at a temperature above the saturation temperature T_{S} with lead zirconate titanate (PZT) PbZr_{X}Ti_{(1-X)}O₃ and cooling to the saturation temperature T_{S};
b. establishing an undercooling in the single-phase high-temperature solution by lowering the temperature below the saturation temperature T_{S};
c. introducing a seed in the top of a liquid of the single-phase, high-temperature solution;
d. growing a crystal on the seed by slow-cooling and pulling for a period to provide a grown crystal, lowering the temperature slowly during a growing period; and
e. lifting the grown crystal above the top of the liquid.

In an embodiment, top-seeded solution growth with supercooling and slow-cooling is conducted at less than or equal to 4° C. undercooling.

In an embodiment, top-seeded solution growth with supercooling and slow-cooling is conducted with the ramp less than or equal to 2° C./day.

In an embodiment, top-seeded solution growth with supercooling and slow-cooling is conducted with a total temperature drop less than or equal to 20° C.

In another aspect, the present disclosure provides a method of growing a PbZr_{X}Ti₍₁₋ₓ₎O₃ crystal from the system by isothermal liquid phase transport in a temperature gradient in the high-temperature solution. In an embodiment, the method comprises:
a. mixing powders comprising the composition of the two-phase system to form a charge, wherein the composition comprises a sum of the solid comprising an amount of excess PbZr_{X}Ti₍₁₋ₓ₎O₃ components [ZrO₂]s, [TiO₂]s, and [PbO]ₛ in proportions to form a solid of composition PbZr_{X}Ti_{(1-X)}O₃ and a liquid composition that is in thermodynamic equilibrium with the solid at a temperature T_{S};
b. bringing the charge to equilibrium at T_{S} by:
   i. heating the charge in a crucible in a vertical furnace to a temperature greater than the saturation temperature T_{S} of the entire charge including the excess PZT; mixing the fully melted system for a time sufficient to achieve thermodynamic equilibrium with all components in solution; and cooling with stirring to an average melt temperature of T_{S} to allow precipitation of the excess PZT to provide a melted two-phase system; or
   ii. heating the charge in a crucible in a vertical furnace to an average melt temperature of T_{S} to provide a melted two-phase system; and mixing the melted two-phase system for a time sufficient to achieve thermodynamic equilibrium;
c. establishing a temperature gradient between the system and a growing region;
d. introducing a seed in the growing region;
e. holding the average temperature constant to within ±3° C. during a growing period to provide a grown crystal; and
f. separating the grown crystal from the liquid,

In another aspect, the present disclosure provides a method of growing a PbZr_{X}Ti₍₁₋ₓ₎O₃ crystal from the system by isothermal top-seeded solution growth. In an embodiment, the method comprises:
a. mixing powders comprising the composition of the two-phase system to form a charge, wherein the composition comprises a sum of the solid comprising an amount of excess PbZr_{X}Ti₍₁₋ₓ₎O₃ components [ZrO₂]s, [TiO₂]s, and [PbO]ₛ in proportions to form a solid of composition PbZr_{X}Ti₍₁₋ₓ₎O₃ and a liquid that is in thermodynamic equilibrium with the solid at a temperature T_{S};
b. bringing the charge to equilibrium at T_{S} by:
   i. heating the charge in a crucible in a vertical furnace to a temperature greater than the saturation temperature T_{S} of the entire charge including the excess PZT; mixing the fully melted system for a time sufficient to achieve thermodynamic equilibrium with all components in solution; and cooling with stirring to an average melt temperature of T_{S} to allow precipitation of the excess PZT to provide a melted two-phase system; or
   ii. heating the charge in a crucible in a vertical furnace to an average melt temperature of T_{S} to provide a melted two-phase system; and mixing the melted system for a time sufficient to achieve thermodynamic equilibrium;
c. establishing a temperature gradient between a bottom and a top of the system;
d. introducing a seed in the top of a liquid of the system;
e. growing a crystal on the seed by isothermal liquid phase transport from nutrient material at the bottom of the two-phase mixture to the seed;
f. growing a crystal at a top of the liquid for a period to provide a grown crystal, holding an average temperature of the liquid constant to within ±3° C. during a growing period; and
g. lifting the grown crystal above the top of the liquid.

In another aspect, the present disclosure provides a method of growing a PbZr_{X}Ti₍₁₋ₓ₎O₃ crystal from the system by isothermal liquid phase transport in a temperature gradient in the high-temperature solution using a cold finger. In an embodiment, the method comprises:
a. attaching a seed on a bottom of a platinum crucible over the cold finger;
b. mixing powders comprising the composition of the two-phase system to form a charge, wherein the composition comprises a sum of the solid comprising an amount of excess PbZr_{X}Ti₍₁₋ₓ₎O₃ components [ZrO₂]s, [TiO₂]s, and [PbO]ₛ in proportions to form a solid of composition PbZr_{X}Ti₍₁₋ₓ₎O₃ and the liquid that is in thermodynamic equilibrium with the solid composition at a temperature T_{S};
c. bringing the charge to equilibrium at T_{S} by:
   i. heating the charge in a crucible in a vertical furnace to a temperature greater than the saturation temperature T_{S} of the entire charge including the excess PZT; mixing the fully melted system for a time sufficient to achieve thermodynamic equilibrium with all components in solution; and cooling with stirring to an average melt temperature of T_{S} to allow precipitation of the excess PZT to provide a melted two-phase system; or
   ii. heating the charge in a crucible in a vertical furnace to an average melt temperature of T_{S} to provide a melted two-phase system; and mixing the melted two-phase system for a time sufficient to achieve thermodynamic equilibrium;
d. establishing a temperature gradient between two regions of the two-phase system by activating the cold finger;
e. holding an average temperature of the system constant to within +3° C. during a growing period;
f. growing a crystal on the seed by isothermal liquid phase transport from nutrient material at a top of the crucible to the seed at the bottom of the liquid for a period; and
g. inverting the platinum crucible to decant the liquid and remaining nutrient into another crucible.

In an embodiment, the present disclosure provides a method of growing a PbZr_{X}Ti₍₁₋ₓ₎O₃ crystal, wherein a temperature gradient between a nutrient solid phase and a growing crystal is less than 10° C.

In an embodiment, the present disclosure provides a method of growing a PbZr_{X}Ti₍₁₋ₓ₎O₃ crystal, wherein the furnace comprises baffles configured to restrict flow of lead oxide vapor and control the temperature gradient.

In an embodiment, the present disclosure provides a method of growing a PbZr_{X}Ti_{(1-X)}O₃ crystal, wherein the crucible comprises an aspect ratio of height: diameter greater than 1.25.

In another aspect, the present disclosure provides a method of growing a PbZr_{X}Ti₍₁₋ₓ₎O₃ crystal from the system by the traveling heater method. In an embodiment, the method comprises:
a. mixing powdered constituents comprising concentrations of free lead oxide [PbO]_{free}, zirconium oxide [ZrO₂], titanium oxide [TiO₂] and boron oxide [B₂O₃] for a high temperature solution in thermodynamic equilibrium having a saturation temperature T_{S} with lead zirconate titanate (PZT) PbZr_{X}Ti₍₁₋ₓ₎O₃ wherein T_{S} is according to T_{S}=A−B[PbO]_{free}+(C[ZrO₂]+D[TiO₂]) (1−E[BO₃³⁺]) wherein A=997±50° C., B=360±100° C., C=29100±5000° C., D=1423±500° C. and E=3.6±1 and [BO₃³⁺] is boron oxide complexed with additional oxygen;
b. In an embodiment, the system has a ratio XL=[ZrO₂]/([TiO₂]±[ZrO₂]) in the high-temperature solution in a range of 0.06 and 0.15;
c. compressing the powdered constituents into a charge comprising a diameter of a crucible;
d. providing a nutrient charge of composition PbZr_{X}Ti₍₁₋ₓ₎O₃ in the diameter of the crucible by ceramic methods or mixing and pressing;
e. placing a seed on a bottom of the crucible;
f. placing the powdered solution constituents on top of the seed;
g. placing nutrient constituents on top of the solution constituents;
h. placing the crucible in a vertical furnace such that a solution zone is at an average temperature of T_{S} and there is a positive temperature gradient between the seed and the nutrient;
i. moving the crucible and/or the furnace to move a hot zone upward at the crystal growth rate; and
j. when the solvent zone reaches the top, slowly cooling the system to room temperature.

In an aspect, the present disclosure provides a method of growing a PbZr_{X}Ti_{(1-X)}O₃ crystal by the traveling solvent floating zone method with no crucible. In an embodiment, the method comprises:
a. assembling a charge comprising in consecutive layers
   i. a PbZr_{X}Ti₍₁₋ₓ₎O₃ seed,
   ii. a solution mixture comprising powdered constituents comprising concentrations of free lead oxide [PbO]_{free}, zirconium oxide [ZrO₂], titanium oxide [TiO₂] and boron oxide [B₂O₃] for a high temperature solution in thermodynamic equilibrium having a saturation temperature T_{S} of lead zirconate titanate (PZT) PbZr_{X}Ti₍₁₋ₓ₎O₃ wherein T_{S} is according to T_{S}=A−B[PbO] free+(C[ZrO₂]+D[TiO₂]) (1−E[B₂O₃]) wherein A=997±50° C., B=360±100° C., C=29100±5000° C., D=1423±500° C. and E=3.6±1, and
   iii. PbZr_{X}Ti_{(1-X)}O₃ nutrient.
b. pressing the charge to form a singular body;
c. placing the charge in a floating zone furnace;
d. pressurizing a chamber of the floating zone furnace;
e. applying, with the floating zone furnace, optical heating such that the solution is at an average temperature of T_{S} and there is a positive temperature gradient between the seed and the nutrient;
f. moving the charge or the heating to move a hot zone at the crystal growth rate to grow the crystal;
g. when the solvent zone reaches a limit of the system, slowly reducing the heating to cool the system to room temperature; and
h. cutting the crystal from a remaining portion of the charge.

In an embodiment, the present disclosure provides a method of growing a PbZr_{X}Ti₍₁₋ₓ₎O₃ crystal, wherein the charge is compressed after mixing.

In an embodiment, the present disclosure provides a method of growing a PbZr_{X}Ti_{(1-X)}O₃ crystal, wherein the seed comprises platinum, a platinum alloy, gold, a gold alloy, a perovskite comprising an average lattice parameter of 4.07±0.01 at room temperature, or PbZr_{X}Ti₍₁₋ₓ₎O₃ wherein X is the same as in claim 1 within ±0.1.

In an embodiment, the present disclosure provides a method of growing a PbZr_{X}Ti_{(1-X)}O₃ crystal, wherein the seed comprises PbZr_{X}Ti₍₁₋ₓ₎O₃, wherein X in the seed is the same as the value X of the crystal to be grown to within ±0.1, and wherein the seed comprises a <100> orientation parallel to the surface of the liquid.

In an embodiment, the present disclosure provides a method of growing a PbZr_{X}Ti_{(1-X)}O₃ crystal, wherein the crystal is grown in an atmosphere comprising air, oxygen, carbon dioxide, mixtures thereof, or a mixture of oxygen with an inert gas comprising nitrogen, helium, or argon, wherein a partial pressure of oxygen in the atmosphere is greater than a partial pressure of oxygen in air.

In an embodiment, the present disclosure provides a method of growing a PbZr_{X}Ti_{(1-X)}O₃ crystal, wherein the crystal is grown in an atmosphere comprising a pressure greater than one bar.

In an embodiment, the present disclosure provides a method of growing a PbZr_{X}Ti_{(1-X)}O₃ crystal, wherein a dopant is incorporated into the solution and the crystal.

In an embodiment, the present disclosure provides a method of growing a PbZr_{X}Ti_{(1-X)}O₃ crystal, wherein the dopant is selected from iron, manganese, niobium, or a rare earth.

In an embodiment, the present disclosure provides a PbZr_{X}Ti₍₁₋ₓ₎O₃ single crystal of mass greater than 10 g.

In an embodiment, the PbZr_{X}Ti₍₁₋ₓ₎O₃ single crystal has X uniform within ±0.02.

In another aspect, a piezoelectric device is provided, comprising a PZT single crystal formed according to the methods according to any embodiment of the present disclosure. In an embodiment, such piezoelectric devices include a transducer, a receiver, a sensor, and an actuator.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1. Historical lattice parameter data for PZT showing the transition between tetragonal and rhombohedral structures at the MPB with X ≈0.52;

FIG. 2A is a PbO—ZrO₂ phase diagram. (S. Fushimi and T. Ikeda, “Phase Equilibrium in the System PbO—TiO₂—ZrO₂,” J. Am. Ceram. Soc., 50 (1967) 129 as reprinted in Phase Diagrams for Ceramists #02330, NIST and ACERS);

FIG. 2B is a PbO—TiO₂ phase diagram. (J. R. Soh, H. M. Lee, and H. S. Kwon, CALPHAD: Comput. Coupling Phase Diagrams Thermochem., 18 [3] 237-244 (1994) as reprinted in Phase Diagrams for Ceramists #EC-121, NIST and ACERS.);

FIGS. 3A-3C are proposed isothermal ternary phase diagram sections for PT and PZ in a PbO self-flux according to Fushimi and Ikeda (S. Fushimi and T. Ikeda, “Phase Equilibrium in the System PbO—TiO₂—ZrO₂,” J. Am. Ceram. Soc., 50 (1967) 129. as reprinted in Phase Diagrams for Ceramists #02562, NIST and ACERS);

FIG. 4A is a melt formulation for PZT growth showing variation of melt concentrations of ZrO₂ and TiO₂ versus the starting ratio X₀; and FIG. 4B illustrates data for PZT crystal growth in a solution of excess PbO. The transition between Ti-rich and Zr-rich regions is close to the PbTiO₃ end and has the appearance of a miscibility gap. No crystals near the MPB composition X=0.52 were observed. (R. Clarke and R. W. Whatmore, “The Growth and Characterization of PbZrxTi₁₋ₓO₃ Single Crystals,” J. Cryst. Growth 33:29 (1976));

FIGS. 5A and 5B provide data for PZT (15 mole %) in solutions of PbO—PbF₂ (5A) and KF—PbF₂ (5B) cooled from 1200 to 800° C. Crystal compositions were determined from optical observation of ferroelectric transition temperatures and therefore a range of temperatures indicated a range of compositions as shown here by the minimum and maximum values observed;

FIG. 6 illustrates qualitative solution phase diagram between PT and PZ in a PbO—PbF₂ solvent for the data shown in FIG. 5A;

FIG. 7 is a phase diagram of PbO—P₂O₅ showing congruent phases Pb&P (octalead phosphate-Pb₈P₂O₁₃), Pb₄P (tetralead phosphate-Pb₄P₂O₉), Pb₃P (lead orthophosphate-Pb₃(PO₄)₂), PbsP₂ (PbsP₄O₁₅) and Pb₂P (lead pyrophosphate-Pb₂P₂O₇). (H. H. Paetsch and A. Dietzel, “Untersuchungen über das System PbO—SiO₂—P₂O₅,”. Glastech. Ber., 29 [9] 345-355 (1956) as reprinted in Phase Diagrams for Ceramists #00228, NIST and ACERS.);

FIG. 8 is a saturation curve for one PZT melt is shown demonstrating both growth (positive weight change) and dissolution (negative weight change) on a PZT seed with varying undercooling; according to an embodiment of the present disclosure;

FIG. 9 illustrates liquidus and solidus data points are shown for single crystal growth of PZT from a PLP solvent, according to an embodiment of the present disclosure, where error bars are not shown on the graph but uncertainties for liquid compositions are±0.01, for solid compositions are±0.05, and for temperatures are±15° C., and the apparent unevenness of the solidus curve appears only to be data variation within the error bars;

FIGS. 10A and 10B, according to an embodiment of the present disclosure, provides a phase diagram of a simple solid solution with no enthalpy of mixing constructed comprising (10A) free energy curves and their tangent; and (10B) a continuous solid solution liquidus and solidus;

FIGS. 11A and 11B, according to an embodiment of the present disclosure, illustrate a eutectic phase diagram resulting from a positive enthalpy of mixing constructed comprising (11A) free energy curves with a tangent showing phase separation; and (11B) a eutectic between two terminal solid solutions SSy and SS8;

FIGS. 12A and 12B, according to an embodiment of the present disclosure, provide (12A) a fit to Equation (15) is shown with W optimized and held constant; and (12B) a fit to Equation (18) is shown with W optimized and held constant at the same value as for Equation (15);

FIG. 13, according to an embodiment of the present disclosure, is a PZT phase diagram for C=5 cation % Zr+Ti in a PLP-PbO solvent calculated from first principles and fitted data. The liquidus line is light and the solidus is heavy. A simple extrapolation at lower temperatures is shown with dashed lines. The short Zr: PT branch on the left side was not measured and is therefore not shown. Below 1100° C., the fit equations begin to break down, so a simple extrapolation is shown with dashed lines;

FIG. 14, according to an embodiment of the present disclosure, is a free energy diagram for growth of PZT with a crystal composition of X=0.52 from a PLP-PbO solvent is calculated from the parameters of TABLE V;

FIG. 15, according to an embodiment of the present disclosure, is a PZT phase diagram shown with single crystal (filled squares) and normalized polycrystal (open squares) data from a Pb₄P—PbO solvent;

FIG. 16, according to an embodiment of the present disclosure, provides a fit of Ti fraction in the crystal versus Ti/Zr in the melt with data corrected for overall Ti+Zr concentration. Circles with a short-dashed line (PLP) and triangles with a solid line (Pb₄P) are for single crystals (black) while the squares with a solid line (Pb₄P) and diamonds with a long-dashed line (PbO—B₂O₃) are polycrystalline (gray) with higher distribution coefficients because of kinetic effects of the higher growth rate;

FIG. 17, according to an embodiment of the present disclosure, provides calculated saturation temperatures from Equation (29) plotted against measured saturation temperatures in various solvents and literature data, where the results are accurate to within the temperature error bars of ±15° C.;

FIGS. 18A and 18B, according to an embodiment of the present disclosure, provide (18A) calculated solidus and liquidus curves for PbO (gray) PbO-5 cation % BO₃ (black) and PbO-5 cation % Li₂O (narrow) solvents with C=10 cation % [ZrO₂]+[TiO₂], where the PbO liquidus curve extrapolates to an intercept of 816° C., which is reasonably consistent with an extension of the liquidus in FIG. 2B; and (18B) calculated solidus and liquidus curves for PbO solvent with C=15 cation % [ZrO₂]+[TiO₂] are compared to data extracted from FIGS. 3A-3C;

FIGS. 19A-19K, according to an embodiment of the present disclosure, schematic free energy curves for the results of TABLE VIII are shown with the entropy contribution of the initial mixture (dotted), the free energy of the crystal (dashed) flattened by the positive enthalpy of mixing, and the mutual tangential tie line between them (gray solid) connecting the initial mixture charge composition (X₀) and the crystal composition (X). The energy is given in arbitrary units;

FIGS. 20A-20D, according to an embodiment of the present disclosure, are photographs of PbZr_{X}Ti_{1-X}O₃ single crystals grown from a PLP melt by top seeded solution growth from a single-phase melt with supercooling: (20A) and (20B) were dipped one time; (20C) comprising 1 cm³ PZT and (20D) comprising 1.33 cm³ were dipped multiple times. (20D) shows a smooth crystal surface partially from thermal shadowing. The dark appearance of the crystal may be due to composition;

FIGS. 21A-21E, according to an embodiment of the present disclosure, are photographs of PbZr_{X}Ti_{1-X}O₃ single crystals grown from a Pb₄P melt by top seeded solution growth. (21A), (21B), and (21C) were grown from a single-phase melt with supercooling. (21D) was grown from a two-phase melt at thermodynamic equilibrium. (21E) is a rectangle fabricated from one of the crystals where the columnar steps are still visible;

FIGS. 22A-22C schematically illustrate columnar growth. (22B), according to an embodiment of the present disclosure, an unpolished crystal surface is shown with aligned steps indicating a common origin and orientation such that the crystal is vertically monolithic. (22C), according to an embodiment of the present disclosure, a polished and etched crystal surface shows that the surface steps are separated by solvent that, when etched out, leaves gaps. This shows the crystal is not horizontally monolithic.

FIG. 23A schematically illustrates step flow growth, and 23B, according to an embodiment of the present disclosure, a small PZT crystal grown by slow step flow growth is pictured. The spalling mark in lower left corner is from residual solution that adhered to the crystal when removed from the melt;

FIG. 24 is a model of interface kinetics with a boundary layer. (R. Ghez and E. A. Giess, “Liquid Phase Epitaxy,” in Epitaxial Growth, Part A, ed. by J. W. Matthews, Academic Press, New York, 1975.);

FIG. 25, according to an embodiment of the present disclosure, illustrates furnace internals shown with insulation and baffling to control the temperature gradient and solvent evaporation;

FIGS. 26A and 26B, according to an embodiment of the present disclosure, (26A) is a baffle design is shown with a keyhole to permit insertion of a platinum sheathed thermocouple; and (26B) a platinum crucible is pictured with aspect ratio height: diameter of 1.36:1;

FIG. 27, according to an embodiment of the present disclosure, is a design for a platinum-5% gold extension paddle with welded cup to attach to an alumina rod with a platinum-gold wire pin; and

FIG. 28, according to an embodiment of the present disclosure, calculated Fe concentration in the crystal (based on structure variation) is plotted versus melt concentration with respect to octahedral site ions.

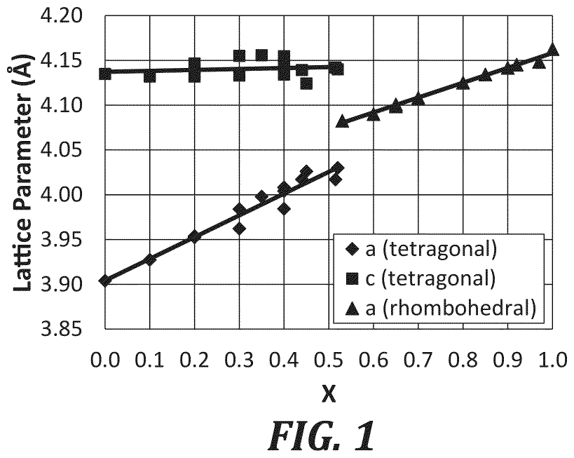

### DETAILED DESCRIPTION

The detailed description set forth below in connection with the appended drawings is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

The present disclosure relates generally to formulation of melts for crystal growth and crystal growth therefrom. This disclosure is the product of an extensive experimental and theoretical effort. As discussed further herein, the present disclosure provides methods to grow a PZT crystal from a system in thermodynamic equilibrium. It was first important to establish what thermodynamic equilibrium is, which had not been done previously. As also described herein, methods were developed to grow PZT single crystals from a single-phase solution near the thermodynamic equilibrium with a very low undercooling. The present disclosure also shows that methods were developed to achieve a two-phase liquid-solid system in thermodynamic equilibrium. Additionally, methods were developed to grow PZT single crystals of the desired composition from such a two-phase liquid-solid system in thermodynamic equilibrium. Such crystals far exceed in size anything achieved previously and therefore enable devices and applications.

### Phase Diagram Determination

### Solvent Investigation

In one aspect, the present disclosure provides a system comprising: a single-phase high temperature solution comprising concentrations of free lead oxide [PbO]_{free}, zirconium oxide [ZrO₂], titanium oxide [TiO₂] and dissolved boron oxide complexed with additional oxygen [BO₃³⁺] in thermodynamic equilibrium having a saturation temperature Ts with crystal lead zirconate titanate (PZT) PbZr_{X}Ti₍₁₋ₓ₎O₃ wherein T_{S} is according to:

$${T}_{S} = A - {B [ PbO ]}_{free} + ( C [ {ZrO}_{2} ] + D [ {TiO}_{2} ] ) ( 1 - E [ {BO}_{3}^{3 +} ] )$$

$$wherein$$

$$A = 997 \pm 50 ° C . , B = 360 \pm 100 ° C . , C = 29100 \pm 5000 ° C . ,$$

$$D = 142 \; 3 \pm 500 ° C . and E = 3.6 \pm 1 .$$

In an embodiment, the system has a ratio X_{L}=[ZrO₂]/([TiO₂]+[ZrO₂]) in the high-temperature solution in a range of 0.06 and 0.15.

In an embodiment, the system has a cation fraction [BO₃³⁺] in a range of 0 and 0.2.

In another aspect, the present disclosure provides a system comprising a solid comprising lead zirconate titanate (PZT) PbZr_{X}Ti_{(1-X)}O₃ in thermodynamic equilibrium with a high-temperature solution comprising lead oxide, zirconium oxide (ZrO₂), and titanium oxide (TiO₂).

In an embodiment, the high-temperature solution is in a state of saturation at a saturation temperature T_{S} and an average temperature of the high-temperature solution is constant to within ±3° C.

The pseudo-binary solution phase diagrams developed herein are the first of their kind and show a liquid and solid at thermodynamic equilibrium at a given temperature defined by the liquidus and solidus lines of the phase diagrams. Previously the only accurate phase diagrams available were of the end members PbO—ZrO₂ and PbO—TiO₂.

In an embodiment, the system has X in the solid in a range of 0.30 and 0.65.

In an embodiment the system has a ratio X_{L}=[Zr]_{L}/([Ti]_{L}+[Zr]_{L}) in the high-temperature solution in a range of 0.07 and 0.15.

These conditions together are explicitly not found anywhere else in the literature.

In an embodiment, the high-temperature solution does not comprise a fluoride or chloride constituent.

This differs from flux growth work done previously and eliminates constituents that have high vapor pressure, are subject to PZ-PT phase separation, and can precipitate ZrO₂. Fluorides are also more toxic and hazardous to handle.

In an embodiment, the system has a saturation temperature T_{S} in a range of about 950° C. to about 1150° C.

This is the range to assure the solution is a liquid and that the evaporation of the solvent is low enough to permit growth from a melt of sufficiently constant composition.

High temperature solution (HTS) growth is useful for growth of “difficult” materials that, for various reasons, are not amenable to growth by conventional bulk techniques wherein the crystal is grown directly from the melted target compound. This includes non-congruent melting materials, complex mixtures, and compounds with volatile constituents. HTS growth gives the ability to vary growth conditions including temperature, chemical environment, and atmosphere so that unstable crystal materials can be stabilized. The most basic decision is the choice of the solvent or flux. Elwell and Scheel give a wide variety of solvents for solution growth (D. Elwell and H. J. Scheel, Crystal Growth from High Temperature Solutions (Academic Press, London, (1975)). The following are desirable attributes for an HTS solvent.

1) Good solubility for the crystal constituents in the target growth temperature range. In an embodiment, 10-20% is desirable for methods such as slow cooling or top-seeded solution growth. Up to 50% increases the yield but also increases the risk of massive homogeneous nucleation. A dilute melt with ~1-4% solute at growth conditions is the most stable against homogeneous nucleation but can have a very low growth rate. There should be an appreciable change in solubility with temperature so that crystals can be grown by undercooling. Solvent concentration is one of the factors that govern growth kinetics. If there are dopants, they should dissolve equally well in the solvent. Because zirconium oxide is so refractory, it tends to have poor solubility in many solvents including PbO. Previous studies often tried adding equal amounts of ZrO₂ and TiO₂ in contravention of this fact.

2) In an embodiment, the solvent constituents do not appear as an impurity in high concentration in the crystal or form a solid solution with the solute. Choosing different valence states or ionic sizes of the solvent constituents compared to the solute reduces their solubility in the crystal. Self fluxing is often a first choice for HTS growth and PbO is a well-known solvent that is used in many applications.

3) In an embodiment, the crystal phase is the only stable solid phase at the growth temperature, and it precipitates with the desired stoichiometry. This is particularly challenging for PZT. KF—PbCl₂ solvents tend to precipitate ZrO₂ crystals under many conditions.

4) In an embodiment, the viscosity of the solution is moderate at the growth temperature, preferably ~1 centipoise, but certainly <10 centipoise. This allows transport processes wherein the solute ions are transported to the growth interface and solvent ions are transported away, which control the growth kinetics. Somewhat higher viscosity can reduce vaporization of volatile constituents. Solvents with high concentrations of boron oxide, phosphorous oxide, and silicon oxide tend to have problems with high viscosity, but moderate concentrations can improve solvent performance.

5) In an embodiment, the solution has a low melting point, certainly below the desired range of growth, substantially limited on the lower end by the solvent solidification temperature, which should be less than 1000° C., preferably less than 950° C. In an embodiment, the upper end of the growth range is limited to be less than 1150° C. for PZT by the vapor pressure of PbO, PbF₂ or PbCl₂. A low melting and growth temperature melt is also consistent with a dilute melt.

6) In an embodiment, the system is contained in an inert crucible with low solubility in the high-temperature solution at the saturation temperature Ts. In an embodiment, the solvent has low reactivity with the crucible. In an embodiment, the system is contained in a crucible comprising platinum, a platinum alloy, or a dispersion hardened platinum alloy. Platinum has a high melting temperature and is a noble metal that does not have a thermodynamically preferred oxide at 1000° C. in air. Lead- and bismuth-containing solvents are known to have a moderate solubility of platinum, particularly in an air atmosphere, but platinum is not readily incorporated in perovskites. Because of the significant change of volume of the system on melting and repeated thermal cycling with solidification-melting cycles, pure platinum is too soft and easily deformed, and crucibles have a lower lifetime. Platinum alloys such as Pt-5% Au are stronger and more durable as are dispersion hardened platinum alloy composites reinforced with ceramic particles such as Pt—ZrO₂ or Pt—Y₂O₃.

7) In an embodiment, the solvent is easily separated from the crystal by physical or chemical means. In an embodiment, the HTS solvent is easily dissolved in hot water, a heated mineral acid such as hydrochloric acid, nitric acid, and acetic acid, or a basic solution, such as sodium hydroxide. A nitric acid/acetic acid/water mixture is commonly used to dissolve lead oxide and other lead compounds and only moderately etches the PZT if the cleaning time is kept short.

8) In an embodiment, the solvent has a low vapor pressure under the growth conditions. The issue with lead oxide, even more so with PbF₂, and worst of all with PbCl₂ is that they have high vapor pressures at high temperatures. Unless the crucible is sealed, which is not possible for top-seeded solution growth, a high vaporization rate can result in a constantly varying melt composition and unstable conditions unsuitable for crystal growth. In some ZrO₂ growth experiments, nearly all the fluoride solvent vaporized during the run (Y. Fujiki and Y. Suzuki, “Flux growth and surface observations of ZrO₂ single crystals,” J. Cryst. Growth 24/25 (1974) 661). In one early experiment in the present disclosure, half the fluoride solvent evaporated during the process of crystal growth and losses of 10-15% were common for melts equilibrated near 1200° C. While solvent evaporation can be a means to precipitate the solute at constant temperature, it is also relatively uncontrolled, and the furnace exhaust system and fume scrubber are strained to handle this large chemical load. In an embodiment, the solvent is non-reactive and compatible with the growth atmosphere, most commonly air, though other atmospheres have advantages as will be discussed below.

9) In an embodiment, low/moderate toxicity and chemical hazard is important for a process that will eventually go to production. Lead-based solvents are considered moderately toxic. Fluorides are a higher degree of hazard.

10) In an embodiment, the density of the solution is lower than the density of PZT. The density of the solvent governs whether the crystals float or sink to the bottom of the crucible. One or the other may be more desirable depending on the growth technique. Because PZT is very dense, almost all solvents except undiluted lead oxide/fluoride/chloride are observed to be less dense than the crystals, which tend to reside on the bottom of the crucible.

11) In an embodiment, the solvent does not wet the crucible so well that it “creeps” out of the crucible. A few materials wet the crucible so well and have such low density that they can “creep” out of the crucible. Alkali vanadates are of concern for this issue.

12) In an embodiment, the solvent is available in high purity at low cost for a viable industrial process.

A summary statement is that the crystal growth system consisting of the solvent, solute, crucible, atmosphere, and furnace should be stable in as many ways as possible.

In an embodiment, the system comprises lead oxide in a form selected from PbO and Pb₃O₄.

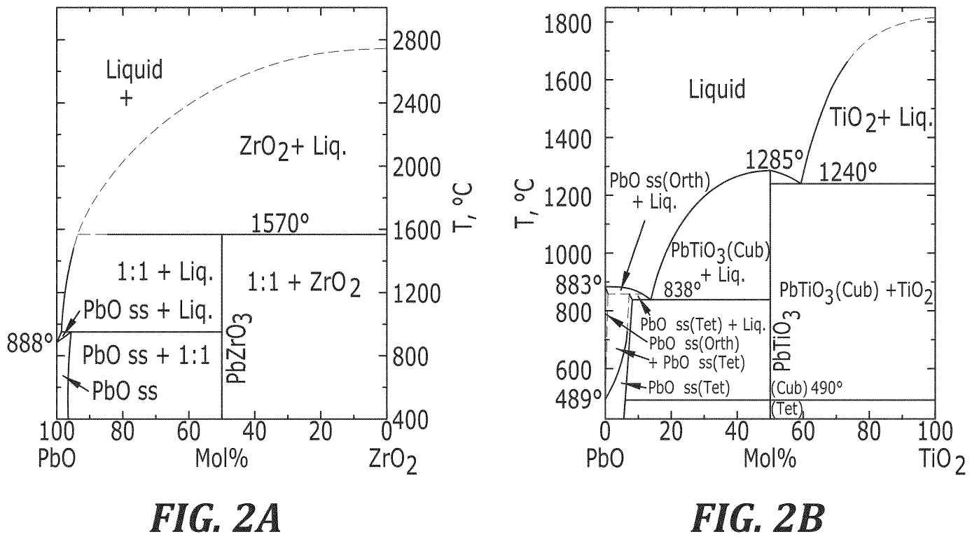

The phase diagrams of FIG. 2 show that a substantial source of lead oxide is needed to form PZT and that typically comes from PbO, Pb₃O₄, or another lead compound acting as both part of the solvent and part of the solute. Pb₃O₄ is multi-valent and is sometimes preferred over PbO because it can be more oxidizing on initial melting, however at temperatures above 600° C., Pb₃O₄ converts to 3PbO+1/2O₂ unless a high oxygen pressure is supplied, and the melt is expected to contain only Pb²⁺. As discussed throughout this specification, lead oxide is preferable to lead halides.

In an embodiment, the system has a solvent composition of the high temperature solution comprising lead oxide and a Lewis acid component selected from the group consisting of B₂O₃, P₂O₅, V₂O₅, MoO₃, or a combination thereof.

In the early phases of the present work, various melt combinations were studied, mostly consisting of a Lewis base (oxygen donor) such as PbO and a Lewis acid (oxygen acceptor group) such as B₂O₃, P₂O₅, V₂O₅, MoO₃, or a combination thereof, as this is a common method of formulating solvents/fluxes. Additives that complex PbO or increase the melt viscosity decrease PbO evaporation making crystal growth more stable. Many of these mixtures have compounds, but the ratios between them in the solvent were not always the stoichiometric compound ratios. The question is whether the solvent ingredients melt to an ionic solution or a molecular solution where clusters of atoms form in compound molecules. This may depend on how refractory the compounds are with high melting temperature compounds tending to cluster molecularly in the melt. Unblended lead oxide is known to form an ionic solution mostly of Pb²⁺ and O²⁻ and to dissolve the ingredients for rare earth iron garnets ionically as well (K. Fischer, D. Linzen, E. Sinn, and S. Bornmann, “Equilibrium Reactions in Oxidic High Temperature Solutions Used for Liquid Phase Epitaxy of Garnet,” J. Cryst. Growth 52 (1981) 729). However, in the present study it was seen that Pb₂P₂O₇, PbMoO₄, PbWO₄, and PbLiPO₄ form molecular clusters in the melt that greatly reduce the solving power of PbO. Free PbO dissolving to an ionic solution is the most effective solvent for solution of PZT.

The following solvent ingredients were investigated singly or in combination.

PbO or Pb₃O₄

PbO—PbF₂—In air any mixture with more than 45% PbF₂ will react to form the eutectic 55% PbO-45% PbF₂, which melts at 490° C.

PbO—Li₂O—Makes the melt much less dense.

PbO—Na₂O—Makes the melt less dense; sodium can potentially be incorporated into the perovskite crystal structure.

PbO—K₂O—Potassium can potentially be incorporated into the perovskite crystal structure.

PbO—B₂O₃—(see below)

PbO—SiO₂—Precipitates ZrSiO4.

PbO—P₂O₅ (added as ammonium dihydrogen phosphate-ADP, which dehydrates and decomposes to P₂O₅ releasing ammonia and water)—or equivalent mixtures of PbO with molecular compounds such as PbO—(Pb₂P₂O₇, Pb₅P₄O₁₅, Pb₃P₂O₈, Pb₄P₂O₉, Pb₅P₂O₁₀). It is seen that Pb₂P₂O₇ and other Lewis base-Lewis acid combinations form a molecular solution.

PbO—V₂O₅—PbV₂O₆ and Pb₂ V₂O₇ molecular solutions are seen in solidified melts. V₂O₅ is subject to evaporation, it oxidizes the platinum crucible, and the vanadate melt creeps up the crucible walls. Vanadium oxide occurs in many valence states and may be added as such. Vanadium is often reduced to V³⁺ at high temperature resulting in the release of oxygen.

PbO—PbSO₄—Complete SO₃ evaporation.

PbO—MoO₃—PbO—PbMoO₄ molecular solution seen in solidified melts.

PbO—WO₃—PbO—PbWO₄ and Pb₂WO₅ molecular solutions seen in solidified melts.

PbO—LiF—Forms PbF₂, which evaporates at a high rate.

PbO—NaF—Forms PbF₂, which evaporates at a high rate.

PbO—KF—Forms PbF₂, which evaporates at a high rate.

PbO—K₂P₂O₆—Forms phosphate molecular solution.

PbO—PbLiPO₄ (PLP)—(see below)

In an embodiment, the system has a solvent composition of the high temperature solution comprising lead oxide and a Lewis base component selected from the group consisting of Li₂O, Na₂O, K₂O, or a combination thereof.

In an embodiment, the system has a solvent composition selected from PbO, Pb₃O₄, PbO—B₂O₃, Pb₃O₄—B₂O₃, PbO—Li₂O, Pb₃O₄—Li₂O, PbO—Li₂O—B₂O₃, Pb₃O₄—Li₂O—B₂O₃, PbO—Li₂O—MoO₃, Pb₃O₄—Li₂O—MoO₃, PbO—Pb₂P₂O₇, and PbO—PbLiPO₄.

In an embodiment, the system has a has a solvent composition comprising an ionic solution.

In an embodiment, the system comprises a PbZr_{X}Ti₍₁₋ₓ₎O₃ solid, wherein the PbZr_{X}Ti₍₁₋ₓ₎O₃ comprises a higher density than the high-temperature solution.

Any additive to PbO in the solvent acts in multiple ways.

Most additives reduce the melting temperature of the solvent through melting point depression up to a certain level of addition and according to the binary phase diagram between the two thereafter. The lead oxide compounds with B₂O₃ and V₂O₅ have the lowest melting temperatures and therefore reduce the melting temperature the most and are less likely to form molecular clusters with PbO at high temperature.

Lewis bases such as Li₂O and Na₂O also contribute to the forming of an ionic solution. When a solvent is only two Lewis bases, e.g. PbO and Li₂O, it is likely to be fully ionic and unlikely to have any molecular clusters but both Lewis base constituents may evaporate.

Lewis acids such as B₂O₃, P₂O₅, V₂O₅ and MoO₃ complex oxygen from the Pb²⁺—O²⁻ ionic solution.

Glass-formers such as B₂O₃, SiO₂ and P₂O₅ increase the viscosity of the melt and reduce PbO evaporation but can also reduce diffusion and other forms of transport.

B₂O₃, can complex other ions to decrease their activity and increase their effective solubility.

Lewis bases and Lewis acids can complex in the melt to form a molecular solution.

All these additives are less dense than PbO and so reduce the density of the solution. This is important because it is desirable in this case for any nucleated PZT crystals to remain on the bottom of the melt rather than floating to the surface. Pure PZT has a density of 7.995 g/cm³ at room temperature. Lattice parameter data and the coefficient of thermal expansion extrapolate to a density of 7.859 g/cm³ at 1000° C. However, pure α-PbO (litharge) has a density of 9.53 at room temperature. Fortunately, this has higher coefficient of thermal expansion and a significant volume change on melting, so the liquid density is reduced to 7.99 g/cm³ at 1000° C. (E. F. Riebling, “Structure Changes in the Molten Oxide System: Lead Oxide-Germanium Dioxide,” Inorganic Chemistry 3 (1964) 958). With the addition of solute, the melt is further reduced in density to an estimated 7.59 g/cm³ for 10% [ZrO₂]+[TiO₂] solute. Therefore, the crystals should be denser than the melt under all circumstances. However, to reduce the melt density further to avoid any upwelling of small PZT crystals that could interfere with growth, addition of around 5-10 molar % of a low-density additive is possible. Some examples with their solid densities are given in TABLE IV. Their liquid densities should be lower still. Effects of mixing are unknown.

TABLE IV
Low density additives solid densities.

| Compound | ρ (g/cm³) |
|---|---|
| Li₂O | 2.01 |
| Na₂O | 2.27 |
| B₂O₃ | 2.46 |
| P₂O₅ | 2.39 |
| V₂O₅ | 3.36 |
| LiBO₂ | 2.222 |
| Li₂B₄O₇ | 2.43 |
| LiVO₃ | 2.984 |
| Li₂MoO₄ | 3.044 |
| Na₂MoO₄ | 3.78 |

The determination of the solution phase diagram in these solvents is an enabling technology for crystal growth. Since these melts are at least partially ionic solutions and contain cations of various valences and oxygen coordinations, melts were formulated using cation percentages for consistency rather than molar or weight percentages as is common in the literature, but various sources may use conventional molar percentages or even weight percentages.

### Solution Phase Diagram in Phosphate Sol Vents

Lead pyrophosphate Pb₂P₂O₇ with a melting temperature of 830° C. has an almost immeasurably low vapor pressure up to 1200° C. In the present work, it was seen that this most likely results from forming a molecular solution. In the present work, lead lithium phosphate PbLiPO₄ with a melting temperature of 850° C. was likewise found to have a very low vapor pressure and likely forms a molecular solution. Therefore, phase diagram studies were undertaken with these solvents mixed with an excess of PbO as both solvent and solute and varying amounts of TiO₂ and ZrO₂. The characteristics of these solvents are discussed below.

PbO—PbLiPO₄ (PLP) lead lithium phosphate-Xray diffraction (XRD) of the solidified melt showed that PLP remained as a compound in the solidified solvent and probably remained intact molecularly even in the high temperature melt resulting in low PbO evaporation. PLP has a high melting temperature of 850° C., so the free energy may favor molecules remaining after melting. Pure PLP had virtually no PbO evaporation. PLP had a very low solubility of ZrO₂ and tended to grow ZrO₂ crystals if large amounts were added. Added PbO was used to increase the ZrO₂ solubility and provide enough Pb activity to form PZT rather than ZrO₂. An optimum ratio of PbO: PLP of 0.6:1 was found with a range of 0.5-0.8:1. This solvent has more evaporation than pure PLP, generally proportional to the ratio of excess (e.g. “free”) PbO to PLP, but it was still low. There was some lithium phosphate evaporation that deposited on the alumina furnace tube causing the formation of lithium aluminum phosphate, which then partially melted. The PLP solvent had the disadvantage that it wet all surfaces very strongly including both the platinum crucible and any PZT crystals and was readily incorporated in crystals as inclusions. Residual melt was hard to remove from the crucible except by thermal shock.

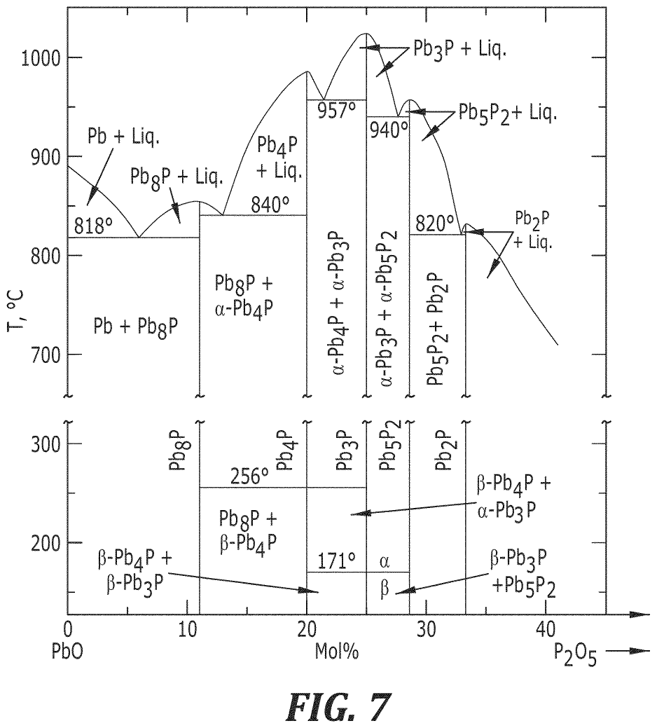

PbO—P₂O₅ is a complex phase diagram, as seen in FIG. 7, containing multiple congruent phases Pb₈P (octalead phosphate-Pb₈P₂O₁₃ or, more correctly, octalead pentoxide diphosphate Pb₈O₅(PO₄)₂), Pb₄P (tetralead phosphate-Pb₄P₂O₉ or, more correctly, tetralead monoxide diphosphate-Pb₄O(PO₄)₂), Pb₃P (lead orthophosphate-Pb₃(PO₄)₂, the “stoichiometric” lead phosphate), Pb₅P₂(Pb₅P₄O₁₅) and Pb₂P (lead pyrophosphate-Pb₂P₂O₇) as shown in FIG. 7. Pure lead pyrophosphate Pb₂P₂O₇ is known to have virtually zero PbO evaporation but grew only ZrO₂ in this study unless additional lead oxide was added. A solidified solvent in the Pb₄P phase range indeed had an x-ray diffraction (XRD) pattern for Pb₄P consistent with the phase diagram. Because this was the region of the phase diagram used for HTS experiments, this solvent was referred to as Pb₄P. However, the melt was thermodynamically estimated to consist of PbO and molecular clustered Pb₂P₂O₇ (possibly as some mix of PbPO₃ and PbPO₄) based on the PbO activity. The solubility of ZrO₂ in lead orthophosphate is very low and mainly the excess PbO participates in solubility. The excess PbO in the final solvent mixture was prone to more evaporation as was seen in PLP but some lead phosphate evaporation occurred and condensed on alumina fixtures, which corroded at a moderate rate. This solvent did not wet platinum or the PZT crystal well. The residual solvent dissolves quickly off the crystal, and the crystals grown were much less subject to inclusions.

Using these phosphate solvents, evaporation of the solvent, mainly PbO, was reduced from 5-10% down to <1%, which is very low in uncovered PbO solvent melts at such high temperatures.

In an embodiment, to produce a consistent phase diagram, a cation concentration C=[Zr]+[Ti]=5 cation % is used for crystal growth with varying octahedral species fractions XL=[Zr]/([Zr]+[Ti]). It was observed that owing to the lower solubility of zirconia, XL in a narrow range about 0.07-0.15 was preferred in certain embodiments.

As described further herein, experiments were done by growth on a platinum paddle. HTS growth on a platinum paddle proceeds quickly and copiously at a relatively low undercooling because platinum is a good nucleation site, it does not dissolve in the melt, and is cooler by virtue of being higher in the negative gradient and a good conductor of heat. Platinum can be used as a buffer layer in growing piezoelectric perovskites on silicon, where the resulting epitaxy is textured polycrystalline with grain boundaries and dislocations to accommodate the mismatch rather than being a true single crystal. Growth runs on the platinum paddle were highly polycrystalline showing the many orientations of platinum grains in the paddle. Platinum has a moderate lattice mismatch to PZT with a room temperature cubic lattice parameter of 0.392 nm, 3.7% lower than the PZT average, which is worse than an exemplary perovskite substrate TbScO₃, which was found not to grow epitaxial crystals but dissolve instead. This lattice mismatch persists to high temperature, but platinum wins the competition because, unlike TbScO₃, it does not dissolve significantly, so the growth interface can only move one way. It was observed that the undercooling to nucleate on Pt was only about 4° C. less than the saturation temperature on a PZT seed. This is less than one would expect from the perovskite substrate results. Gold (Au) has a better lattice match to PZT (a (Au)=0.40782 nm), but the melting temperature of pure Au is low, 1064° C., and it is very soft unless alloyed, for example, with Pt.

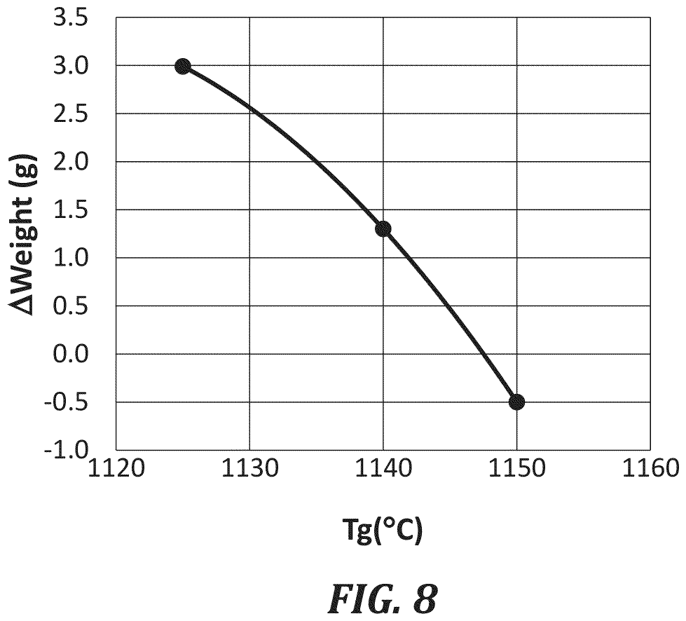

Growth on PZT allowed a clear determination of saturation temperature for growth, which was fully proven by dissolution of a part of a seed. FIG. 8 shows a representative set of such data from one of the PLP melts with common composition and growth conditions, with the exception of varying temperature. This plot shows that there is no thermodynamic barrier or minimum undercooling for PZT growth on a PZT seed.

The melt was stirred first at a high temperature, at least 50° C. above the growth temperature, to put everything in solution and then lowered to the growth temperature where it was held for 3-7 days until it was determined growth had stopped. However, this rapid growth method on the paddle changed the distribution coefficient among Zr and Ti because of kinetic incorporation of the higher concentration solute, Ti. Therefore, once the general phase diagram was determined, more precise data were taken by dipping a pointed platinum wire into the melt and growing a single or near-single crystal from a single nucleation site. The temperature was also varied according to the initial data to delineate the liquidus and solidus curves.

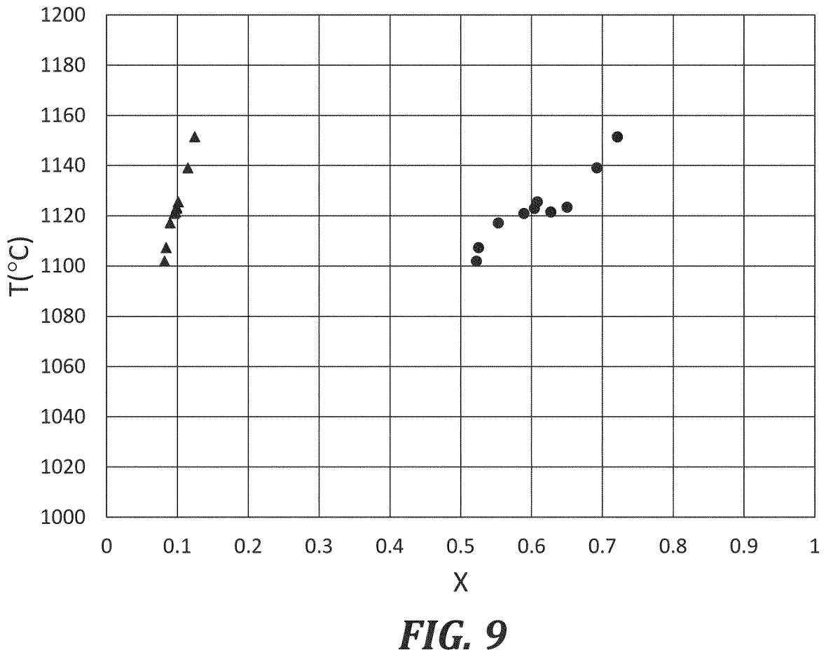

The initial data were pairs of liquid-solid compositions from the crystal growth runs that delineated small portions of the liquidus and solidus curves on the phase diagram (FIG. 9). This could be done over a reasonable temperature range where the growth rate was sufficiently high, and the evaporation rate was not too low. The solid curve appears uneven but is well within the data uncertainties.

During the growth runs, growth of the crystals and evaporation of the solvent resulted in deviation from the ideal concentration C=5 cation % and therefore the growth temperature was normalized for consistency to have combined C=Zr+Ti ionic concentration of 5 cation % as is used for the phase diagram. Each data set was normalized to C=0.05 using T(norm)=T−3,400 (C−0.05)+185 (Pb−Pb₀) where the second (and much smaller) correction is to allow for small variations in the excess Pb concentration in the melt that might arise from such factors as evaporation. Only single crystal data were used in this determination. Because of the higher growth rate, pilot polycrystalline runs on the paddle have a somewhat lower Zr distribution coefficient (higher Ti distribution coefficient) and therefore a shifted solidus (though not the liquidus).

The compositional pair data for the innovative PLP solvent was shown to shift the eutectic far toward lead titanate with the Zr fraction at the eutectic estimated at X_{L} =2-3% PZ. This also reduced the enthalpy of mixing in the crystal relative to the melt such that all the growth occurs in the Ti-doped PZ range and the desired equimolar composition is accessible without phase separation as occurred in previous studies. The range of X_{L} was only 0.08-0.13 with fine details explored iteratively based on results, compared to coarse meshes in previous studies.

While this data is useful for a single concentration, a better understanding of the entire phase diagram was needed and was therefore achieved by theoretical and computational means. This derivation was done initially for the PbO—PLP solvent and later adapted to the PbO—Pb₄P solvent. What follows is a complete free energy derivation to a closed form for the growth of a solid solution with an enthalpy of mixing in the solid from a liquid solution that also contains a solvent not incorporated into the crystal. To our knowledge, such has not been completed before. It is presented in full here. The results are more than just a theoretical exercise. When fit to the growth data already taken, these equations allow the determination of important thermodynamic parameters, accurate construction of a phase diagram and plotting of free energy curves that elucidate issues of phase separation in lead zirconate titanate (PZT=PbZr_{X}Ti₁₋ₓO₃) and how it can be avoided.

Assuming that the melt and the crystal are ideal solutions, the entropy of mixing AS of two components, Zr/Ti, ZrO₂/TiO₂, or lead zirconate (PZ=PbZrO₃)/lead titanate (PT=PbTiO₃) in either the liquid or the solid is given as:

$$Δ S = - R ( X ln ( X ) + ( 1 - X ) ln ( 1 - X ) ) \qquad ( 1 )$$

where R is the gas constant (8.314 J/K/mol) and X is the concentration of Zr versus all octahedral ions X=Zr/(Zr+Ti). (Note that 1−X=Ti/(Zr+Ti) is the concentration of Ti versus all other octahedral ions.)

If it is assumed that the liquid is the reference phase and there is no enthalpy of mixing in the liquid, the free energy change of a liquid solution ΔG_{L} of two components compared to a solution of a single substance comes just from the entropy of mixing between Zr and Ti for a relative Zr concentration in the liquid XL.

$$Δ {G}_{L} = - T Δ {S}_{L} = RT ( {X}_{L} ln ( {X}_{L} ) + ( 1 - {X}_{L} ) ln ( 1 - {X}_{L} ) ) \qquad ( 2 )$$

In the solid, the free energy of solution starts with ΔG₀, the linear combination of the temperature dependent free energies of solution of the two end members, lead zirconate and lead titanate at the solidification temperature T, which would be the free energy of solidification if there was no solid solubility, and the two components were completely immiscible. (The Zr concentration in the solid Xs has elsewhere just been called X or x.)

$$Δ {G}_{0} = {X}_{S} Δ {G}_{PZ} ( T ) + ( 1 - {X}_{S} ) Δ {G}_{P T} ( T ) \qquad ( 3 )$$

The temperature dependence of the free energy of formation depends on the temperature relative to the equilibrium temperature, in this case the saturation temperature for the nominal concentrations of PZ and PT. The sum of the concentrations of Zr and Ti in the melt is set to be constant at 5% for this derivation. Other Zr+Ti concentrations will have different end member saturation temperatures T_{PZ} and T_{PT}.

$$Δ {G}_{PZ} ( T ) = Δ {H}_{PZ} ln ( {T}_{PZ} / T ) = Δ {H}_{PZ} ( ln ( {T}_{PZ} ) - ln ( T ) ) \qquad ( 4 )$$

$$Δ {G}_{P T} ( T ) = Δ {H}_{P T} ln ( {T}_{P T} / T ) = Δ {H}_{P T} ( ln ( {T}_{P T} ) - ln ( T ) ) \qquad ( 5 )$$

To a first approximation, the enthalpies of solution of PZ and PT, ΔH_{PZ} and ΔH_{PT}, are considered temperature independent, but this is not certain. It is expected that they will be independent of the concentration Zr+Ti.

For a solid solution, the enthalpy of mixing in the solid AHM can be written as:

$$Δ {H}_{M} = {WX}_{S} ( 1 - {X}_{S} ) \qquad ( 6 )$$

where W is the interaction parameter between Zr and Ti in PZT with units of enthalpy. At its simplest, this expresses the difference in free energies between like and different nearest neighbor octahedral ions. A positive W, which is known in PZT from Rane and Navrotsky (M. V. Rane and A. Navrotsky, “Enthalpies of Formation of Lead Zirconate Titanate (PZT) Solid Solutions,” J. Solid State Chem. 161 (2001) 402.), indicates that PZT tends to demix, which has been seen as phase separation.

The entropy of mixing of the two octahedral site ions in the solid solution ΔSs is given by Equation (1) in the Zr concentration in the solid Xs.

$$Δ {S}_{S} = - R ( {X}_{S} ln ( {X}_{S} ) + ( 1 - {X}_{S} ) ln ( 1 - {X}_{S} ) ) \qquad ( 7 )$$

The total free energy of the solid AGs comes from the sum of the linear immiscible free energy ΔG₀, the enthalpy of mixing, and the entropy of mixing.

$$Δ {G}_{S} = {ΔG}_{0} + Δ {H}_{M} - T Δ {S}_{S} \qquad ( 8 )$$

Substituting Equations (3), (6) and (7) into Equation (8) yields:

$$Δ {G}_{S} = {X}_{S} Δ {G}_{PZ} ( T ) + ( 1 - {X}_{S} ) Δ {G}_{P T} ( T ) + {WX}_{S} ( 1 - {X}_{S} ) + RT ( {X}_{S} ln ( {X}_{S} ) + ( 1 - {X}_{S} ) ln ( 1 - {X}_{S} ) ) \qquad ( 9 )$$

Substituting Equations (4) and (5) into Equation (9) and regrouping yields:

$$Δ {G}_{S} = {X}_{S} ( Δ {H}_{PZ} ln ( {T}_{PZ} ) - Δ {H}_{P T} ln ( {T}_{P T} ) ) + {X}_{S} ln ( T ) ( Δ {H}_{P T} - Δ {H}_{PZ} ) - Δ {H}_{P T} ln ( T ) + Δ {H}_{P T} ln ( {T}_{P T} ) + {WX}_{S} ( 1 - {X}_{S} ) + RT ( {X}_{S} ln ( {X}_{S} ) + ( 1 - {X}_{S} ) ln ( 1 - {X}_{S} ) ) \qquad ( 10 )$$

Usefully these terms can be given as five constants C₁-C₄ (numbered according to the derivation below) and W with Xs and T as variables.

$$Δ {G}_{S} = {X}_{S} {C}_{1} + {X}_{S} ln ( T ) {C}_{2} - {C}_{4} ln ( T ) + {C}_{3} + {WX}_{S} ( 1 - {X}_{S} ) + RT ( {X}_{S} ln ( {X}_{S} ) + ( 1 - {X}_{S} ) ln ( 1 - {X}_{S} ) ) \qquad ( 11 )$$

For a constant temperature, the curves for Equations (2) and (10) can be plotted on a free energy diagram.

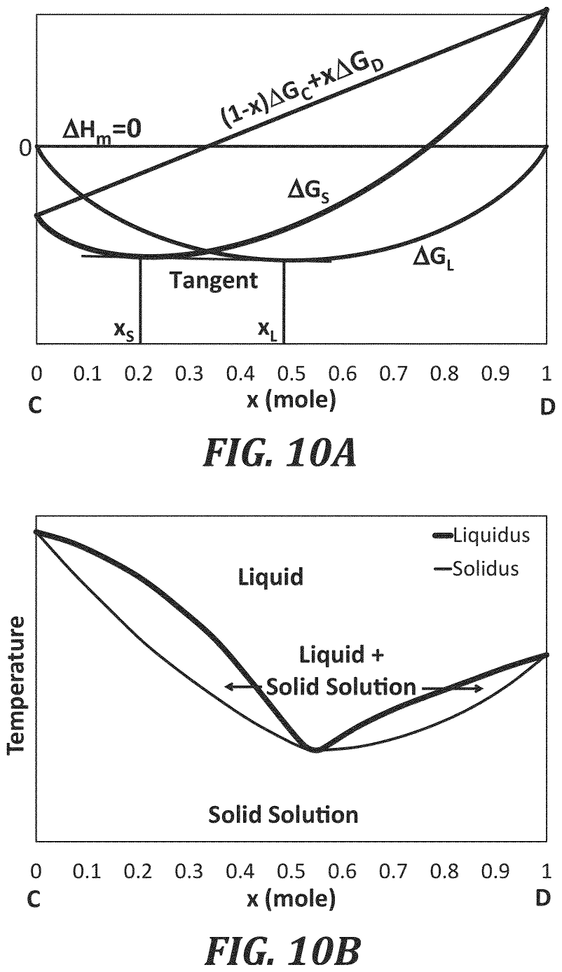

For reference, an exemplary set of free energy curves used to construct a phase diagram for a normal simple two-component continuous solid solution in two pure components with no enthalpy of mixing is given in FIGS. 10A and 10B. At any given temperature there is a mutual tangent between the two curves as shown in FIG. 10A. This defines the saturation liquid composition XL at that temperature and the solid composition Xs that will precipitate. This can be used to create a simple solid solution phase diagram as in FIG. 10B and found commonly in the literature.

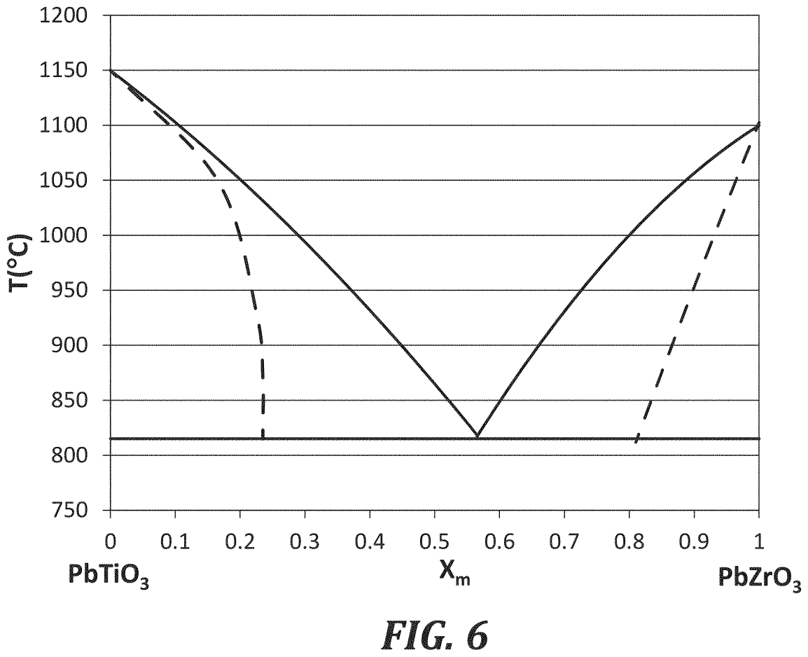

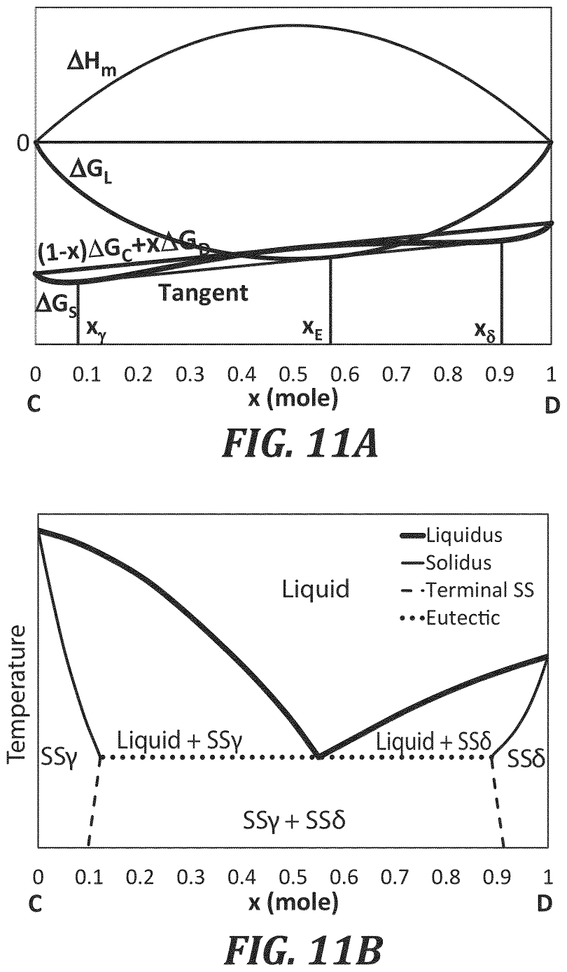

If there is a positive heat of mixing, the situation is more complex and there can be phase separation as shown in FIGS. 11A and 11B. When the positive heat of mixing becomes large enough, the solid free energy curve has a retrograde segment with two minima as in FIG. 11A. This produces a eutectic phase diagram as in FIG. 11B with two terminal partial solid solutions of D in C (SSY) and C in D (SS8). This is similar to the hypothetical phase diagram in FIG. 6 and is also similar to many phase diagrams found in the literature.

The current situation is more complex in that C and D are oxide compounds PZ and PT precipitating from a liquid solution containing additional solvent components that are not incorporated into the crystal and the PbO concentration is variable and different from the sum of the ZrO₂ and TiO₂ concentrations to be off stoichiometry. To derive a phase diagram, it is assumed that the overall sum of the concentrations of Zr and Ti in solution is constant and the PbO concentration is also constant (corrections for slight variations in the sum and variable PbO concentrations to a standard value were determined and is discussed above). As a result, other free energy terms will remain constant or nearly so on solidification and can be ignored. If there is no phase separation as in FIGS. 10A and 10B, the mutual tangent line has the simple equation:

$$Δ G = a X + b \qquad ( 12 )$$

and must be simultaneously tangent to ΔG_{L} and ΔGs at X_{L} and X_{S}, respectively.

Equations (2) and (10) can be differentiated with respect to X and they must have equal slope a, and equal intercept b when evaluated at X_{L} for Equation (13) and X_{S} for Equation (14).

$${a}_{L} = d ( Δ {G}_{L} ) / dX = RT ( ln ( {X}_{L} ) - ln ( 1 - {X}_{L} ) ) \qquad ( 13 )$$

$${a}_{S} = d ( Δ {G}_{S} ) / dX = Δ {G}_{PZ} ( T ) - Δ {G}_{P T} ( T ) + W ( 1 - 2 {X}_{S} ) + RT ( ln ( {X}_{S} ) - ln ( 1 - {X}_{S} ) ) = Δ {H}_{P Z} ( ln ( {T}_{P Z} / T ) ) - Δ {H}_{P T} ( ln ( {T}_{P T} / T ) ) + W ( 1 - 2 {X}_{S} ) + RT ( ln ( {X}_{S} ) - ln ( 1 - {X}_{S} ) ) = Δ {H}_{PZ} ( ln ( {T}_{PZ} ) - ln ( T ) ) - Δ {H}_{P T} ( ln ( {T}_{P T} ) - ln ( T ) ) + W ( 1 - 2 {X}_{S} ) + RT ( ln ( {X}_{S} ) - ln ( 1 - {X}_{S} ) ) = Δ {H}_{PZ} ln ( {T}_{PZ} ) - Δ {H}_{P T} ln ( {T}_{P T} ) ) + ( Δ {H}_{P T} - Δ {H}_{PZ} ) ln ( T ) + W ( 1 - 2 {X}_{S} ) ) + RT ( ln ( {X}_{S} ) - ln ( 1 - {X}_{S} ) ) \qquad ( 14 )$$

Setting aL=as and regrouping:

$$( Δ {H}_{PZ} ln ( {T}_{PZ} ) - Δ {H}_{P T} ln ( {T}_{P T} ) ) + ( Δ {H}_{P T} - Δ {H}_{PZ} ) ln ( T ) + W ( 1 - 2 {X}_{S} ) = {C}_{1} + {C}_{2} ln ( T ) + W ( 1 - 2 {X}_{S} ) = RT ( ln ( {X}_{L} ) - ln ( 1 - {X}_{L} ) - ln ( {X}_{S} ) + ln ( 1 - {X}_{S} ) ) \qquad ( 15 )$$

Constants C₁ and C₂ have been inserted for two terms.

The intercepts b_{L} and b_{S} must also be the same.

$${b}_{L} = Δ {G}_{L} - {a}_{L} {X}_{L} = R T ln ( 1 - {X}_{L} ) \qquad ( 16 )$$

$${b}_{S} = Δ {G}_{S} - {a}_{S} {X}_{S} = RT ln ( 1 - {X}_{S} ) + Δ {G}_{P T} ( T ) + {{WX}_{S}}^{2} \qquad ( 17 )$$

Setting Equations (16) and (17) to be equal

$$Δ {H}_{P T} ln ( {T}_{P T} ) - Δ {H}_{P T} ln ( T ) + {WX}_{S}^{2} = {C}_{3} + {C}_{4} ln ( T ) + {WX}_{S}^{2} = RT ( ln ( 1 - {X}_{L} ) - ln ( 1 - {X}_{S} ) ) \qquad ( 18 )$$

Constants C₃ and C₄ have been inserted for two other terms. These four constants have the following relations.

$${C}_{1} = Δ {H}_{PZ} ln ( {T}_{PZ} ) - Δ {H}_{P T} ln ( {T}_{P T} ) \qquad ( 19 )$$

$${C}_{2} = Δ {H}_{P T} - Δ {H}_{P Z} \qquad ( 20 )$$

$${C}_{3} = Δ {H}_{P T} ln ( {T}_{P T} ) \qquad ( 21 )$$

$${C}_{4} = - Δ {H}_{P T} \qquad ( 22 )$$

$${C}_{1} + {C}_{3} = Δ {H}_{PZ} ln ( {T}_{PZ} ) \qquad ( 23 )$$

$$- {C}_{2} - {C}_{4} = Δ {H}_{P Z} \qquad ( 24 )$$

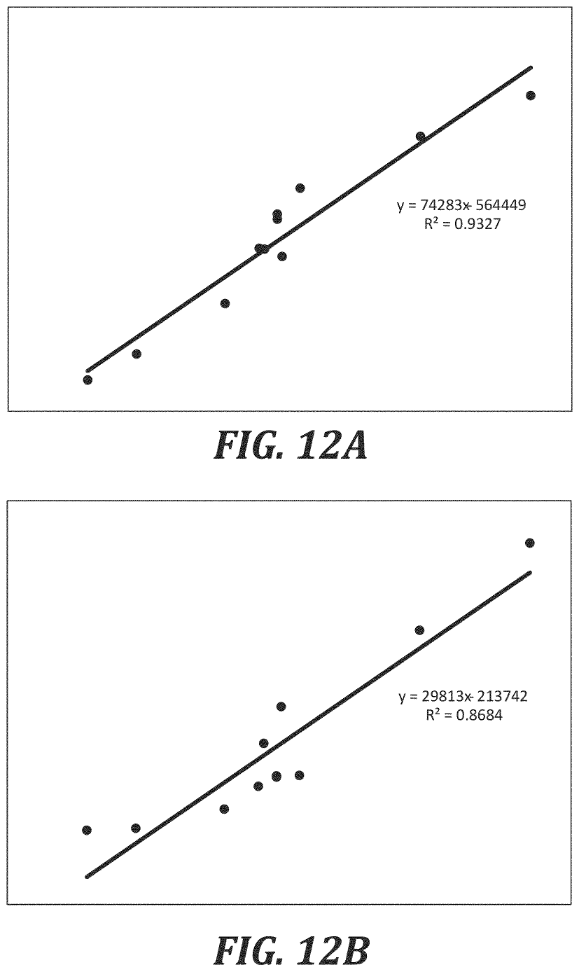

Eleven single crystal data points were used with Equations (15) and (18) to fit C1, C2, C3, C4 and W, which can in turn be used to calculate ΔH_{PZ}, ΔH_{PT}, T_{PZ}, T_{PT}. For phase diagram and free energy curve construction, fitted constants can simply be put back into Equation (11). Equations (15) and (18) gave slightly different values of W so the two fits were redone with W the same in both, varying until the total R² of the fits was minimized. This turned out to be the same as the fit to Equation (15). These two fits are shown in FIGS. 12A and 12B.

The fitted parameters are compared to literature data values in TABLE V.

TABLE V
Fitted thermodynamic data for PbO-PLP and PbO-Pb₄P
solvents compared to literature data. Literature ΔH_{PZ},
ΔH_{PT} and W data were taken by Rane and
Navrotsky at 700° C. from a sodium molybdate solvent.

| Parameter | PbO-PLP | PbO-Pb₄P | Literature | Reference |
|---|---|---|---|---|
| ΔH_{PZ} (J/mol) | −104,096 | −75,883 | −83,500 | [13] |
| ΔH_{PT}(J/mol) | −29,813 | −23,864 | −11,000 | [13] |
| W (J/mol) | 20,571 | 16,788 | 39,800 | [13] |
| T_{PZ} (° C.) | 1491.5 | 1479.1 | 1500* | [14] |
| T_{PT} (° C.) | 1025.9 | 911.0 | 993⁺ | [13] |
| ΔS_{PZ} = −ΔH_{PZ}/T_{PZ} | 59 | 43 | 66 | [13, 15] |
| (J/mol-K) | | | | |
| ΔS_{PT} = −ΔH_{PT}/T_{PT} | 23 | 20 | 17.4 | [13, 16] |
| (J/mol-K) | | | | |

*[Zr]/[all constituents]
⁺[Ti]/([Pb] + [Ti]
[13] M. V. Rane and A. Navrotsky, “Enthalpies of Formation of Lead Zirconate Titanate (PZT) Solid Solutions,” J. Solid State Chem. 161 (2001) 402.
[14[ S. Fushimi and T. Ikeda, “Phase Equilibrium in the System PbO-TiO₂-ZrO₂,” J. Am. Ceram. Soc., 50 (1967) 129. as reprinted in Phase Diagrams for Ceramists #02330, NIST and ACERS.
[15] R. L. Holman and R. M. Fulrath, “Intrinsic nonstoichiometry in the lead zirconate-lead titanate system determined by Knudsen effusion,” J. Appl. Phys., 44 (1973) 5227.
[16] J. R. Soh, H. M. Lee, and H. S. Kwon, CALPHAD: Comput. Coupling Phase Diagrams Thermochem., 18 [3] 237-244 (1994) as reprinted in Phase Diagrams for Ceramists #EC-121, NIST and ACERS.

Enthalpy of solution and mixing data AHPZ, AHPT and W taken by Rane and Navrotsky at 700° C. from a sodium molybdate (3Na₂O-4MoO₄) solvent are consistently ~20,000 J/mol higher than in PLP. This may result from temperature dependence as current data were taken at much higher temperatures or may result from the difference in solvent used. The fitted data were taken as constant in the following phase diagram construction, but a temperature dependence would not make any qualitative difference. The decrease in the mixing parameter in the solid, W, is important in the present application as the present value of W is just at the edge of resulting in phase separation under the growth conditions. The value of Rane and Navrotsky would likely result in phase separation.

The saturation temperature Trz of PZ in PLP is consistent with the PbO—ZrO₂ phase diagram in FIG. 2A, using the ratio [Zr]/[all constituents] while the value for TPT is consistent with the PbO—TiO₂ phase diagram, using the ratio of [Ti]/([Pb]+[Ti]) omitting other constituents. This suggests that the method of solubility differs between the two.

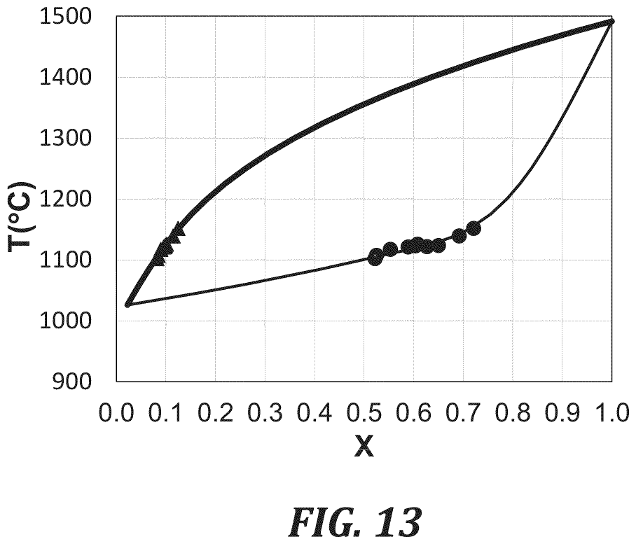

Equations (15) and (18) are sufficient to define the solidus and liquidus curves. While there is no straightforward closed form solution, these equations may be solved simultaneously numerically to allow the construction of the phase diagram in FIG. 13.

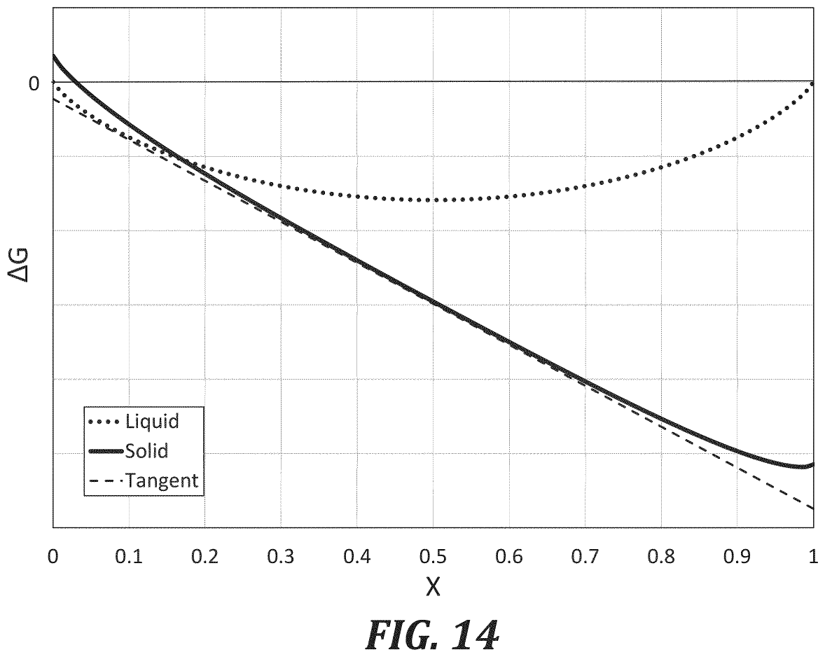

The free energy curves can be constructed as well from this data. FIG. 14 shows the optimum set of curves for the target composition X_{S}=0.52. Qualitatively they are somewhere between FIGS. 10A and 10B and FIGS. 11A and 11B. This type of curve can produce what is called an indifferent point (in liquid vapor phase diagrams it is called an azeotrope) that can result in a congruently melting minimum at some composition extrapolating to near X_{L}≈0.02 here. This system may or may not have a phase separation at a lower temperature below the measurements taken but the extrapolation and shape of the free energy curves are suggestive that there is no two-phase region in equilibrium. This involves precise temperature and composition control to grow the MPB composition in the middle of the phase diagram.

The solid free energy curve in FIG. 14 is flattened by the positive enthalpy of mixing to the point that the tangent line is barely distinguishable over a wide range (it had to be intentionally offset very slightly in this figure to be visible). There is not a large enough enthalpy of mixing contribution that it goes retrograde and creates phase separation as in FIGS. 11A and 11B. It is, however, very close, which explains a variety of results by past and current authors who did observe phase separation under slightly different conditions, different temperatures and with different solvents. Notably, this formulation gives specific guidance on growth conditions to reduce the magnitude and effect of the positive heat of mixing and therefore avoid phase separation. This guidance has been incorporated into the current process.

In this process of limited range slow cooling, the growth moves down the liquidus curve of the phase diagram (light curve in FIG. 13) as the temperature ramps downward, growing crystals with a composition at the solidus (heavy curve in FIG. 13) also moving downward and toward PT. This results in a compositional gradient in the crystal but if the total amount of slow cooling is limited, the compositional gradient is also small

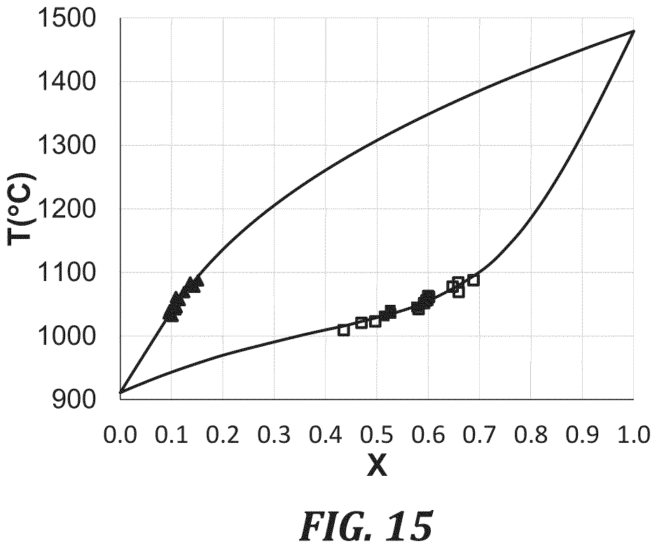

FIG. 15 shows how the change to the Pb₄P solvent changes the phase diagram, again at C=5%. The data was normalized according to T(norm)=T-3,400 (C-0.05)-74 (Pb—Pb₀), where the compositional coefficient is the same, but the lead coefficient is of the opposite sign as in PLP. Lead acts as both a part of the solvent and part of the solute with some balance that appears to be different in the two solvents being more a solvent in PLP and more a solute in Pb₄P. In either case the correction is small.

The Pb₄P liquidus is the same for polycrystals on the paddle grown quickly and single crystals grown slowly, but they differ in the solidus because the change in growth rate influences the effective distribution coefficient. The single crystal data is shifted slightly since the polycrystals grow faster and the effective distribution coefficients move closer to unity. However, the polycrystal data could be normalized to the single crystal curve by using the Ti distribution coefficients discussed below for each and the resultant normalized polycrystal data is plotted with the single crystal data and used for the phase diagram free energy calculations and fitting. The curves clearly are lower in temperature than the PLP data by an estimated 85° C. compared to PLP. This lower temperature has the advantages that 1) Growth can be done at a lower temperature, which results in less PbO evaporation and is less stressful on the furnace. 2) there is improved crystal quality from Pb₄P. A new fit to the equations has been done for Pb₄P and is compared to the PLP fit in TABLE V. The values for AHPz and AHPT are ~5,800 J/mol higher (less negative) while the value of W is 3,783 J/mol lower, which reduces the tendency to phase separate. These values then are dependent on the solvent, explaining the differences from Rane as well. PBO—B₂O₃ SOLVENT

PbO—B₂O₃ is a commonly used solvent system and Xie used this successfully to grow small MPB PZT crystals (Y. Xie, “Synthesis and Characterization of Piezo-ferroelectric Lead Zirconate-Titanate (PZT) Single Crystals and Related Ternary Ceramics,” Ph.D. thesis, Simon Fraser University, 2013). Boron oxide (B₂O₃) is known to attract excess oxygen to form BO_{y}^{3-2y} species, where y is commonly given as 3. In the present study, B₂O₃ was added to a PbO solvent up to 20 cation % (11 mole %) alone and in combination with P₂O₅ and the following results were observed.

Addition of B₂O₃ reduces the solute activity a of both ZrO₂ and TiO₂ in approximately equal amounts according to the equations a (ZrO₂)=[ZrO₂](1-c[BO₃]) and a(TiO₂)=[TiO₂](1-c[BO₃]) where c≈3.6 up to an addition of 10 cation %. In a previous study by the present inventor, it was found that B₂O₃ addition reduces rare earth activity in PbO solvents up to 15% B₂O₃ with a coefficient c=4.6 (V. J. Fratello, S. J. Licht, and M. P. Norelli, “Effect of Composition on Bi Incorporation in Iron Garnets,” J. Cryst. Growth 97 (1989) 657.), which is similar. This could occur by borate cations complexing with Zr and Ti ions to form borate clusters that are chemically inactive or by the borate ions increasing the solution power of Pb²⁺ by complexing O²⁻. Possible borate molecular clusters/second phases with ZrO₂ include PbZr(BO₃)₂ (observed by Lazar as well) and Zr₃(BO₃)₄.

The distribution coefficient of Ti with respect to Zr remained the same, as will be discussed below, indicating the effect of the borate on the activity of the two components was approximately equal.

An addition of 20 cation % B₂O₃ caused the precipitation of borate phases. The melt with no B₂O₃ had such a high density and high melting point that crystals of undetermined composition were lighter and floated on the surface.

Because previous data was sufficient to establish growth conditions, a variety of experiments were attempted without a constant concentration as would be needed for a phase diagram as those determined for the phosphate solvents, but the collective data were sufficient to be extrapolated to a phase diagram as will be discussed below.

### Distribution Coefficient

The phase diagrams above show pairs of compositions of the melt and the crystal that correspond to each other at a given concentration (5%) and temperature. A common way of viewing this is as one component having a distribution coefficient with respect to the other. Initially it was attempted to determine either a Zr distribution coefficient with respect to Ti or a Ti distribution coefficient with respect to Zr, which, for example, would usually be expressed as:

$$k ( Zr ) = \frac{\frac{{[ Zr ]}_{S}}{{[ Zr ]}_{S} + {[ Ti ]}_{S}}}{\frac{{[ Zr ]}_{L}}{{[ Zr ]}_{L} + {[ Ti ]}_{L}}} = \frac{{X}_{S}}{{X}_{L}} or \qquad ( 25 )$$

$$k ( Ti ) = \frac{\frac{{[ Ti ]}_{S}}{{[ Zr ]}_{S} + {[ Ti ]}_{S}}}{\frac{{[ Ti ]}_{L}}{{[ Zr ]}_{L} + {[ Ti ]}_{L}}} = \frac{1 - {X}_{S}}{1 - {X}_{L}}$$

where square brackets indicate concentrations and subscripts S and L indicate the solid (crystal) and the liquid (melt). These relations were seen to be nonlinear and, since Ti is the majority octahedral constituent by a factor of 9-10 in the melt, k (Ti) deviates only slightly from unity no matter how much the composition changes and does not reflect the physical reality.

A better model is to view the growth as crystal growth of Ti-doped PZ. Equation (28) for the distribution coefficient of Ti with respect to Zr is similar to what is used to describe the very low distribution coefficient of solvent atoms into a solute. The higher thermodynamic stability of PZ makes it likely to be the host species. But Ti is nevertheless a favorable dopant rather than a trapped impurity because PT is thermodynamically stable as well.

$$k ( Ti ) = \frac{\frac{{[ Ti ]}_{S}}{{[ Ti ]}_{S} + {[ Zr ]}_{S}}}{\frac{{[ Ti ]}_{L}}{{[ Zr ]}_{L}}} = \frac{1 - X}{\frac{{[ Ti ]}_{L}}{{[ Zr ]}_{L}}} \qquad ( 26 )$$

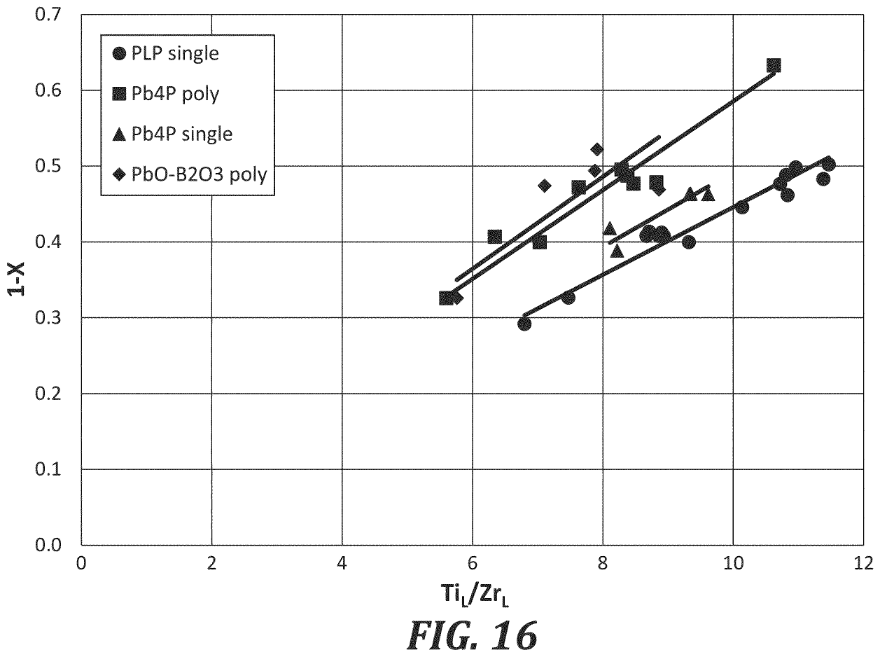

As discussed above, the rapid growth polycrystalline runs are much more likely to trap more Ti giving a higher distribution coefficient approximately 25% greater. The trapping reduces the tendency to phase separate, at least at the macroscopic level. FIG. 16 shows that the single crystal and polycrystal distribution coefficients k(Ti) are constant within experimental accuracy among different solvent systems. The distribution coefficient fits of the various lines are given in TABLE VI. These data were used to normalize polycrystalline data to the single crystal value as was used in FIG. 15 and to determine the parameters in TABLE V.

TABLE VI
Distribution coefficient k(Ti) slopes from FIG. 16.

| Solvent-crystal type (symbol) | k(Ti) |
|---|---|
| PLP solvent-single crystal (black circles) | 0.045 |
| Pb₄P solvent-single crystal (black triangles) | 0.049 |
| Pb₄P solvent-polycrystal (gray squares) | 0.059 |
| PbO-B₂O₃ solvent-polycrystal | 0.061 |
| (gray diamonds) | |

The literature values that can be extracted vary wildly with Fushimi (0.023) and Clarke (0.02) having significantly lower values and the others being much higher 0.26-0.62 all probably from mixed phase systems.

### Solute Solubility

In an embodiment, for any given solvent and constant solidus composition X, the saturation temperature T_{S} is a function of [TiO₂]_{L}.

In an embodiment, for any given solvent and constant saturation temperature Ts, the solidus composition X is a function of [TiO₂]_{L}.

The phase diagram work above would be time consuming to reproduce for varying solvents, solvent proportions, solute concentrations, and solute proportions. Fortunately, an empirical formation has been developed that fits all the data taken and extrapolates well to the phase diagrams of FIG. 2. Molecular complexes such as PLP, Pb₄P, etc. participate much less in the solubility of ZrO₂ and TiO₂ so the excess or free PbO concentration in PbO—PLP and PbO—Pb₄P solvents was used. The cation liquid concentrations of [ZrO₂]_{L}, [TiO₂]_{L}, [PbO]_{free} and [BO₃] were fit to the saturation temperature data yielding the following equation:

$${T}_{S} = 997 - {360 [ PbO ]}_{f r e e} + ( {29100 [ {ZrO}_{2} ]}_{L} + {1423 [ {TiO}_{2} ]}_{L} ) ( 1 - 3.6 [ {BO}_{3} ] ) \qquad ( 27 )$$

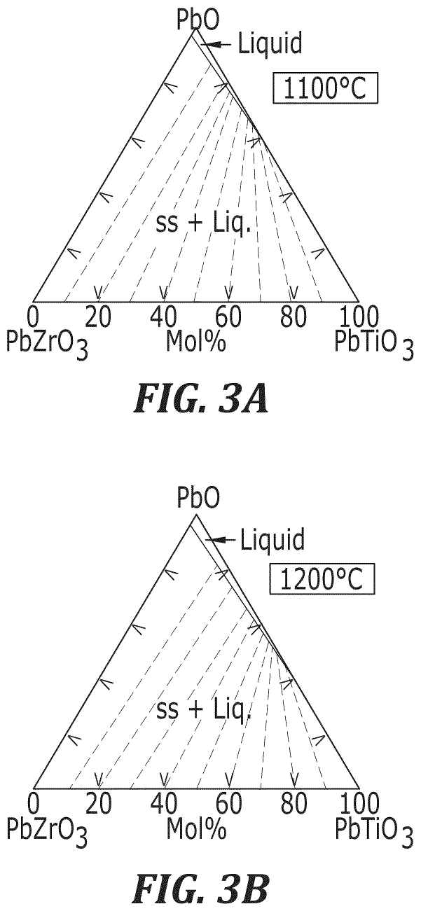

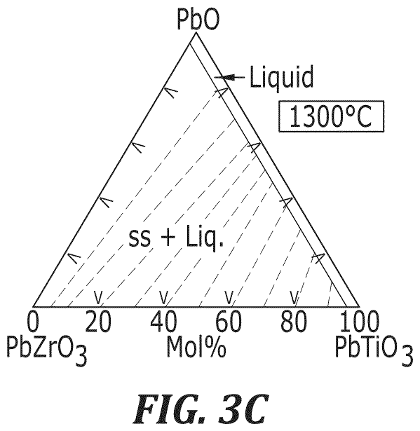

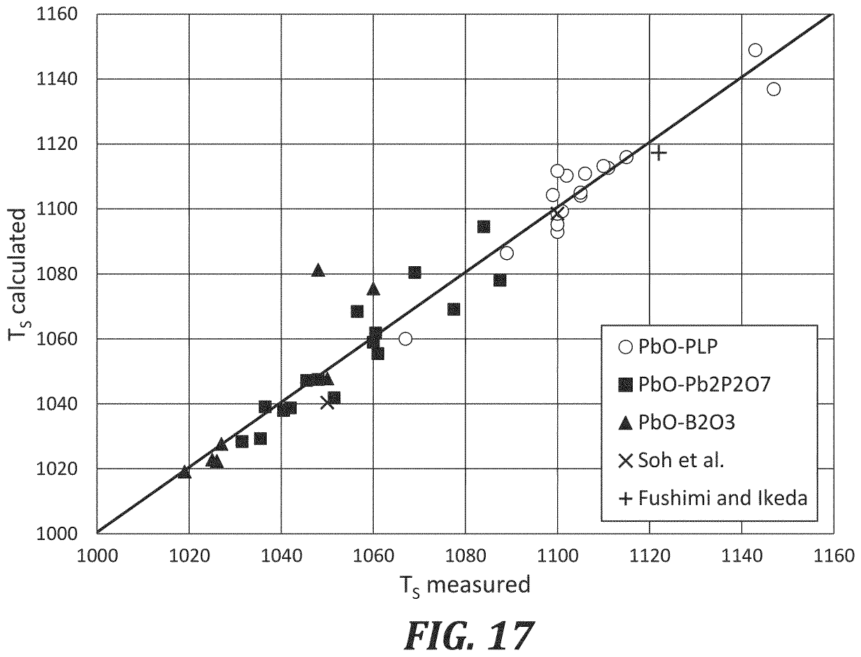

This equation was adjusted slightly to be consistent with the results of Soh, Lee, and Kwon in FIG. 2B when extrapolated to a PbO—TiO₂ solution. This simple equation provided a better fit to all the data in this work and the literature than any other including an Arrhenius-type relation, and also yielded a sensible phase diagram when coupled with the distribution coefficient. Fushimi and Ikeda had a data point of [ZrO₂]=0.163 at 1122° C. for PbO—ZrO₂ and this equation gives 0.1645 at the same temperature. It is also consistent with the liquidus of FIGS. 3A-3C. Calculated saturation temperatures are plotted against measured ones in FIG. 17 and the results are accurate to within the temperature error bars of +15° C. It will be understood that this remains empirical over this range and a complete model involves use of free energy curves.

Equation (27) can also be inverted to get an expression for [ZrO₂]_{L}. This is simplest for a pure PbO solvent where [PbO]_{free}=1−[ZrO₂]_{L}−[TiO₂]_{L}.

$${[ {ZrO}_{2} ]}_{L} = ( - 6 \; 37 + {T}_{S} - {1783 [ {TiO}_{2} ]}_{L} ) / 29460 = A + {BT}_{S} + {D [ {TiO}_{2} ]}_{L} \qquad ( 28 )$$

where A=−0.02162, B=0.00003394 and D=−0.06052. The concentration of [ZrO₂] L increases with Ts, decreases with [TiO₂] L and is not determined by anything else.

When extrapolated to a solution with no free PbO, the cation % of solute [ZrO₂]_{L}+[TiO₂]_{L} for an MPB composition is ¼ that of a solution with only free PbO as the solvent. On a molar basis for the molecular solvents, this is closer to 1 but was not the same for the three cation PLP as the four cation P₄P. There is a temptation to try to include a term for the molecular solvents in the equation, but it is not an independent quantity, being given as one minus all the other constituents.

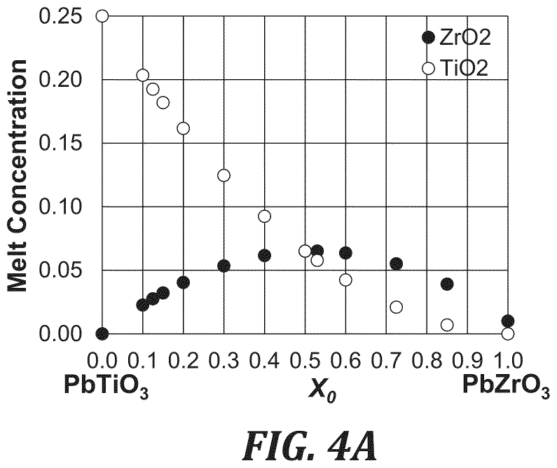

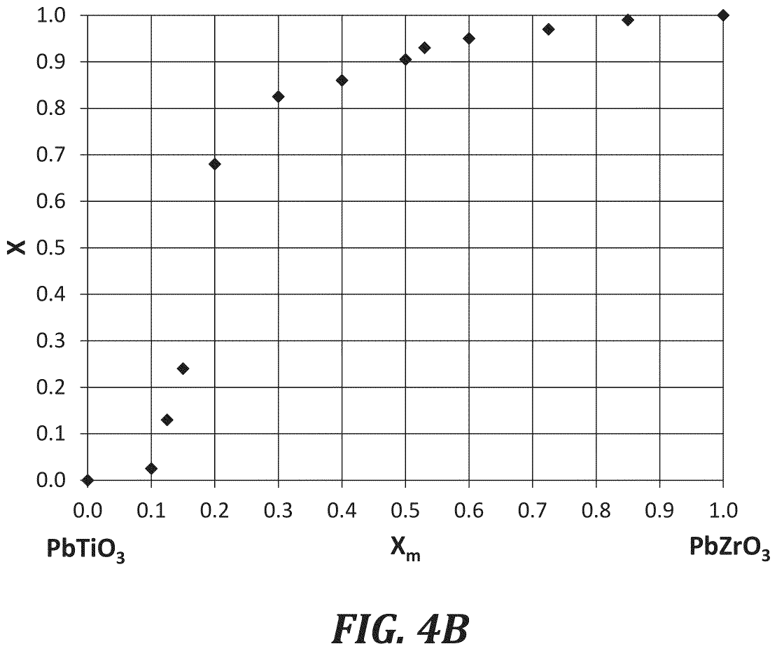

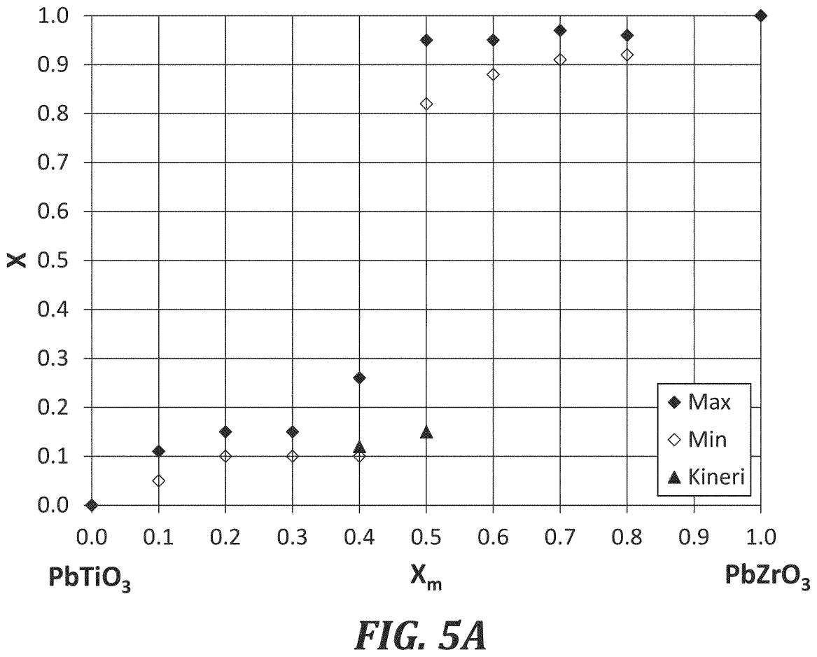

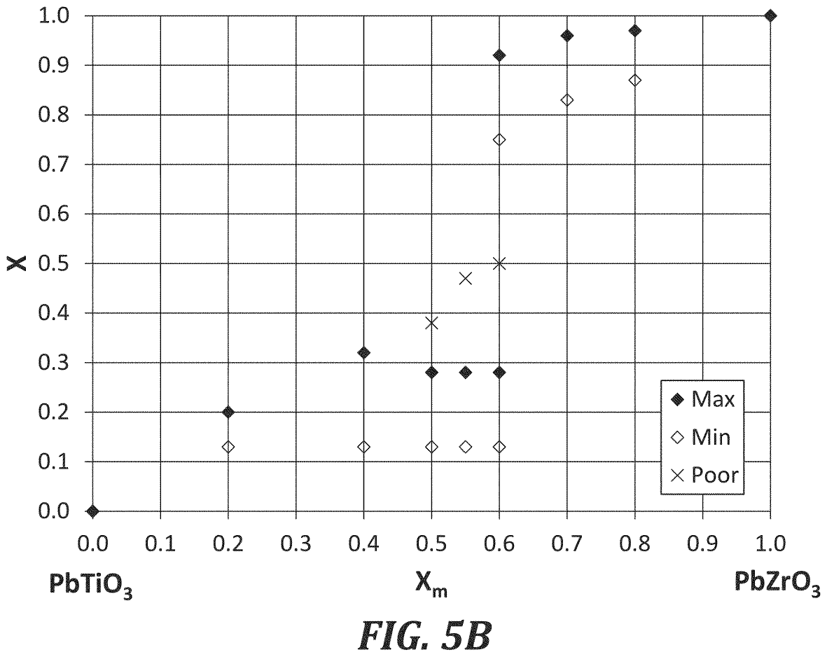

Both ZrO₂ and TiO₂ increase the saturation temperature but the influence of [ZrO₂] on the saturation temperature is 20 times that of [TiO₂]. Since the concentration of [TiO₂] is approximately 10 times that of [ZrO₂] for growth of crystals at the MPB composition, the saturation temperature is substantially higher than in a melt with only the same concentration of [ZrO₂]. At any given saturation temperature, the addition of TiO₂ decreases the solubility of [ZrO₂] in contravention of the assumption of Clarke and Whatmore and FIG. 4A.

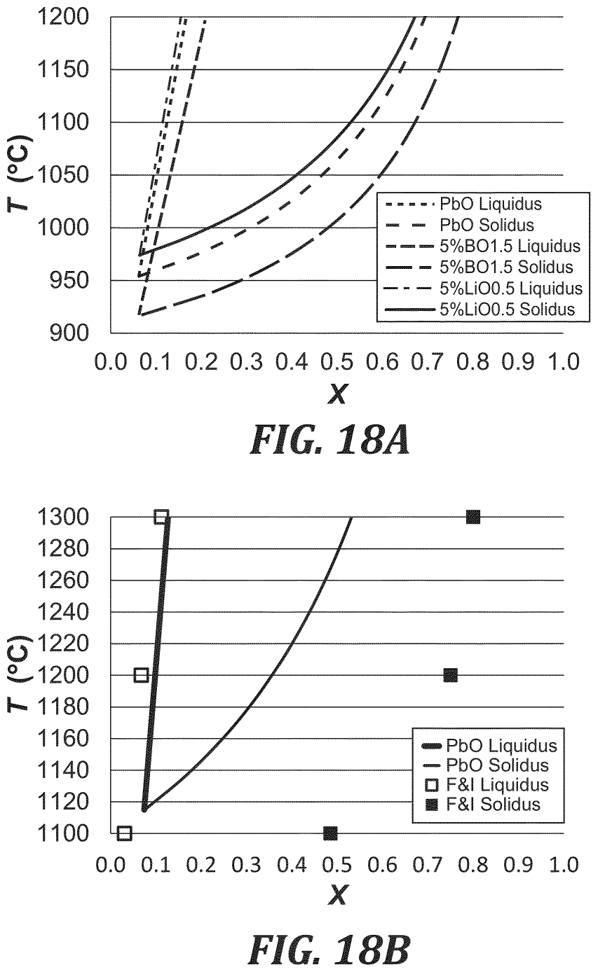

Using the saturation temperature and distribution coefficient data, FIGS. 18A and 18B show the calculated solidus and liquidus curves for PbO, PbO-5 cation % BO₃, and PbO-5 cation % Li₂O solvents with C=10 cation % [ZrO₂]+[TiO₂]. The higher concentration was used because of the higher solubility than in the phosphate solvents. The slope of T versus X is notably higher on the solidus branch than in the phosphate solvents as will be discussed quantitatively below, so the growth composition uniformity will be more forgiving of variations in temperature.

Solving Equation (26) for [ZrO₂]_{L} and inserting that into Equation (27) yields an expression for T_{S} in terms of only [TiO₂] L for any given solvent composition.

$${T}_{S} = 997 - {360 [ PbO ]}_{f r e e} + {( 29100 k ( Ti ) / ( 1 - X ) + 1423 ) [ {TiO}_{2} ]}_{L} ( 1 - 3.6 [ {BO}_{3} ] ) \qquad ( 29 )$$

For a PbO-only solved melt with k(Ti)=0.05, this reduces to two relations among T_{S} and X depending only additionally on [TiO₂]_{L}. The simple linear dependence in Equation (30) is an artifact of [ZrO₂]_{L} being proportional to [TiO₂]_{L} in Equation (29) for a constant X and solvent. A free energy derivation will likely be more complex.

$${T}_{S} = 637 + {( 1783 + 1482 / ( 1 - X ) ) [ {TiO}_{2} ]}_{L} \qquad ( 30 )$$

$$X = 1 - \frac{1}{\frac{( {T}_{S} - 637 )}{{1482 [ {TiO}_{2} ]}_{L}} - 1.203} \qquad ( 31 )$$

### Eutectic Position and Curve Slope

The behavior seen can be described as follows. Since PZT is a solid solution, there is a mixture of Zr and Ti on the octahedral site. Solid solutions can have full solubility between the end members if the enthalpy of mixing is zero or negative, or have a eutectic with phase separation in the middle of the phase diagram if the enthalpy of mixing is positive and large. Rane and Navrotsky showed that PZT has a positive enthalpy of mixing, but it is not seen to phase separate in ceramics at a macroscopic level. Of course, the chemical-mechanical means of manufacture of PZT ceramics are highly non-equilibrium.

High temperature solution growth is much closer to equilibrium and therefore can be subject to phase separation of the crystals into Ti and Zr-rich phases depending on the magnitude of the positive enthalpy of mixing, which is seen to depend on the solvent here. In a PbF₂ solvent in Fushimi and Ikeda there was a transition between Zr-doped PT and Ti-doped PZ regimes with mixtures seen of the two end-member solid solutions and a miscibility gap with phase separation in a specific melt concentration range, though rapid quenching yielded some small, poor-quality crystals in the gap. The desired near-equimolar morphotropic phase boundary (MPB) composition PbZr_{0.52}Ti_{0.48}O₃ with x =0.52 (52 mole % PZ) was not thermodynamically accessible. The enthalpy of mixing parameter in the solid W has been shown to be solvent dependent in TABLE V and could be even larger for the fluoride solvents.

In the Clarke and Whatmore results in a PbO solvent, crystal compositions of approximately 24-68 mole % in the phase separation gap were not accessible, but this may simply have been because of the errors in melt formulation and very wide mesh of their starting compositions compared to the narrow range determined in the present disclosure. The Clarke model of solubility with the assumption that the addition of TiO₂ increases the melt solubility of ZrO₂ is fundamentally incorrect. In fact, the opposite occurs. This likely results in part from the positive enthalpy of mixing resulting in a tendency to phase separate.

If this pseudo-eutectic is near the center of the phase diagram as in fluoride solvents, the desired near-equimolar MPB composition is not achievable because of phase separation. The contrasting results in fluoride and PbO solvents show that the choice of solvent can move the location of the eutectic transition in part through variation of W. A solvent formulation and growth conditions where the eutectic between Zr: PT and Ti: PZ is near the PT end of the phase diagram away from the growth point and, if possible, there is a lower positive enthalpy of mixing will reduce the tendency to phase separate. For such a system, Ti-doped PZ can be grown with a range of ZrO₂ concentrations X that includes the desired X=0.52. This involves poorer solubility for ZrO₂ and/or higher solubility of TiO₂. Fluoride solvents do the opposite with higher ZrO₂ solubility moving the transition nearer to the MPB range 40-50 mole % PZ (in addition to being unacceptably volatile) and resulted in a higher degree of phase separation. Clarke and Whatmore showed what could be a miscibility gap in the range X_{L}=0.15-0.20 for PbO (this will be discussed later) but the current study extrapolates to an indifferent point at X_{L}=0.03 for a pure PbO solvent, which is desirable since the X_{L} to grow MPB crystals is ~0.094.

The solubility of zirconium oxide varies strongly among solvents ranging from very high (similar in magnitude to the solubility of TiO₂) in PbF₂ to very low in various molecular lead salts such as lead lithium phosphate PbLiPO₄ (PLP). A moderate solubility around C=0.1 or 10% was found to work best. It is desirable for the solidus to have as high as possible a slope to buffer against temperature variations. TABLE VII shows how the concentration C at 1050° C. and slope dXs/dT vary in the solvents of this study. The lower the slope, the less sensitive the crystal growth is to variations in temperature including supercooling and slow cooling if used. For PbO and PbO-5% BO₃ solvents a 3° C. variation in growth temperature results in only 0.01 variation in X, which is acceptable uniformity.

TABLE VII
Solvent Curve Properties

| Solvent | C(1050° C.) | dXs/dT(° C.⁻¹) | Solvent type |
|---|---|---|---|
| PLP-PbO | 0.026 | 0.014 | Molecular |
| Pb₄P-PbO | 0.052 | 0.007 | Molecular |
| PbO | 0.084 | 0.003 | Ionic |
| PbO-5% Li₂O | 0.090 | 0.003 | Ionic |
| PbO-5% BO₃ | 0.111 | 0.003 | Mixed |

The higher solute concentration in the boron oxide-containing melt is somewhat illusory. While more ZrO₂ and TiO₂ can be dissolved, their activity remains the same as the added amounts are effectively complexed with BO₃ and therefore do not participate in crystal growth processes.

### Melt Formulation

### Non-Equilibrium Two-Phase Melts

If more solute is added to a melt than is permitted by the solubility curve or the melt is cooled below the saturation temperature, then PZT crystals will precipitate, grow, or be deposited with composition according to the phase diagram. Under conditions of slow cooling a variety of compositions may be deposited as the melt proceeds down the liquidus curve so slow cooling experiments can only produce thermodynamic equilibrium crystals over a very narrow range of growth conditions with small overall changes in temperature.

Halide (fluoride and chloride) solvent melts have a high enough solubility for zirconium oxide that some of the previous studies may have achieved full solubility of the solutes before cooling to form crystals. Additionally, the high vaporization rates of these solvents also give constantly varying conditions. The similar solubilities of ZrO₂ and TiO₂ in halides will result in the solidus free energy curve being horizontal so the flat portion will result in an abrupt transition from Zr: PT to Ti: PZ resulting in an effective phase separation.

However, with the understanding of the current solubility curve, it can be concluded that all previous studies in PbO/Pb₃O₄ and PbO—B₂O₃ solvent melts contained too much nutrient to dissolve fully at the equilibration temperatures used. The evaporation rate of PbO should be controlled to produce sufficient thermodynamic equilibrium but this can be done in multiple ways. Two previous studies that are relevant are reviewed below.

### Clarke and Whatmore

Clarke and Whatmore (R. Clarke and R. W. Whatmore, “The Growth and Characterization of PbZr_{X}Ti_{1-X}O₃ Single Crystals,” J. Cryst. Growth 33:29 (1976)) made a mistaken assumption in their equation (1) that melts should follow a compositional series ([ZrO₂]ₑ[TiO₂]₁₋ₑ)_{1-y} [PbO]_{1-y} per FIG. 4A and TABLE III. The effect of this relation is that the solubilities of [TiO₂]_{L} and [ZrO₂]_{L} are assumed to interact positively in a PZT high temperature solution in an excess of lead oxide as a solvent such that the addition of TiO₂ increases the solubility of ZrO₂ with [ZrO₂]_{L} peaking at 0.065, which is more than six times the solubility of ZrO₂ with no TiO₂ present. The current results show this produces very high saturation temperatures hundreds of degrees above the equilibration temperature of 1170° C. Therefore, these melts contain both solid and liquid phases even at the equilibration temperature and the bulk of the crystals grown probably occurred during the equilibration phase. It is also clear from the results that these melts never come to equilibrium as they are only equilibrated for a relatively short period and the results are inconsistent with equilibrium data.

In an embodiment, a self-consistent free energy interpretation of the data has been developed in the following way.

Assuming the measurements of Clark and Whatmore are correct, a partition between the solid and the liquid at the equilibration temperature of 1170° C. was determined by removing an amount of solid with composition X from the mixture such that the remaining liquid portion had a saturation temperature of 1170° C. according to Equation (29). The amount of solid removed Cs and the remaining [ZrO₂]_{L} and [TiO₂]_{L} in the liquid are given in TABLE VIII. This is not an equilibrium state; the formulation merely uses the values given by Clarke and Whatmore.

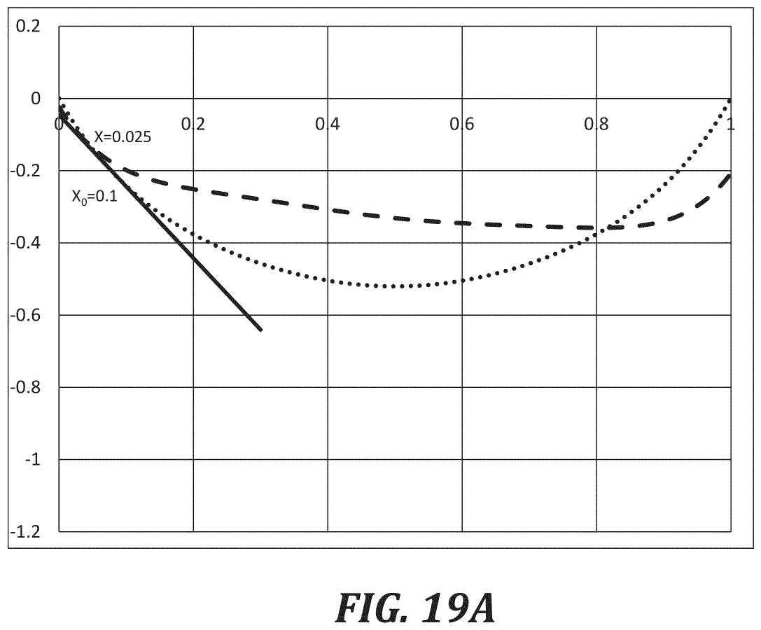

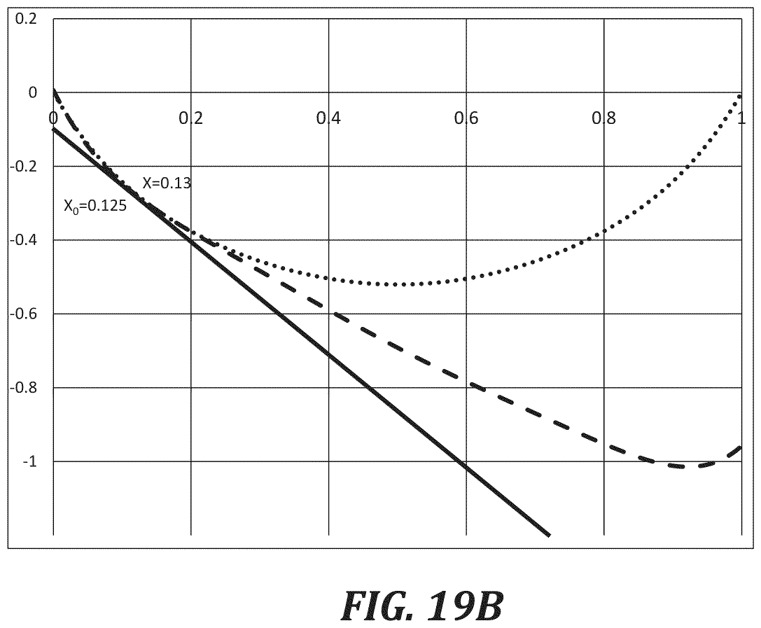

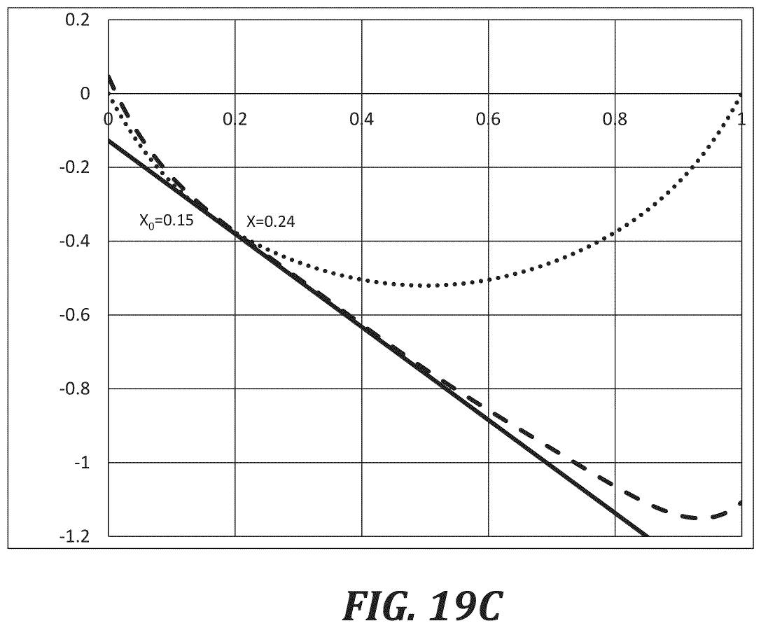

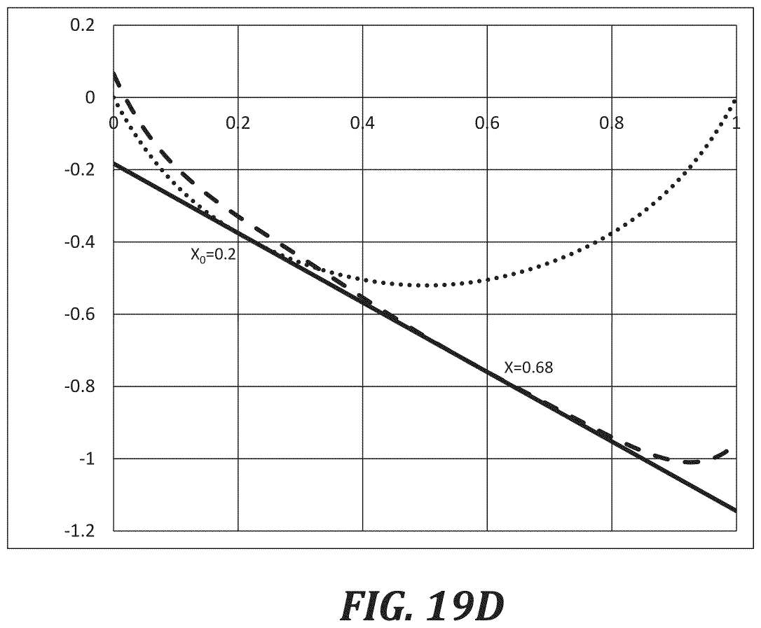

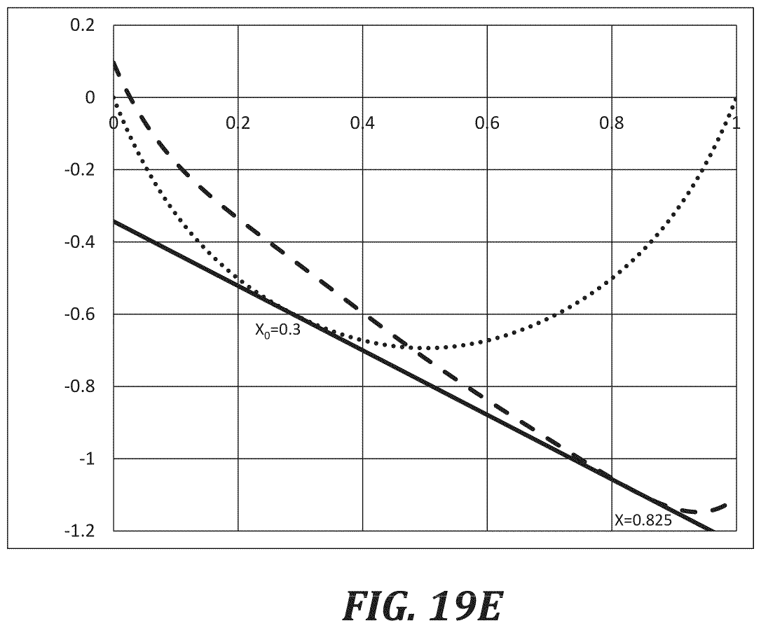

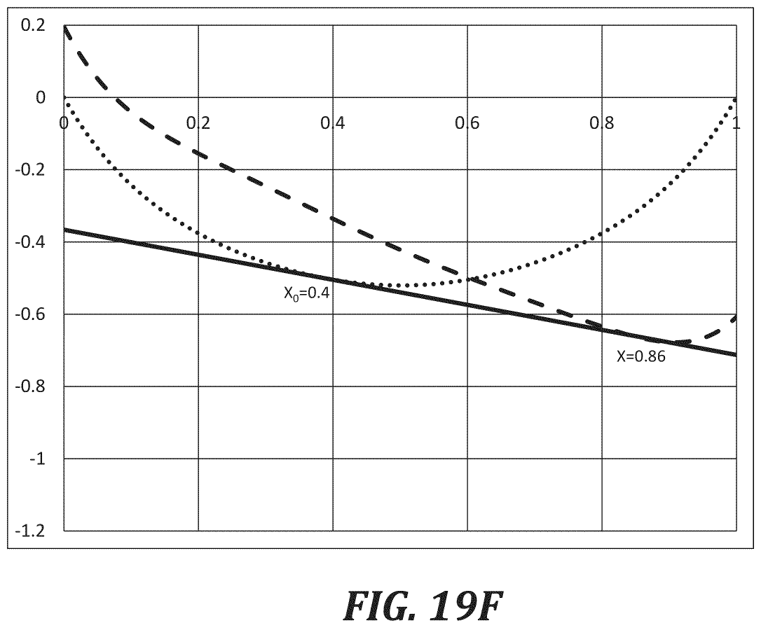

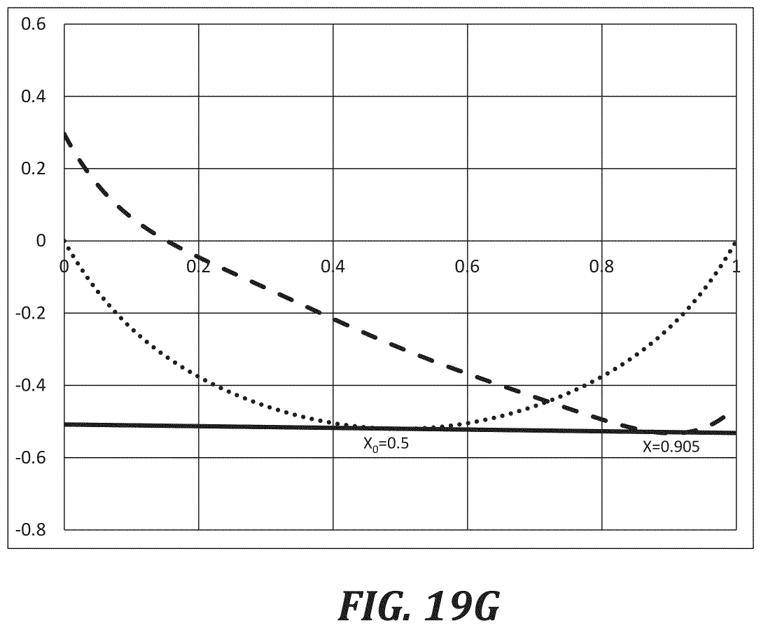

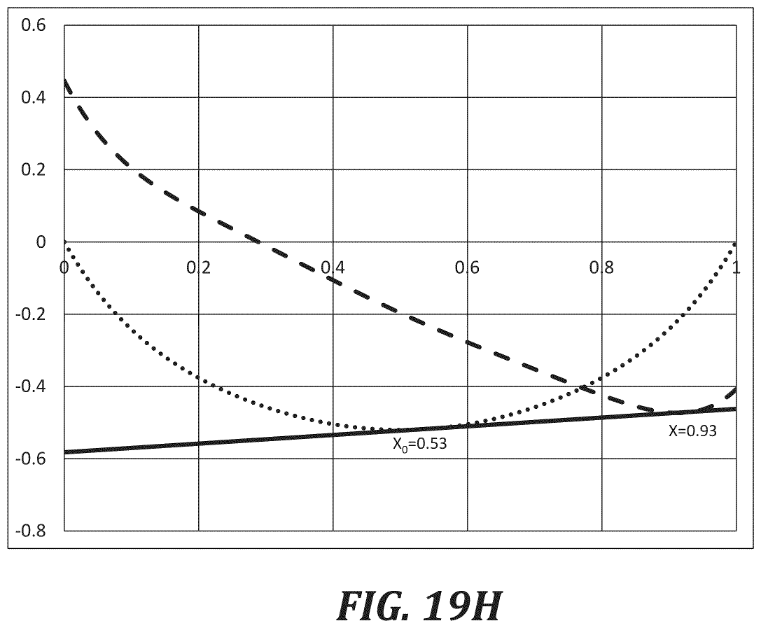

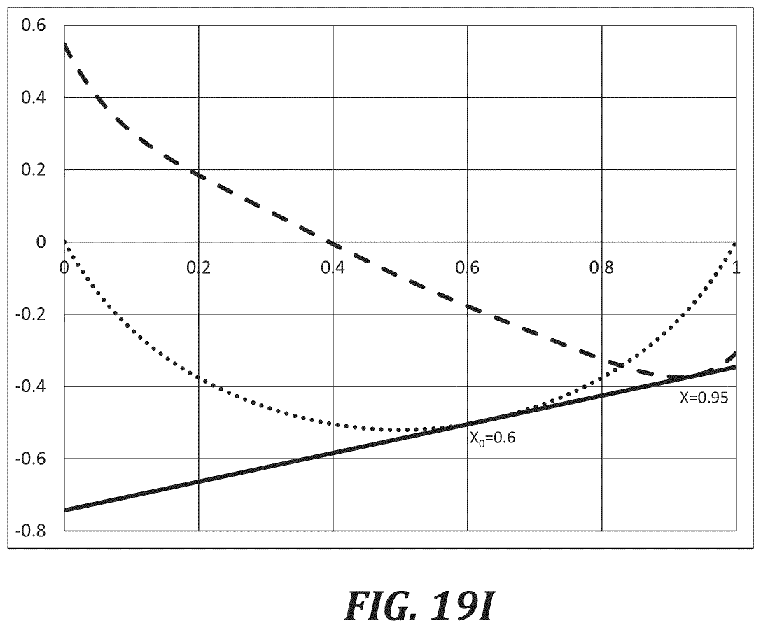

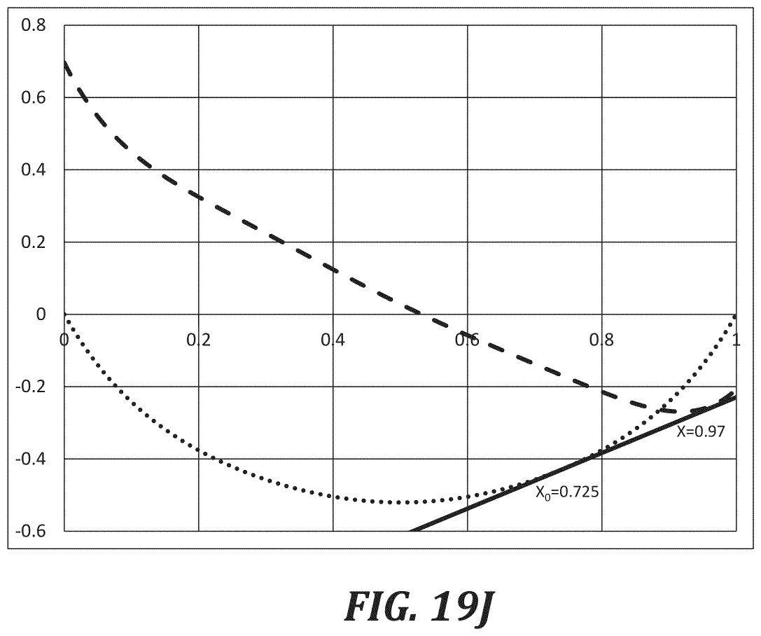

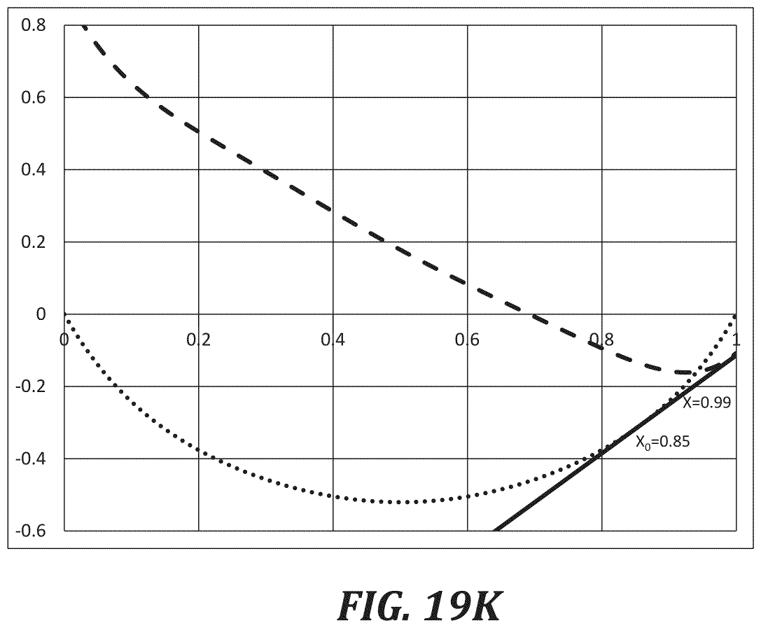

A schematic free energy diagram was developed using this data. The entropic free energy of the initial mixture per Equation (7) was plotted identically on all the free energy diagrams (dotted line) in FIGS. 19A-19K. Because this mixture cannot be characterized as a liquid, it is just interpreted to be a mixture of powders with a value of X₀ according to TABLE VIII. The end member values for the solid energy are scaled by the relation of CL to the saturation values of pure [ZrO₂]_{L} and [TiO₂]_{L}. This was successful except for the 0.1 data point, which had to be adjusted. The likely cause is unidentified phase separation with Ti-doped PZ particles being too small to identify as crystals. The solid free energy curve in between these end member values (dashed line) is the sum of the entropic free energy and a positive enthalpy of mixing according to Equation (6) given by an optimized value W for this system. This is flattened as seen in FIG. 14. A mutually tangent tie line between the two curves (gray solid line) should be tangent to the initial mixture curve at X₀ and to the solid curve at X in TABLE VIII.

This yields the plots in FIG. 19. This is different than the standard formulation that would give this relation between the final liquid and the final solid in complete thermodynamic equilibrium, but it is clear that a metastable equilibrium with the initial mixture occurs likely because of the thermal path to reach this outcome. There appear to be two different regimes. For the low Zr/high Ti values, the distribution coefficient acts as if it is growing Zr-doped PT with a relation that suggests that only the ZrO₂ above some threshold value is incorporated in the characterized crystals with a linear distribution coefficient, possibly due to phase separation. This gives relatively low X. For the high Zr/low Ti values, the melt appears to grow Ti-doped PZ as in the present disclosure. Most of these melts had a similar amount of Zr in solution and varied the Ti with the precipitating crystals highly segregating Zr. If the deposited PZT crystal composition is estimated and removed, the distribution coefficient slope is kri≈0.05 as in the present study. This gives relatively high X's. The split between these does not appear to be a phase separation/eutectic but rather an artifact of the very flat region in the solid free energy curve caused by the positive enthalpy of mixing and the coarse mesh of the X₀ values. The result at X₀=0.13 with a nearly identical X to the starting material has the appearance of a congruent point, but this is only because the system is not in thermodynamic equilibrium.

TABLE VIII
[PbO]_{(1-C0)}[ZrO₂]_{C0X0}[TiO₂]_{C0(1-X0)} melts from
Clarke and Whatmore per TABLE III with the amount of solid
removed Cₛ and the remaining C_{L} = [ZrO₂]_{L} +
[TiO₂]_{L} in the liquid shown.

| X₀ | [ZrO₂]₀ | [TiO₂]₀ | C₀ | X | C_{S} | C_{L} | [ZrO₂]_{L} | [TiO₂]_{L} |
|---|---|---|---|---|---|---|---|---|
| 0.00 | 0 | 0.250 | 0.250 | 0.00 | | | | |
| 0.10 | 0.023 | 0.203 | 0.226 | 0.03 | 0.200 | 0.026 | 0.018 | 0.008 |
| 0.13 | 0.028 | 0.193 | 0.220 | 0.13 | 0.115 | 0.105 | 0.013 | 0.092 |
| 0.15 | 0.032 | 0.182 | 0.214 | 0.24 | 0.088 | 0.127 | 0.011 | 0.115 |
| 0.20 | 0.040 | 0.162 | 0.202 | 0.68 | 0.046 | 0.156 | 0.009 | 0.147 |
| 0.30 | 0.053 | 0.125 | 0.178 | 0.83 | 0.051 | 0.127 | 0.011 | 0.116 |
| 0.40 | 0.062 | 0.092 | 0.154 | 0.86 | 0.057 | 0.097 | 0.013 | 0.084 |
| 0.50 | 0.065 | 0.065 | 0.130 | 0.91 | 0.056 | 0.074 | 0.014 | 0.060 |
| 0.53 | 0.065 | 0.058 | 0.123 | 0.93 | 0.054 | 0.069 | 0.015 | 0.054 |
| 0.60 | 0.064 | 0.042 | 0.106 | 0.95 | 0.050 | 0.056 | 0.016 | 0.040 |
| 0.73 | 0.055 | 0.021 | 0.076 | 0.97 | 0.039 | 0.037 | 0.017 | 0.020 |
| 0.85 | 0.039 | 0.007 | 0.046 | 0.99 | 0.022 | 0.024 | 0.018 | 0.007 |
| 1.00 | 0.010 | 0 | 0.010 | 1.00 | | | | |

This may be more analysis than should be made with historical data, but it is clear the original authors' interpretation of their results is not correct. The melt is taken to 1170° C., held briefly with no mixing, and cooled at a fairly high rate of 3° C./hour to 950° C. The concentration of solute is well above the saturation limit at 1170° C. and so never goes completely into solution. The melt never comes to thermodynamic equilibrium. Therefore, the Clarke and Whatmore results are in no way relevant to the present study.

### XIE

Lead oxide-boron oxide is of interest because Xie, his advisor, and other group members did successfully grow small crystals at the MPB from this solvent by top-seeded solution growth (Y. Xie, “Synthesis and Characterization of Piezo-ferroelectric Lead Zirconate-Titanate (PZT) Single Crystals and Related Ternary Ceramics,” Ph.D. thesis, Simon Fraser University, 2013). They used a flux with 4:1 PbO—B₂O₃ molar ratio (2.42:1 cation ratio or 29.2 cation %), which, according to the current results, will reduce the activity of ZrO₂ and TiO₂ up to some B₂O₃ concentration (about 10 cation % B₂O₃), and above that form borate second phases. The starting material was pre-reacted PZT pellets with X=0.4 that were not completely dissolved in the solvent. The melts were equilibrated 5° C. above the starting temperature for 5 days, lowered to the starting temperature, seeded, and then ramped to the end temperature at 4° C./day. The most successful run that achieved an MPB composition (which they measured at X=0.54) had a starting temperature of 1070° C. and an end temperature of 1000° C. Xie concluded the melt composition and therefore the crystal composition depended solely on the temperature.

Crystals grown by the slow cooling method with undercooling establish the amount of nutrient in the melt during the initial equilibration phase and then deplete that nutrient continuously during the growth run without dissolving any further nutrient from the source material so, although this is made up as a two-phase melt, the fixed composition of solid starting material, which is not fully dissolved, means that it never comes to complete thermodynamic equilibrium but achieves at best a metastable equilibrium. In this case the solvent will thermodynamically preferentially dissolve PT over PZ resulting in phase separation at the surface of the nutrient pellets. The system will become a three-phase system with two solids and a liquid of suitable composition to produce PZT with X=0.54, which includes a lower X_{L} than in the starting material. The very high B₂O₃ concentration makes the exact liquid activities difficult to estimate.

### Summary of Previous Results

Previous experiments had systems that never come to an isothermal thermodynamic equilibrium owing to (1) insufficient equilibration time and mixing (Clarke and Whatmore); (2) slow cooling for a continuously variable temperature (all), (3) high temperature equilibration (others), and (4) solid starting materials of a fixed composition that neither dissolved nor came to equilibrium (Xie).

### Equilibrium Single-Phase High Temperature Solution

In an embodiment, the present disclosure provides a single-phase high temperature solution system comprising concentrations of free lead oxide [PbO]_{free}, zirconium oxide [ZrO₂], titanium oxide [TiO₂] and dissolved boron oxide complexed with additional oxygen [BO₃³⁺] is brought to thermodynamic equilibrium by mixing at a temperature above the saturation temperature T_{S} with respect to lead zirconate titanate (PZT) PbZr_{X}Ti_{(1-X)}O₃ and cooling to the saturation temperature.

A high temperature solution can be in thermodynamic equilibrium at any temperature above or equal to its saturation temperature. At the saturation temperature, the solution is, by definition, in equilibrium with a precipitating phase, in this case PbZr_{X}Ti₍₁₋ₓ₎O₃ with a composition X defined by the phase diagram.

### Equilibrium Two-Phase Melts

In an embodiment, a two-phase system is brought to thermodynamic equilibration at the saturation temperature T_{S} by steps comprising:
a. mixing the powders comprising the composition of the two-phase system to form a charge wherein the composition comprises a sum of the solid composition comprising an amount of excess PbZr_{X}Ti₍₁₋ₓ₎O₃ components [ZrO₂]ₛ, [TiO₂]ₛ, and [PbO]ₛ in proportions to form a solid of composition PbZr_{X}Ti_{(1-X)}O₃ and the liquid composition that is in thermodynamic equilibrium with the solid composition at a temperature Ts.
b. heating the charge in a crucible in a vertical furnace to a temperature greater than the saturation temperature of the entire charge including the excess PZT;
c. mixing the fully melted one-phase system for a time sufficient to achieve thermodynamic equilibrium with all components in solution.
d. cooling with stirring to an average melt temperature of T_{S} to allow precipitation of the excess PZT to provide a melted two-phase system.

In an embodiment, a two-phase system is brought to thermodynamic equilibration at the saturation temperature T_{S} by steps comprising:
a. mixing the powders comprising the composition of the two-phase system to form a charge wherein the composition comprises a sum of the solid composition comprising an amount of excess PbZr_{X}Ti₍₁₋ₓ₎O₃ components [ZrO₂]ₛ, [TiO₂]ₛ, and [PbO]ₛ in proportions to form a solid of composition PbZr_{X}Ti_{(1-X)}O₃ and the liquid composition that is in thermodynamic equilibrium with the solid composition at a temperature Ts.
b. heating the charge in a crucible in a vertical furnace to an average melt temperature of T_{S} to provide a melted two-phase system; and
c. mixing the melted two-phase system for a time sufficient to achieve thermodynamic equilibrium.

The preceding phase diagram, work was used to determine what the thermodynamic equilibrium is. If the liquid-solid system of the high temperature solution and the PZT crystals is at thermal equilibrium, the crystals can be of uniform composition. This was accomplished in the present disclosure in various ways.

1. In an embodiment, forming a two-phase liquid-solid system by starting with a superheated one-phase liquid system and cooling it rapidly to the growth temperature to precipitate the second solid phase. This means first that no more excess PZT is added than can be fully dissolved by superheating to a high temperature that is practical in terms of the furnace operation and evaporation of solvent typically for 8-16 hours. The phase diagram and solubility work of the previous sections quantify this. This limits the quantity of excess PZT and therefore the amount of crystal that can be grown from any single run. This type of equilibration is not anticipated in the literature where there is a general presumption that a melt can be extensively supercooled as is the case in garnet systems where supercooling of 20-30° C. is regularly sustained for a week or more and 100° C. supercooling can be sustained for a short period. But the garnet crystal structure is the most complex cubic crystal structure in the crystallographic tables with 160 atoms in a unit cell that is thirty times the volume of a PZT unit cell. Forming a PZT nucleus can be much smaller and easier. Additionally, garnet does not nucleate significantly on platinum and PZT nucleates very well. Therefore, a small supercooling for a short time produces extensive PZT crystal growth on the platinum crucible sufficient to deplete the liquid to its exact saturation composition at the growth temperature thus establishing thermodynamic equilibrium.

2. In an embodiment, forming a two-phase system immediately by heating to the growth temperature and equilibrating there. First, all the constituents should be thoroughly mixed as powders, heated quickly to a constant equilibration temperature and stirred there for 16-48 hours. Under such circumstances the constituents will react at that temperature and assume a thermodynamic equilibrium state of a liquid in equilibrium with a PZT solid, which typically sits on the bottom of the crucible. A larger amount of excess PZT solid can be accommodated by this process.

If PZT crystals of the equilibrium composition are added to such a melt, they will remain in equilibrium, whereas crystals of a different composition will not be in complete thermodynamic equilibrium, though they may be metastable. If nutrient equivalent to a PZT crystal of the equilibrium composition is added to such a melt, additional crystals of the equilibrium composition will form. Therefore, thorough mixing before and after melting is utilized to achieve thermodynamic equilibrium.

Depending on the relative densities of the melt and the crystal, the crystals may tend to sink to the bottom or float on the surface. Commonly crystals will nucleate, grow, and continue to adhere to a heterogeneous site such as the crucible wall or bottom.

This is distinct from flux growth wherein the starting materials are solids of a non-equilibrium composition and a solvent liquid, which can only come to a metastable equilibrium possibly with multiple phases.

The empirical Equations (26) and (28) can be used to determine the state of such a two-phase system in thermodynamic equilibrium. The conservation equations between the total starting quantities [Til]₀ and [Zr]₀ and their partitions into the solid and liquid phases can be inserted into equation (26).

$${X}_{S} = \frac{{[ Ti ]}_{S}}{{[ Ti ]}_{S} + {[ Zr ]}_{S}} = \frac{{[ Ti ]}_{0} - {[ Ti ]}_{L}}{{[ Ti ]}_{0} - {[ Ti ]}_{L} + {[ Zr ]}_{0} - {[ Zr ]}_{L}} = k \frac{{[ Ti ]}_{L}}{{[ Zr ]}_{L}} \qquad ( 32 )$$

Rearranging this to solve for [Zr] L can then be made equal to Equation (28).

$${[ Zr ]}_{L} = \frac{( ( {[ Ti ]}_{0} + {[ Zr ]}_{0} ) {k [ Ti ]}_{L} - {k [ Ti ]}_{L}^{2} )}{( {[ Ti ]}_{0} + {( k - 1 ) [ Ti ]}_{L} )} = A + {BT}_{S} + {DTi}_{L} \qquad ( 33 )$$

This in turn can be rearranged into a quadratic equation in [Ti] L, which can be solved in the normal way for a given temperature.

$${( k + D ( k - 1 ) ) [ Ti ]}_{L}^{2} + ( {( D - k ) [ Ti ]}_{0} - {k [ Zr ]}_{0} + ( A + {BT}_{S} ) ( k - 1 ) ) {[ Ti ]}_{L} + {( A + {BT}_{S} ) [ Ti ]}_{0} = 0 \qquad ( 34 )$$

### Crystal Growth

The experiments of the present disclosure comprise a number of different methods including 1) top seeded solution growth from a slightly supercooled liquid, 2) isothermal liquid phase transport from a two-phase system in thermodynamic equilibrium (comprising multiple possible methods to use this mechanism), and 3) isothermal top seeded solution growth from a two-phase system in thermodynamic equilibrium by liquid phase transport. Each of these is detailed below.

Top-Seeded Solution Growth from a Supercooled Solution with Slow Cooling

In an aspect, the present disclosure provides a method growing a PbZr_{X}Ti_{(1-X)}O₃ crystal from the single-phase high temperature solution system by top-seeded solution growth with supercooling and slow cooling. In an embodiment, the method comprises:
a. using the thermodynamic equilibration method for a single-phase solution to make the single-phase system in thermodynamic equilibrium at the saturation temperature T_{S};
b. establishing an undercooling in the mixture by lowering the temperature below saturation;
c. introducing a seed in the top of a liquid;
d. growing a crystal on the seed by slow cooling and pulling for a period to provide a grown crystal, lowering the temperature slowly during a growing period; and
e. lifting the grown crystal above the top of the liquid.

In an embodiment, top-seeded solution growth with supercooling and slow cooling is conducted at less than or equal to 4° C. undercooling.

In an embodiment, top-seeded solution growth with supercooling and slow cooling is conducted with the ramp less than or equal to 2° C./day.

In an embodiment, top-seeded solution growth with supercooling and slow cooling is conducted with a total temperature drop less than or equal to 20° C.

TSSG allows the crystal grower to bootstrap from seeded growth on a completely different material (heteroepitaxy), in this case a platinum paddle, rod or wire, to homoepitaxy on a PZT seed thus created. When the melt is cooled below the saturation temperature, growth of an existing crystal is thermodynamically favored, but nucleation of the crystal generally involves supercooling to a temperature further below the saturation temperature to supply the additional free energy to form a nucleus. In classic nucleation theory, a three-dimensional crystallite forms by homogeneous nucleation when enough atoms come together in the solution in the crystalline pattern. Heterogenous nucleation on a favorable surface allows the formation of a smaller nucleus, which uses less energy and less supercooling/undercooling below the saturation temperature. Epitaxial nucleation uses less free energy with the amount of energy used depending on the degree of lattice match since stressed nucleation produces stress energy to be overcome. Seeded nucleation with a PZT seed in TSSG uses the least free energy of all since there is no barrier to overcome other than the interface process.

The melt was equilibrated and stirred 80° C. above the saturation temperature for 6 hours, then cooled over a period of 3 hours to the growth temperature. To prevent overshoot, the melt was cooled 70° C. at a rate of 35° C./hour and the final 10° C. at 10° C./hour.

Initial seed crystals were nucleated on a platinum wire with a sharp tip. If a small portion of a small diameter pointed platinum wire was put in the melt, only a few platinum grains were exposed as nucleation sites and resulted in a crystal that was much less polycrystalline with only 1-3 crystallites. Pulling the crystal in steps after seeding occurs so that only the fastest downward growing (closest to (111)) crystals continue. Typically, growth on platinum starts about 4° C. below the saturation temperature. This means that once a crystal nucleates, it will be well below saturation and no ramp should be used initially to avoid a high growth rate and polycrystals. The seeding procedure was to dip the wire so only the tip was in and pull up to form a meniscus to within 0.2 mm of separation. Then over the next day, the formed seed crystal was progressively pulled repeatedly upward as it grew downward from the end of the wire to stay within 0.2 mm of separation. This typically gave a single or bi-crystal. Then the crystal was allowed to grow at this height for three days to spread to diameter. Normally in TSSG the crystal would be pulled up vertically at this point, but it was found that this leaves too much weight on the wire point and the crystal tends to fall off near the end. This was ameliorated by lowering the crystal downward into the melt at a rate of 0.3 mm/day until 2 mm of wire was immersed in the melt with crystal grown around it. Because the single crystal has grown to width, the downward push does not result in the aborted polycrystals at the base growing, but only the single large crystal domain. When this has proceeded to the point where there is enough support on the wire, the crystal can be raised upward to put the bottom of the crystal at the surface of the melt and thereafter pulled slowly in the normal upward direction.

For good growth at the lowest possible undercooling and the slowest possible rate, a PZT seed from a previous growth run is used so there is no nucleation step or extra supercooling, only growth. This involves precise knowledge of the saturation temperature, which was developed from the phase diagram work. In practice, crystals grew fastest with the (1,1,1) axis pointing down into the melt and step flow going downward, But this also resulted in thermal shadowing and the bottom of the crystal being hotter because of the vertical temperature gradient as well. To overcome this, the crystal had to be pulled progressively as it grew, either at a steady rate or incrementally in steps. This was particularly true in nucleating off a platinum wire, where pulling the crystal pulled the slower growing non-(1,1,1) direction crystals out of the melt, leaving only the fast growing (1,1,1) oriented seed to continue.

As always, the quality of the crystal is only as good as the quality of the seed. If there are inclusions and other defects in the seed, it is difficult to impossible to heal those over and have a monolithic crystal.

To create still larger crystals, acceptable seeds produced on a platinum wire tip were either cut down to a single crystal domain or only had one domain dipped in the melt. This seed then forms the basis for TSSG. PZT has a slow growth rate versus undercooling that appears to be interface kinetic dependent on the interface kinetics constant K because of chemical complexes and viscosity of the melt. As a result, increasing the undercooling only marginally increases the crystal growth rate and extremely increases the generation of defects especially face nucleation, both in and out of registry, where the latter generates polycrystals. Therefore, growth was conducted at low undercoolings preferably 1-2° C. below the saturation temperature. This was accomplished in two ways in slow cooling growth.

1. Initial seeding was attempted just above the saturation temperature so that there was some meltback. This gave a clean surface and made sure that there was no initial supercooling that might cause too fast growth.

2. The temperature ramp was set as low as possible 0.1° C./hr (or less by stepwise pulling) to make sure that all the possible growth occurred at any given temperature before any further ramping occurred so that the ramp did not outpace the growth and the supercooling and growth rate stayed constant. The total ramp, over a period of up to two weeks, scales with the concentration in TABLE VII and was 15-20° C. for PLP melts, 7-10° C. for Pb₄P melts and 3-5° C. for PbO-5% B₂O₃.

There is an additional complication from using a small seed that grows outward. The cooling rate governs the volume growth rate not the perpendicular growth rate. If the crystal surface area is small, even the lowest ramp may give a constant volume growth rate that translates to too fast of a perpendicular growth rate. Therefore, seeding was undertaken with a large surface area face contacting the melt.

There is a compositional gradient in the larger crystals as a result of the distribution coefficients between Zr and Ti being non-unity and the growth of the crystal by slow cooling. The crystal grows with a higher Zr content than the melt because the Zr distribution coefficient is greater than one. Thus, as the crystal grows, the melt will become depleted of Zr with respect to Ti and ensuing portions of the crystal will grow with less Zr. This can also be viewed as the crystallization process moving down the solidus curve of the phase diagram. The crystal growth process is intentionally terminated before this difference can become too large. This amount of depletion depends on the relative sizes of the melt and the crystal. A larger melt will have slower depletion. Calculations indicate the variation of the Zr concentration X is 0.52±0.05 atoms per formula unit in crystals grown from a PLP melt. Less gradient as much as an order of magnitude lower is possible in melts that do not contain phosphates because of their higher concentration of nutrient.

Growth in a supercooled melt is inherently a metastable process. Growing defect-free crystals depends on suppression of various nucleation mechanisms including satellite crystals, parasitic crystals, side-wall nucleation, second phases and, in this case, face nucleation. The amount of supercooling possible in a HTS melt depends on the melt properties and thermodynamics. A major issue in growth is that the crystal should be seeded and grown as close as possible to the saturation temperature. Too much undercooling and there will be fast growth with the attendant problems. Therefore, a different method was developed.

### Isothermal Liquid Phase Transport in a Two-Phase System

In another aspect, the present disclosure provides a method of growing a PbZr_{X}Ti_{(1-X)}O₃ crystal from the system by isothermal liquid phase transport in a temperature gradient in the high-temperature solution. In an embodiment, the method comprises:
a. mixing powders comprising the composition of the two-phase system to form a charge, wherein the composition comprises a sum of the solid comprising an amount of excess PbZr_{X}Ti₍₁₋ₓ₎O₃ components [ZrO₂]s, [TiO₂]s, and [PbO]ₛ in proportions to form a solid of composition PbZr_{X}Ti₍₁₋ₓ₎O₃ and a liquid composition that is in thermodynamic equilibrium with the solid at a temperature T_{S};
b. bringing the charge to equilibrium at T_{S} by:
   i. heating the charge in a crucible in a vertical furnace to a temperature greater than the saturation temperature T_{S} of the entire charge including the excess PZT; mixing the fully melted system for a time sufficient to achieve thermodynamic equilibrium with all components in solution; and cooling with stirring to an average melt temperature of T_{S} to allow precipitation of the excess PZT to provide a melted two-phase system; or
   ii. heating the charge in a crucible in a vertical furnace to an average melt temperature of T_{S} to provide a melted two-phase system; and mixing the melted two-phase system for a time sufficient to achieve thermodynamic equilibrium;
c. establishing a temperature gradient between the system and a growing region;
d. introducing a seed in the growing region;
e. holding the average temperature constant to within ±3° C. during a growing period to provide a grown crystal; and
f. separating the grown crystal from the liquid.

Isothermal liquid transport in a temperature gradient may sound contradictory, but the term isothermal is intended to describe that the system, including the furnace, crucible, and melt, are controlled to be at a constant average temperature over a long period of time to assure that the thermodynamic equilibrium that has been established remains constant and therefore the crystals thus produced are of constant composition. The temperature gradient creates a free energy gradient where dissolution of nutrient crystals at a hotter location and formation of crystal at a cooler location are thermodynamically favored with the intervening liquid mixed by convection and hydrodynamic stirring at an intermediate equilibrium composition where both processes are equally favored for a constant flow of material. If the temperature gradient is small, the two locations remain close to thermodynamic equilibrium dissolving and crystallizing PZT of essentially the same composition governed by thermodynamic equilibrium with the composition of the liquid. The growth process and kinetics are a combination of transport processes (diffusion, convection, hydrodynamic stirring, heat conduction) and interface kinetics at both locations. To be uniform, the gradient should be less than 10° C. and preferably less than 5° C.

### Top-Seeded Solution Growth in a Two-Phase System

In another aspect, the present disclosure provides a method growing a PbZr_{X}Ti_{(1-X)}O₃ crystal from the system by isothermal top-seeded solution growth. In an embodiment, the method comprises:
a. mixing powders comprising the composition of the system to form a charge, wherein the composition comprises a sum of the solid comprising an amount of excess PbZr_{X}Ti₍₁₋ₓ₎O₃ components [ZrO₂]ₛ, [TiO₂]ₛ, and [PbO]ₛ in proportions to form a solid of composition PbZr_{X}Ti₍₁₋ₓ₎O₃ and a liquid that is in thermodynamic equilibrium with the solid at a temperature T_{S};
b. bringing the charge to equilibrium at T_{S} by:
   i. heating the charge in a crucible in a vertical furnace to a temperature greater than the saturation temperature T_{S} of the entire charge including the excess PZT; mixing the fully melted system for a time sufficient to achieve thermodynamic equilibrium with all components in solution; and cooling with stirring to an average melt temperature of T_{S} to allow precipitation of the excess PZT to provide a melted two-phase system; or
   ii. heating the charge in a crucible in a vertical furnace to an average melt temperature of T_{S} to provide a melted two-phase system; and mixing the melted system for a time sufficient to achieve thermodynamic equilibrium;
c. establishing a temperature gradient between a bottom and a top of the system;
d. introducing a seed in the top of a liquid of the system;
e. growing a crystal on the seed by isothermal liquid phase transport from nutrient material at the bottom of the two-phase mixture to the seed;
f. growing a crystal at a top of the liquid for a period to provide a grown crystal, holding an average temperature of the liquid constant to within ±3° C. during a growing period; and
g. lifting the grown crystal above the top of the liquid.

Isothermal top seeded solution growth from a two-phase system in thermodynamic equilibrium by liquid phase transport involves rethinking melt thermodynamics compared to more conventional crystal growth methods such as slow cooling or growing from a supersaturated melt. In this case isothermal is used to refer to the average temperature of the system, though there are gradients within the system. Equilibration and growth occur at the same average system temperature to achieve thermodynamic equilibrium.

A two-phase charge composition is calculated by 1) determining the equilibrium liquid composition for growth of a PZT crystal of desired X at a saturation temperature T_{S} from a given solvent according to the phase diagram, 2) calculating the weights of PbO, ZrO₂ and TiO₂ to form solid crystal nutrient of the desired excess quantity and, 3) summing the liquid and solid compositions for the two-phase system. Equation (33) or a similar equation for a different solvent system can be used for this.

A new melt is created by mixing the powders thoroughly, compacting the charge if desired by various pressing means, placing the charge in a platinum or platinum-gold crucible, placing in a furnace, heating quickly to the thermal equilibrium temperature to melt/react the charge, and stirring with a paddle for 12-24 hours. This allows proper reaction of the constituents to precipitate out the PZT composition in thermodynamic equilibrium with the liquid.

It is also possible to prepare the solid and liquid compositions separately and stack the liquid on top of the solid in the crucible. This allows preparation of a ceramic PZT solid source material.

If the powder is much less dense than the molten charge, it can take up more volume than the crucible. In this case, a quantity of just the solvent may be melted first, and the balance of the charge added in a second step.

In a solution with excess ZrO₂+TiO₂ above the saturation concentration, the concentration in the solution is governed by the solvent and the temperature and the excess will precipitate out. Initially PZT crystals will form spontaneously either homogeneously in the liquid and sink to the bottom if the crystals are of higher density than the melt or, more likely, heterogeneously on the crucible wall and/or bottom. When the melt is fully saturated in ZrO₂+TiO₂ with a nearly fixed concentration of TiO₂ because of its much lower solubility, the PZT solidus is stable giving a fixed equilibrium PZT composition for every temperature if the crystal is grown slowly enough to avoid kinetic effects. This composition will be according to the single crystal solidus in the phase diagram.

If there is a temperature gradient between the top and bottom of the melt, the hotter region will have a higher equilibrium concentration of ZrO₂ than the cooler region. In this case, the surface is inherently cooler than the bottom of the crucible owing to 1) thermal radiation from the melt surface, 2) cooling thermal conduction from the seed wire and stirring rod, 3) heating thermal conduction from the hot pedestal and 4) the natural gradient of the furnace. Therefore PZ/PT/PZT will dissolve from the reservoir at the bottom of the furnace until the melt on the bottom is in saturation equilibrium at the temperature of the bottom of the furnace. Thermal and forced (from the rotation of the wire/seed/crystal) convection stirs the melt bringing this nutrient to the surface where the lower temperature will cause the concentration that is excess at the lower temperature to precipitate.

As the crucible walls are typically hotter than the center, the preferred site of precipitation will be the center of the melt surface where the melt is seeded. It is also seen that crystals will grow on a submerged platinum-sheathed thermocouple, which may be cooler because it conducts heat upward, but there is no nucleation on the hot crucible walls for a system in thermodynamic equilibrium. If a nucleus in the form of a platinum wire or a seed crystal of some sort is provided, heterogeneous nucleation will be favored over homogeneous nucleation and only a single crystal will grow. However, if there is any homogeneous nucleation, it will be of higher density than the melt and fall to the bottom. While this has similarities to, for example, hydrothermal growth, this is believed to be a unique crystal growth method that has not been used in a controlled fashion before at thermodynamic equilibrium. To keep the crystal composition constant, the process set point should be isothermal and the same as the equilibration temperature, which makes the growth cycle much easier. In thermodynamic equilibrium, the nutrient crystals at the bottom will have essentially the same composition as the growing crystal at the top so the melt composition will stay constant as long as there is nutrient. Thus, the crystal composition is also constant in a way that no temperature ramp can achieve. For any given solvent, this permits very precise control of crystal composition by keeping [Ti]_{L} constant and changing the temperature to change [Zr]_{L}. Additional control of X can be applied by varying [Ti]_{L} to get to the desired temperature range. At a more gross level, changing the solvent will change the saturation curve of [Zr]_{L}. The crystal will grow in a slower, more controlled fashion with higher quality if the gradient between the bottom and the top is small, in the range of 1-10° C. This is achieved through a combination of crucible placement, melt depth, and baffling.

The actual crystal seeding and growth proceed as for HTS TSSG with supercooling and slow cooling except the slow cooling is eliminated and the supercooling is set up by the temperature gradient.

In an extreme embodiment of this method, a large high-density ceramic puck the diameter of the crucible may be placed in the bottom of the crucible, the equilibrium solution composition placed over the puck and the method conducted as discussed above.

### Cold Finger

In another aspect, the present disclosure provides a method of growing a PbZr_{X}Ti₍₁₋ₓ₎O₃ crystal from the system by isothermal liquid phase transport in a temperature gradient in the high-temperature solution using a cold finger. In an embodiment, the method comprises:
a. attaching a seed on a bottom of a platinum crucible over the cold finger;
b. mixing powders comprising the composition of the two-phase system to form a charge, wherein the composition comprises a sum of the solid comprising an amount of excess PbZr_{X}Ti₍₁₋ₓ₎O₃ components [ZrO₂]s, [TiO₂]s, and [PbO]ₛ in proportions to form a solid of composition PbZr_{X}Ti_{(1-X)}O₃ and the liquid that is in thermodynamic equilibrium with the solid composition at a temperature T_{S};
c. bringing the charge to equilibrium at T_{S} by:
   i. heating the charge in a crucible in a vertical furnace to a temperature greater than the saturation temperature T_{S} of the entire charge including the excess PZT; mixing the fully melted system for a time sufficient to achieve thermodynamic equilibrium with all components in solution; and cooling with stirring to an average melt temperature of T_{S} to allow precipitation of the excess PZT to provide a melted two-phase system; or
   ii. heating the charge in a crucible in a vertical furnace to an average melt temperature of T_{S} to provide a melted two-phase system; and mixing the melted two-phase system for a time sufficient to achieve thermodynamic equilibrium;
d. establishing a temperature gradient between two regions (typically the top and bottom) of the two-phase system by activating the cold finger,
e. holding an average temperature of the system constant to within ±3° C. during a growing period;
f. growing a crystal on the seed by isothermal liquid phase transport from nutrient material at a top of the crucible to the seed at the bottom of the liquid for a period; and
g. inverting the platinum crucible to decant the liquid and remaining nutrient into another crucible.

In the cold finger technique, a thermal gradient is introduced at the bottom of the furnace by a platinum tube typically in contact with the center of the crucible. By a combination of thermal conduction of the platinum and applying a flow of cold gas to the cold finger, a temperature gradient is set up in the melt. This may be a vertical gradient, a lateral gradient or both. A seed holder is placed over the cold finger. A small cooling is applied during the melt equilibration to prevent the seed from dissolving and a larger cooling applied to initiate growth.

For a lateral gradient, the melts and procedures of other methods can be used.

For a vertical gradient, the crucible is lowered so the top of the crucible is at the hottest point in the furnace. In an embodiment, the melt is also configured so the melt is denser than the crystal, typically by using only PbO as the solvent or only a very low addition of any other component. The nutrient is intended to float on the surface of the melt. It may be introduced initially with the melt or a puck of PZT ceramic of the desired composition may be added to the melt after equilibration.

In an embodiment, the cold finger method may be conducted in a horizontal tube furnace with nutrient solid at the hot end and the crystal growing at the cold end.

In an embodiment, the cold finger method may be conducted in a sealed furnace with a controlled atmosphere.

In an embodiment, the cold finger method may be conducted in a sealed crucible to reduce evaporation.

In an embodiment, the melt is decanted after growth by inverting the crucible within the furnace and pouring the residual solution/nutrient into another crucible.

### Crystal Size, Quality, Inclusions, and Growth Rate

In an embodiment, the present disclosure provides a method of growing a PbZr_{X}Ti_{(1-X)}O₃ crystal, wherein a temperature gradient between a nutrient solid phase and a growing crystal is less than 10° C.

In an embodiment, the present disclosure provides a PbZr_{X}Ti₍₁₋ₓ₎O₃ single crystal of mass greater than 10 g.

In an embodiment the PbZr_{X}Ti₍₁₋ₓ₎O₃ single crystal has X uniform within ±0.02.

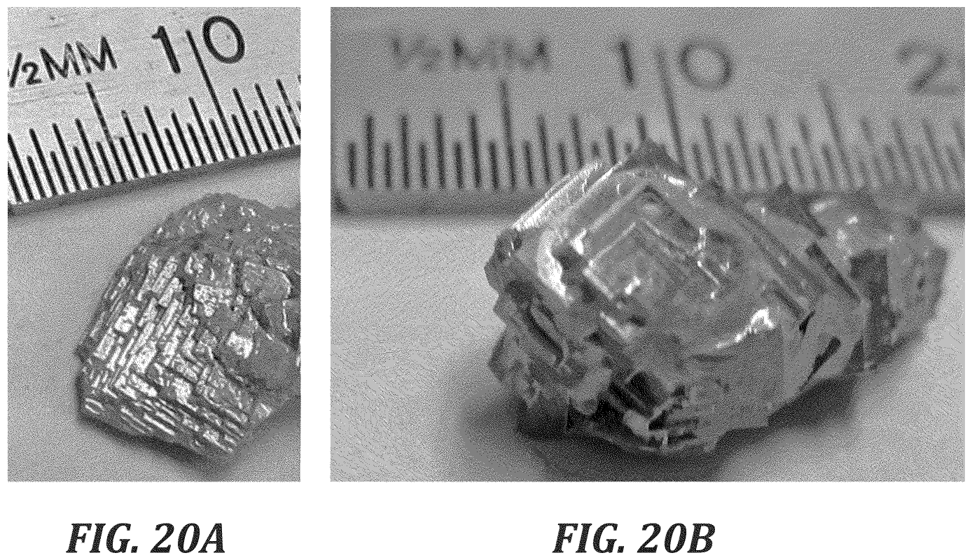

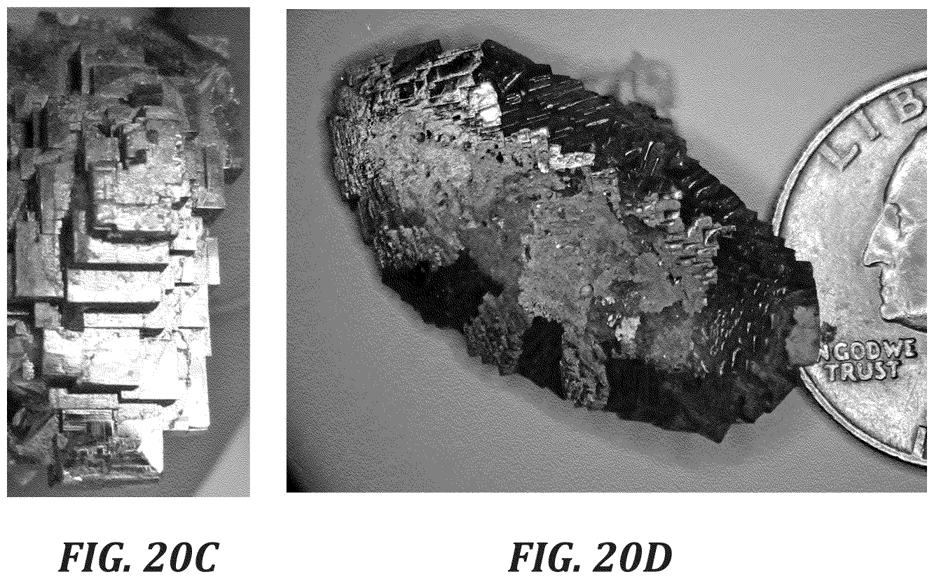

In an embodiment of the present disclosure, single crystals were grown by top-seeded solution growth with limited slow cooling from a single-phase melt with a PLP solvent where the crystals ranged in size with lateral dimensions from 4 to 10 mm, all greater than 1 mm thick. They ranged in average composition from X=0.19 to 0.72 where the desired range is X=0.50-0.53. Photographs of some of the crystals are shown in FIGS. 20A and 20B. Some still have residual solvent adhering (lighter color deposits). The macroscopic stepwise growth pattern resulted in a heavily stepped surface, but all the steps or blocks are oriented together showing they are all part of the same crystal. The variability of appearance results in part from the angle of the growth direction to the facet direction.

In an embodiment, larger crystals were made by reseeding a previous moderate-sized crystal. FIG. 20C shows a 1 cm³ crystal with a stepped surface grown iteratively from an iteratively replenished PLP melt at a relatively high growth rate. FIG. 20D shows that a lower growth rate and an in-plane seed can achieve a smoother surface. This crystal had a planar orientation and achieved a net weight of 10.63 g (1.33 cm³). The clearly smoother nature of the crystal shows almost all the macroscopic surface steps have been removed. However, there were still microscopic melt inclusions from columnar growth and the irregular shape is indicative that step-flow growth is not occurring sufficiently. The black color of the crystal may arise from composition according to Xie, who noted that crystals with compositions away from the MPB are darker because they are more crystallographically symmetric and therefore have a lower and narrower band gap that absorbs more light in the visible. The largest crystal grown by this method broke and fell in the melt. The pieces were recovered by decanting and measured 17 g in mass. This is compared to results from previous studies in TABLE IX.

TABLE IX
Dimensions and volume of current crystals compared to much
smaller prior art. The references are to the numbered
references of TABLE I and TABLE II

| | Maximum | Approximate |
|---|---|---|
| Reference | Dimensions (mm) | volume (mm³) |
| Present | 16 × 13 × 10 | 2080 |
| Xie [4] | 8 × 3 × 4 | 96 |
| Perez [7] | 3 × 3 × 3 | 27 |
| Eknadiosiants [12] | 1-3 | ~8 |
| Tsuzuki [10] | 1-2 | ~4 |
| Fujii [11] | 1.7 × 1.7 × 0.9 | 2.6 |
| Hatanaka [3] | 1 × 1 × 1 | 1 |
| Clarke [2] | 0.5-1 | ~0.5 |
| Fushimi [6] | 0.1 × 0.08 × 0.04 | 0.0003 |

When the crystal becomes large enough, there is thermal shadowing at the center of the crystal. The melt takes in heat from the sides where the heating coils are. The bottom of the crucible/melt is well insulated by the pedestal and can lose heat only by conduction. Since it is placed in the furnace such that it is just above the peak temperature of the distribution, there is very little heat lost out the bottom and instead heat is conducted upward. The top of the melt cools by radiation and conduction from the melt to the air. The latter is increased by a combination of convection in the melt and convection in the air that brings hot melt to the surface and carries hot air away from the surface. The current baffle system has minimized convection of the growth atmosphere, as has been seen from reduction of evaporation, and it also reflects thermal radiation back downward. PZT crystals are opaque in the infrared, so no heat is radiated through the seed and, of course, there is no air above the crystal growth interface to provide convective heat loss, so there is only conductive heat loss through the seed/crystal and that is much lower. As a result, the center of the crystal is significantly hotter than the rest of the surface of the melt, suppressing crystal growth.

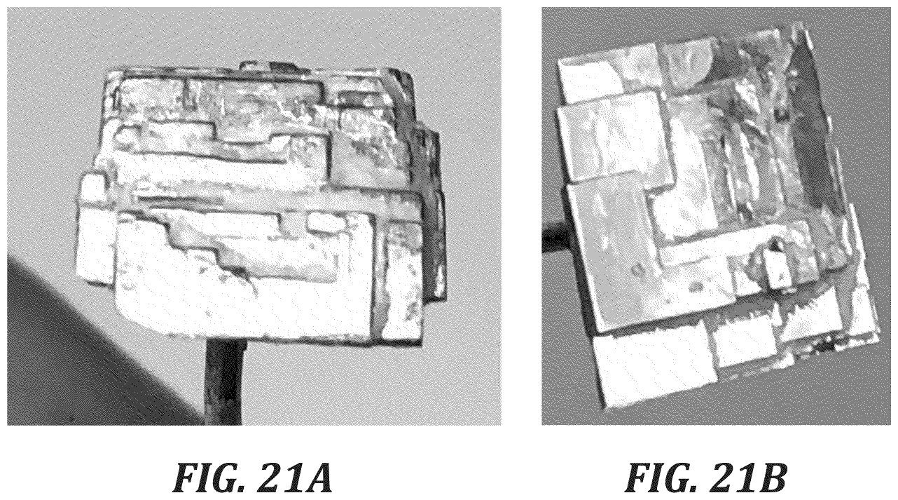

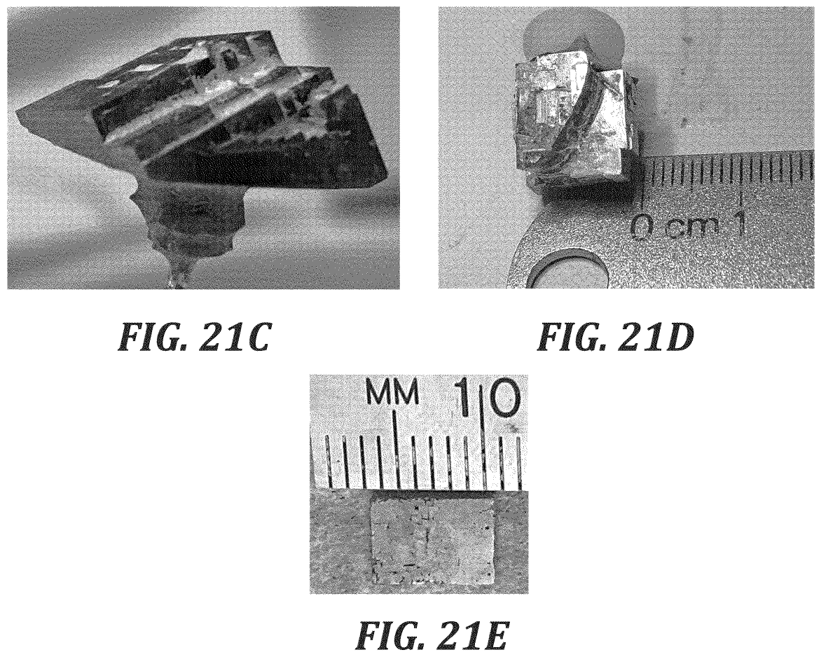

FIGS. 21A-21E shows crystals grown from a PbO—Pb₄P melt by TSSG with supercooling from a single-phase melt in 21A, 21B, and 21C and by TSSG in thermodynamic equilibrium from a two-phase melt in 21D.

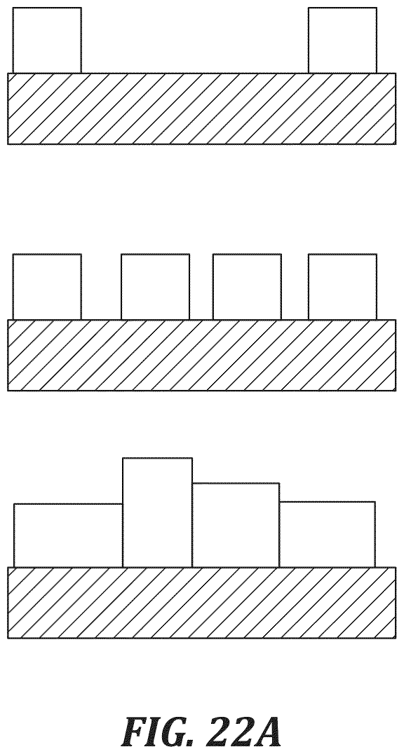

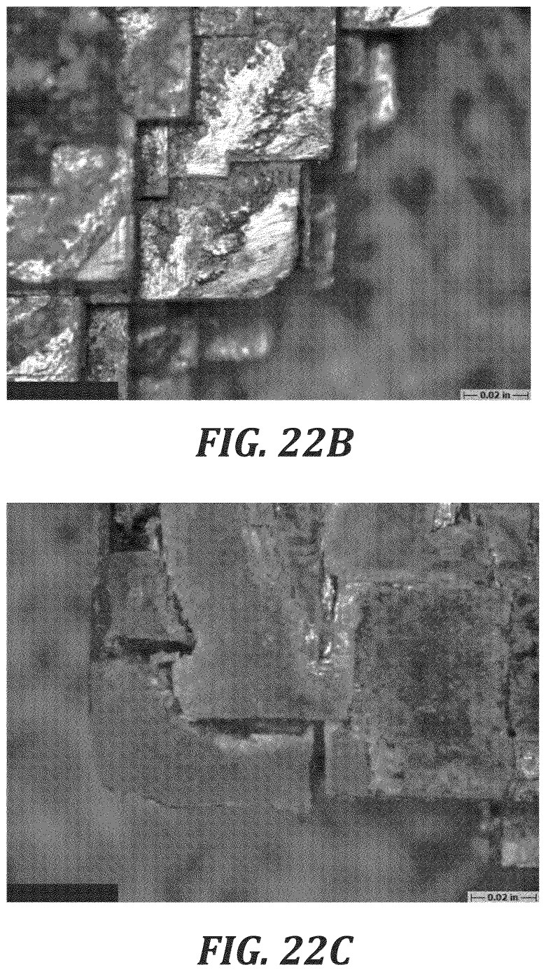

A fabricated crystal in FIG. 21E shows that there remain inclusions in the fully fabricated crystal. If there is insufficient time for chemical complexes in a molecular solution to break down or diffuse away during the interface kinetics, then nucleation of large steps on the face occurs, which is what was observed. This results in columnar growth (FIG. 22A) from many island nuclei and solvent trapping and defects as in FIGS. 22B and 22C. When the unpolished surface is viewed as in FIG. 22B, it has the stepped appearance identified previously with aligned edges indicating all these crystals are part of a single crystal with one orientation. However, when polished and etched, as in FIG. 22C, a different image appears. The steps are separated by gaps that are initially filled by solvent, but, when etched to remove the solvent in FIG. 22C, show that although the crystals have a common origin and orientation, at some point during crystal growth, the growth steps separate so the crystal is monolithic vertically, but not horizontally.

This growth pattern occurs when a monolithic single crystal sheet forms from the nucleation site over the top of the melt and step nuclei form on the surface. In this case, the step nuclei tend to grow equally in all three <1,0,0> crystal directions and draw all the nutrients so that no new step nuclei will form. Eventually these macro-steps come so close to one another that they trap the melted liquid between them, and no new liquid can diffuse into or out of the gap. When this occurs, the crystal grows laterally only as long as there is any nutrient in the trapped melt and then stops with the depleted solvent pinned in place. When this crystal is removed from the melt, the crystal surface is drained of the melt, but capillarity traps the depleted solvent between the steps in part because of the good wetting of the solvent. Visually this appears monolithic as in FIG. 22B, but when the solvent is partially etched away, separation between the crystals is seen as in FIG. 22C.

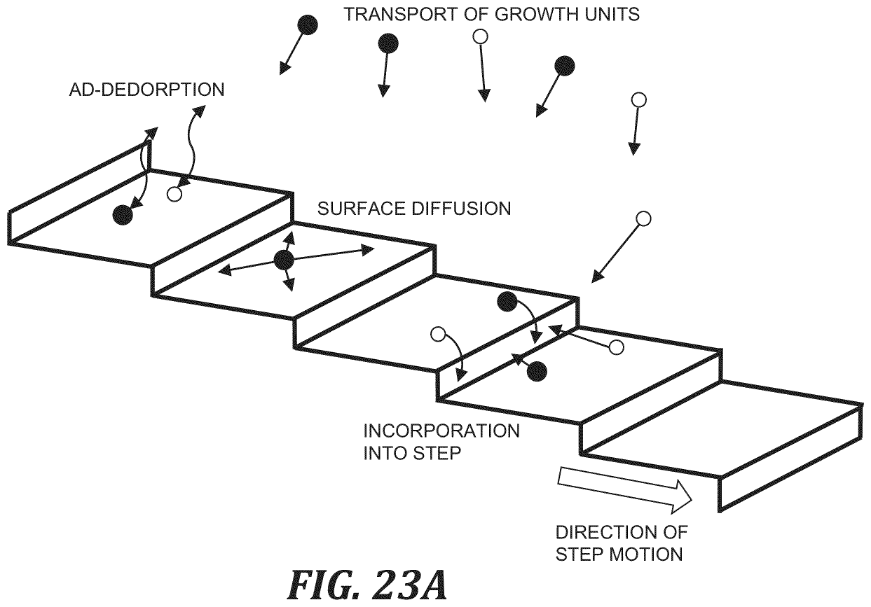

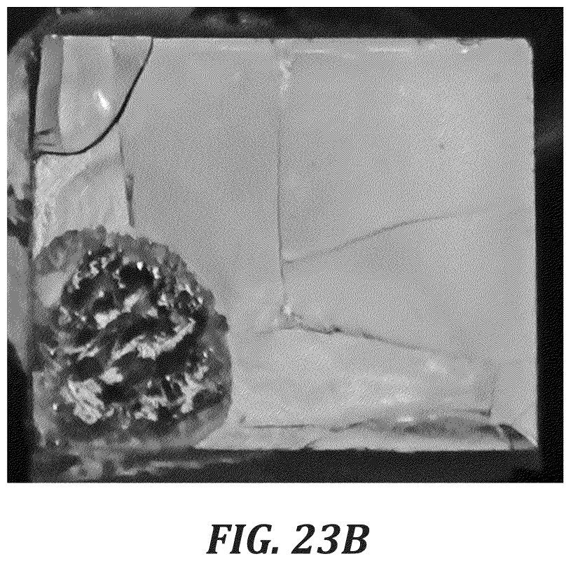

On the other hand, if very slow growth can be achieved, steps are nucleated at the surface that sweep toward a (1,1,1) corner as in FIG. 23A. A desirable growth model is nucleation of steps at (1,1,1) corners followed by spreading on <1,0,0> edges and (1,0,0) faces (L.-C. Lim, “Flux Growth and Characterization of PZN-PT and PMN-PT Single Crystals,” in Handbook of Advanced Dielectric, Piezoelectric and Ferroelectric Materials, ed. By Z.-G. Ye (Woodhead Publishing, Cambridge, England, 2008) pp. 38-72). This produces a cubic crystal with an unstepped face as in FIG. 23B. This involves a slow growth rate.

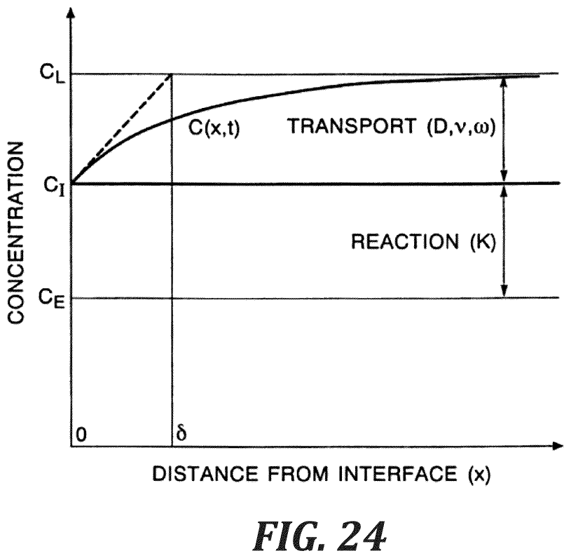

The growth rate of the crystal may be governed by several factors. The growth process and kinetics are a combination of transport processes (diffusion, convection, hydrodynamic stirring, heat conduction) and interface kinetics. To solve all these equations would be extremely complex and provide little physical intuition. Fortunately, Burton, Prim, and Slichter (J. A. Burton, R. C. Prim, and W. P. Slichter, “The Distribution of Solute in Crystals Grown from the Melt. Part I. Theoretical,” J. Chem. Phys. 21 (1953) 1987) developed a simple boundary layer formalism for a well stirred melt to address this problem. For steady state growth in a liquid stirred by thermal convection and convection driven by crystal motion, the arrival of nutrient at the growth interface depends on diffusion of nutrient through the quiescent boundary layer from which rejected solvent diffuses outward. The resultant growth rate is controlled by the combination of transport and reaction kinetics shown schematically in FIG. 24.

1. The temperature gradient between the source nutrient and growing crystal governs the driving force for chemical transport and crystal growth, which in turn governs the growth rate. This gradient comprises the difference between the bottom and top of the melt (8-9° C.) and the distance between them (5-7 cm). This is the highest workable gradient. The depth should be suitable to keep the nutrient particles from being stirred up and incorporated in the crystal as inclusions. Temperature gradient control will be discussed in furnace design below.

2. The reaction kinetics at the interface cause incorporation of PbO, ZrO₂ and TiO₂ into the crystal and rejection of depleted solution. In practice this is governed by the very low Zr concentration in the melt compared to the crystal, so Zr transport and incorporation at the growth interface appears to be limiting. PZT has a slow growth rate with respect to undercooling that appears to be dependent on the interface kinetics constant K because of chemical complexes and viscosity of the melt. Solvents that dissolve higher concentrations of Zr (potentially including fluorides and chlorides) will allow faster growth.

3. If the melt is well stirred and the crystal is rotated, it is assumed that viscosity creates an effective quiescent or boundary layer adjacent to the crystal. The thickness of this boundary layer 8 is given by Burton, Prim, and Slichter as δ=1.6D^{1/3}y^{1/6}ω^{-1/2}, where D is the diffusion coefficient, v is the kinematic viscosity and ω is the angular frequency of the crystal rotation i.e. the rate of shear motion of the growing crystal with respect to the liquid.

4. Diffusion through the boundary layer will be governed by the viscosity, the size of the particles of both the solute to diffuse to the interface and the solvent to diffuse away. Glass formers that increase the viscosity may be problematic. Molecular complexes that are trapped unless they diffuse away can slow down growth and create inclusion defects. Dilution with a small ion such as Li+ or Na+ that promotes an ionic fluid will improve diffusion of solvent away from the interface. Higher temperature growth will reduce the viscosity and improve all the kinetics but can also increase evaporation. A higher melt concentration of solute through a high free PbO concentration will also reduce the amount of flow necessary to provide nutrient to the crystal-melt interface.

5. The melt will be somewhat stirred by convection, but even more the motion of the crystal in the melt through rotation will create a thinner layer at the crystal surface. Bidirectional rotation improves this, but unidirectional rotation may give a more uniform impingement of nutrient on step faces to improve step-flow.

### Furnace Design, Temperature Gradient, and Sol Vent Evaporation

In an embodiment, the present disclosure provides a method of growing a PbZr_{X}Ti_{(1-X)}O₃ crystal, wherein the furnace comprises baffles configured to restrict flow of lead oxide vapor and control the temperature gradient.

In an embodiment, the present disclosure provides a method of growing a PbZr_{X}Ti₍₁₋ₓ₎O₃ crystal, wherein the crucible comprises an aspect ratio of height: diameter greater than 1.25.

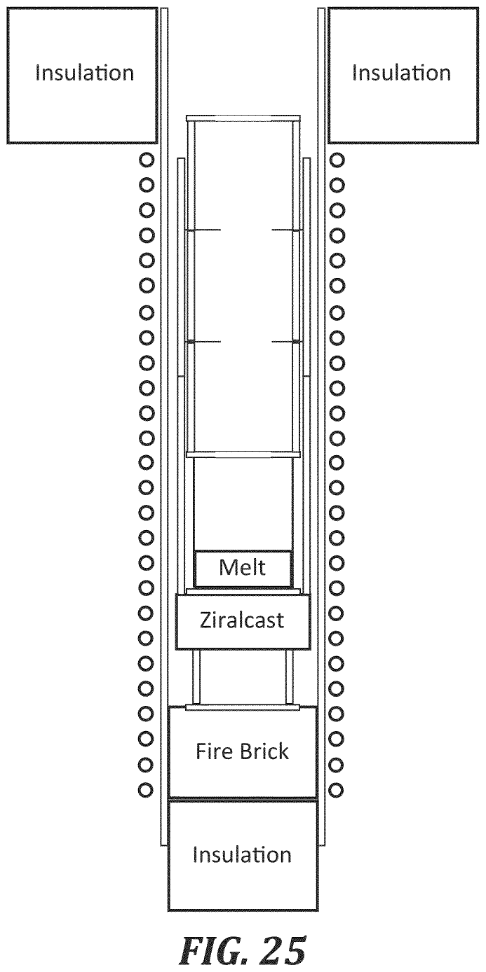

The crystal growth furnace and its internals are designed to control the temperature gradient in the melt and reduce solvent evaporation. FIG. 25 shows the furnace internals with insulation below the crucible to control the temperature gradient.

The hottest spot in the furnace is near the bottom. The pedestal comprises elements to provide structural support and thermal insulation. The latter is always best realized through the incorporation of air, either in insulation or an air chamber. An air chamber with a tubular ceramic support such as an alumina tube for structural strength was incorporated in this design. Adjusting the height of the alumina tube to position the crucible with respect to the hot spot in the furnace is the principal method of adjusting the temperature gradient. Other structural/insulating elements are furnace insulation in the bottom cap, a disc of fire brick, alumina discs for structural support, and a disc of castable lightweight alumina refractory composed of hollow, fused alumina bubbles incorporated into a hydraulically setting cement, such as Ziralcast-94. Both the bubble refractory material and the fire brick have additional value in their ability to absorb spilled solution.

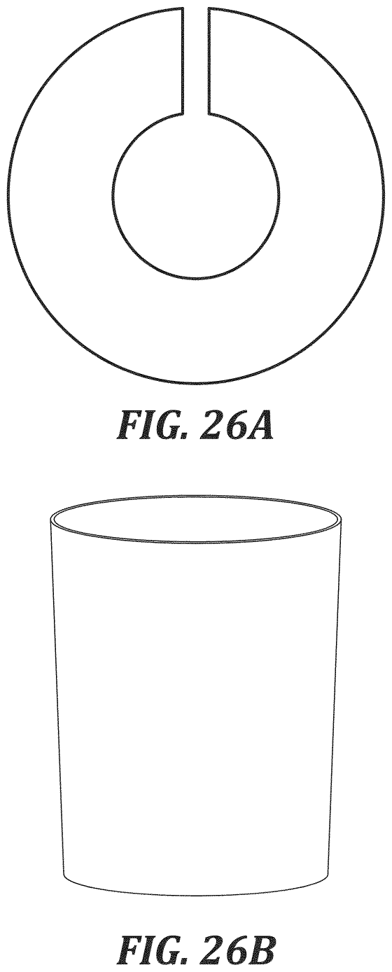

Above the crucible, baffles are used to reduce radiative and convective cooling to maintain a high temperature at the surface of the melt and a low temperature gradient. The top and bottom baffles are made from discs of alumina with a keyhole cut using a diamond loop saw. These have higher rigid structural integrity and some insulation. The intermediate baffles are platinum-5% gold alloy manufactured to shape and spaced with alumina tubes. The precious metal baffles are less prone to degradation from solvent vapors and reflect the heat radiated from the melt. The shape of the baffles is shown in FIG. 26A with a center hole for crystal growth and a side keyhole to allow a platinum sheathed thermocouple to be placed in the melt to monitor and control the temperature and the temperature gradient. These baffles strongly reduce the temperature gradient in the middle of the furnace and confine the gradient mainly to the top region. This system of chambers also controls vapor convection and flow in the top of the furnace to retain lead oxide vapors near the melt thus suppressing additional evaporation and reducing the exhaust fume scrubber load.

Solvent evaporation from the melt is also controlled in other ways.

The rate of melt evaporation depends only on the surface area, not the volume, so a crucible such as in FIG. 26B with an aspect ratio of height: diameter of greater than 1.25 is preferred. This also allows a smaller diameter furnace, which is easier to control. The aspect ratio also governs the melt volume since a tall narrow crucible holds less material, so this is balanced. A taller crucible increases the distance to the nutrient. This can be helpful in preventing convection from elevating PZT particles from the bottom to the surface, but can also reduce diffusion of nutrient through a longer path length. The liquid phase transport method does not require as large a melt as other methods where the melt can be depleted of nutrient.

PbO evaporation is inversely dependent on the oxygen partial pressure above the melt. Therefore, means that increase the oxygen partial pressure include use of higher oxygen partial pressure mixed with air, nitrogen, argon or helium, a carbon dioxide atmosphere, and growth inside a pressure vessel. Each of these has hazards.

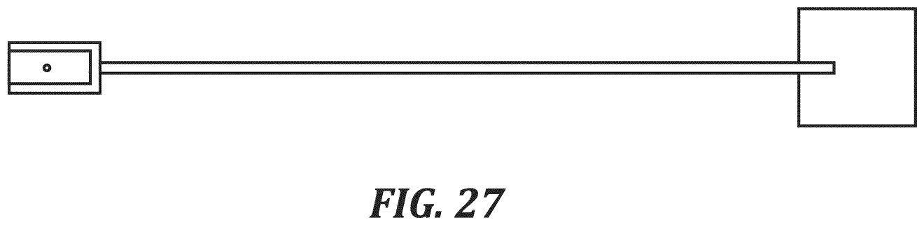

The solvent vapors such as lead oxide, lead phosphate, and lithium phosphate are corrosive, notably to aluminum oxide (alumina). It is therefore beneficial to construct a longer platinum-5% gold paddle that attaches to an alumina stirring rod higher in the furnace where the vapor pressure of solvent is lower. Such a paddle is shown in FIG. 27 with a welded cup to attach to the alumina rod with a platinum-gold wire pin.

### Alternative Crystal Growth Methods

### Traveling Heater Method

In another aspect, the present disclosure provides a method of growing a PbZr_{X}Ti₍₁₋ₓ₎O₃ crystal from the system by the traveling heater method. In an embodiment, the method comprises:
a. mixing powdered constituents comprising concentrations of free lead oxide [PbO]_{free}, zirconium oxide [ZrO₂], titanium oxide [TiO₂] and boron oxide [B₂O₃] for a high temperature solution in thermodynamic equilibrium having a saturation temperature T_{S} of lead zirconate titanate (PZT) PbZr_{X}Ti_{(1-X)}O₃ wherein T_{S} is according to T_{S}=A−B[PbO]_{free}+ (C[ZrO₂]+D[TiO₂]) (1−E[[BO₃³⁺]) wherein A=997±50° C., B=360±100° C., C=29100'5000° C., D=1423±500° C. and E=3.6±1 and [BO₃³⁺] is boron oxide complexed with additional oxygen. In an embodiment, the system has a ratio X_{L}=[ZrO₂]/([TiO₂]+[ZrO₂]) in the high-temperature solution is in a range of 0.06 and 0.15,
b. compressing the powdered constituents into a charge comprising a diameter of a crucible;
c. providing a nutrient charge of composition PbZr_{X}Ti₍₁₋₎O₃ in the diameter of the crucible by ceramic methods or mixing and pressing;
d. placing a seed on a bottom of the crucible;
e. placing the powdered solution constituents on top of the seed;
f. placing nutrient constituents on top of the solution constituents;
g. placing the crucible in a vertical furnace such that a solution zone is at an average temperature of T_{S} and there is a positive temperature gradient between the seed and the nutrient;
h. moving the crucible and/or the furnace to move a hot zone upward at the crystal growth rate; and
i. when the solvent zone reaches the top, slowly cooling the system to room temperature.

The traveling heater or traveling solvent method was adapted from zone melting by adding a solution growth element. The movement of a solvent zone from a seed through a solid source material is induced by a thermal gradient as in the liquid phase transport method described above. The molten zone is moved by slow movement of either the heater or the crucible. In this way, it is similar to the Bridgman method and is sometimes called solvent Bridgman. A typical configuration comprises a seed at the bottom of a crucible, a saturated solvent zone according to the claims, which is then capped by compressed polycrystalline source material. The solvent dissolves the source material at its hot upper interface and deposits a PZT crystal of essentially the same composition at the cooler lower growing crystal interface under near equilibrium conditions. The temperature gradient is created by the movement of the heater and crucible with respect to each other. Nutrient transport from the source to the growing crystal occurs by convection and diffusion in a convection stirred melt region in the solvent zone under the influence of the temperature gradient.

Adapting this method to the current application is a very natural extension and offers the possibility of large-scale crystal growth. A platinum Bridgman crucible provides a well for location of a seed.

A solvent zone would consist of an equilibrium solution composition according to the claims. It could be pre-melted and quenched or formed by ceramic means of mixing, pressing, and sintering to be compact and shaped to the crucible bottom.

The large bulk of nutrient PZT material would be made by ceramic means as is well known to those knowledgeable in the art and formed or machined to the diameter of the Bridgman crucible, then placed on top of the solution material.

The resulting charge is then sealed or placed in an atmosphere in a Bridgman or traveling heater furnace to accomplish crystal growth according to the method described above. This method also has the advantage that the melt is not exposed to the environment during growth and therefore is not subject to solvent evaporation.

### Traveling Sol Vent Floating Zone

In an aspect, the present disclosure provides a method of growing a PbZr_{X}Ti_{(1-X)}O₃ crystal by the traveling solvent floating zone method with no crucible. In an embodiment, the method comprises:
a. assembling a charge comprising in consecutive layers:
   i. a PbZr_{X}Ti₍₁₋ₓ₎O₃seed,
   ii. a solution mixture comprising powdered constituents comprising concentrations of free lead oxide [PbO]_{free}, zirconium oxide [ZrO₂], titanium oxide [TiO₂] and boron oxide [B₂O₃] for a high temperature solution in thermodynamic equilibrium having a saturation temperature Ts of lead zirconate titanate (PZT) PbZr_{X}Ti_{(1-X)}O₃ wherein T_{S} is according to T_{S}=A−B[PbO]_{free}+ (C[ZrO₂]+D[TiO₂]) (1−E[B₂O₃]) wherein A=997±50° C., B=360±100° C., C=29100±5000° C., D=1423±500° C. and [BO₃³⁺]) wherein A=997±50° C., B=360±100° C., C=29100±5000° C., D =1423±500° C. and E=3.6±1 and [BO₃³⁺] is boron oxide complexed with additional oxygen., and
   iii. PbZr_{X}Ti_{(1-X)}O₃ nutrient;
b. pressing the charge to form a singular body;
c. placing the charge in a floating zone furnace;
d. pressurizing a chamber of the floating zone furnace;
e. applying, with the floating zone furnace, optical heating such that the solution is at an average temperature of T_{S} and there is a positive temperature gradient between the seed and the nutrient;
f. moving the charge or the heating to move a hot zone at the crystal growth rate to grow the crystal;
g. when the solvent zone reaches a limit of the system, slowly reducing the heating to cool the system to room temperature; and
h. cutting the crystal from a remaining portion of the charge.

The traveling solvent float zone (TSFZ) technique is a crucible-less equivalent of the traveling solvent or traveling heater methods and circumvents the problems resulting from the use of crucibles. A small solvent disc of different composition is melted between vertical cylindrical feed and seed rods, which have the same composition as the crystal. The molten zone is physically stable because the solvent is supported against gravity by the surface tension of the liquid and chemically stable because the solidification of the crystal from the molten zone is balanced by nutrient feed rod material from above. A single crystal can be nucleated by a single-crystalline seed crystal in the lower region. The hot zone is supplied by optical means, commonly diode lasers or focused infrared light radiation from halogen/xenon lamps. A significant feature is the ability to grow under reactive oxidizing and high pressure atmospheres such as oxygen or carbon dioxide that are hazardous in a system that is open to the air. This will significantly suppress lead oxide evaporation. High pressure can also be applied to reduce evaporation further.

A charge is typically made by ceramic means, compressing together the seed, solution region, and nutrient. This is then placed in the furnace, sealed, an atmosphere is supplied, and heating is applied to create and move the hot zone.

In an embodiment, the present disclosure provides a method of growing a PbZr_{X}Ti_{(1-X)}O₃ crystal, wherein the charge is compressed after mixing.

To ensure that all the constituents fit in the melt without needing to melt multiple batches and to create high density nutrient sources, compression structures and methods may be used. Examples of such structures and methods include:
1. Cold Isostatic Pressing. Place all the mixed powders in a rubber bag and knot at the top. Place in a cold isostatic press and press to 100 MPa by the “wet bag” process under hydrostatic pressure. Remove and clean the exterior of the rubber bag. Cut the knot off the bag and remove all the contents.
2. Uniaxial pressing in a die. Place all the mixed powders inside a die in a die press with the bottom anvil in place. Place a top anvil and a piston on top. Place in a uniaxial die press and apply pressure to the limit of the press and die. Press out the disc thus created.
3. Creating a ceramic by conventional ceramic means involving mechanical mixing, pressing, and sintering.

In an embodiment, the present disclosure provides a method of growing a PbZr_{X}Ti_{(1-X)}O₃ crystal, wherein the seed comprises platinum, a platinum alloy, gold, a gold alloy, a perovskite comprising an average lattice parameter of 4.07±0.01 at room temperature, or PbZr_{X}Ti₍₁₋ₓ₎O₃ wherein X is the same as in claim 1 within ±0.1.

The use of a lattice matched seed and the virtues of platinum or gold as a nucleation site are discussed above.

In an embodiment, the present disclosure provides a method of growing a PbZr_{X}Ti₍₁₋ₓ₎O₃ crystal, wherein the seed comprises PbZr_{X}Ti₍₁₋ₓ₎O₃, wherein X in the seed is the same as the value X of the crystal to be grown to within ±0.1, and wherein the seed comprises a <100> orientation parallel to the surface of the liquid.

The best growth occurs by full homoepitaxy from a crystal seed of the same material as will be grown. The <100> directions are the facet directions of the crystal and so are slowest growing. This is helpful in trying to introduce step-flow growth and reduce inclusions.

This is also a useful orientation for devices. A crystal grown in this orientation maximizes the useful crystal, whereas the fast growing <111> direction often involves cutting the crystal at a severe angle to the grown shape with a large amount of waste.

In an embodiment, the present disclosure provides a method of growing a PbZr_{X}Ti₍₁₋ₓ₎O₃ crystal, wherein the crystal is grown in an atmosphere comprising air, oxygen, carbon dioxide, mixtures thereof, or a mixture of oxygen with an inert gas comprising nitrogen, helium, or argon, wherein a partial pressure of oxygen in the atmosphere is greater than a partial pressure of oxygen in air.

In an embodiment, the present disclosure provides a method of growing a PbZr_{X}Ti₍₁₋ₓ₎O₃ crystal, wherein the crystal is grown in an atmosphere comprising a pressure greater than one bar.

The vapor pressure of PbO above the melt is inversely proportional to the oxygen partial pressure. This can, of course, be varied by using a pure oxygen atmosphere, but that can tend to result in a potentially explosive environment if any fuel is present.

Carbon dioxide is also more oxidizing than air and not explosive. However, it is hazardous if exhausted into the laboratory. Mixtures of oxygen with inert gases may also be used.

The traveling solvent float zone method is particularly amenable to atmospheric control including elevated pressure.

### Crystal Doping

In an embodiment, the present disclosure provides a method of growing a PbZr_{X}Ti_{(1-X)}O₃ crystal, wherein a dopant is incorporated into the solution and the crystal.

In an embodiment, the present disclosure provides a method of growing a PbZr_{X}Ti₍₁₋ₓ₎O₃ crystal, wherein the dopant is selected from iron, manganese, niobium, or a rare earth.

PZT is a ferroelectric perovskite, whose properties can be altered by doping with ions of different valence from the base Pb²⁺(ZrTi)⁴⁺O₃ lattice.

“Soft” PZT can be doped with donor dopants: La³⁺ and other rare earths for Pb²⁺ or Nb⁵⁺ for Ti⁴⁺/Zr⁴⁺. A donor dopant is one that has a higher valence than the ion it is replacing so it can donate an electron unless it is suitably compensated by a cation vacancy. Donor dopants create lead vacancies and are used to make soft PZT.

“Hard” PZT is typically doped with an acceptor dopant of lower valence such as Fe or Mn (potentially multi-valent, e.g. Fe³⁺+Fe²⁺) substituting for Ti⁴⁺/Zr⁴⁺ so it can accept an electron unless it is compensated by an oxygen vacancy. The literature shows that the tetragonal distortion embodied in the ratio between the lattice parameters c/a determined by x-ray diffraction is a significant indicator of Fe or Mn substitution. Mn substitution has a c/a versus concentration slope of −0.156. Fe has a c/a versus concentration slope of −0.270 near the origin, but there is a change in effect with higher concentrations, which are typically considered above the solubility limit.

While PZT crystals in the present disclosure have been developed as undoped, initial doping experiments were carried out.

The melt was doped with Fe/(Zr+Ti) fractions of 0.003, 0.007 and 0.010 and crystals were grown, which were then characterized by powder x-ray diffraction. After extensive review of the resulting crystal structure data, the following results were determined.

Fe goes into the crystal mixed valence as Fe³⁺/Fe²⁺ in approximately equal proportions. This is as would be expected from the iron oxide thermodynamics and phase diagram. As a result, the average ionic size of Fe substituents is 0.8525 Å, which is very close to the ionic size of Zr⁴⁺ 0.86 Å.

Fe substitutes preferentially for Ti rather than Zr. This is logical since Zr has a higher distribution coefficient, is more refractory and is hard to compete with thermodynamically.

The combination of these effects is that Fe has the same effect on the crystal structure as adding more Zr, including moving the tetragonal-rhombohedral phase boundary and changing c/a. These results are not found in the literature and represent a new understanding. This has allowed determination of the Fe concentration in the crystal from the difference between the expected crystal structure (lattice parameters c, a, and their ratio) based on the known Zr distribution coefficient and the observed crystal structure.

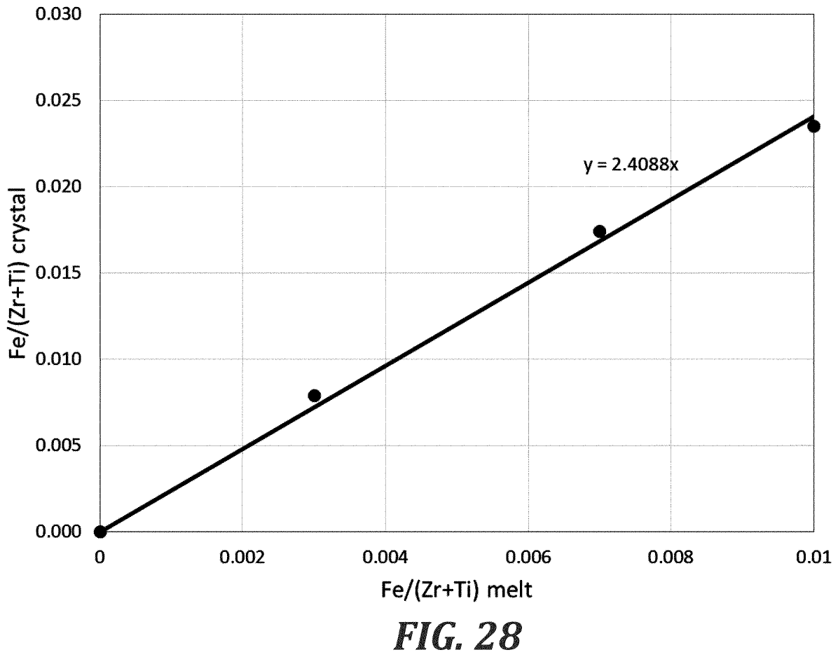

The thus calculated Fe concentration in the crystal is plotted for the three different melt doping levels in FIG. 28. The results are surprisingly uniform with a distribution coefficient of 2.4. If calculated only from the Ti concentration in the film versus the melt, the distribution coefficient closer to 4, which is quite high and similar to the distribution coefficient of Zr versus Ti.

This strong effect of iron doping is cautionary in that any iron impurity in the melt will cause the crystal to deviate significantly in structure and properties.

Therefore, growth of doped crystals from solution is more problematic than preparing doped ceramic. A doped ceramic may be made with a specific and uniform dopant concentration by careful weighing, mechanical mixing, and grinding using the usual ceramic preparation techniques. The high distribution coefficient of dopant in melt growth results in rapid melt depletion and variation of the doping level through the crystal. Because of the strong effect of doping, this can result in a crystal with extremely non-uniform properties.

However, this problem can be solved by using the two-phase solution approach since the dopant will be preferentially segregated in the solid nutrient phase with a much lower relative concentration in the liquid and will be released steadily as the melt is depleted by growth of the crystal. This approach will give a uniform crystal composition.

### Devices and Applications

In another aspect, a piezoelectric device is provided, comprising a PZT single crystal, such as formed according to the disclosed methods. Such piezoelectric devices include a transducer, a receiver, a sensor, and an actuator.

A specific system is provided for characterizing pipelines through in-line inspection comprising a PZT piezoelectric device that is a transducer and/or a receiver. In one embodiment, the pipeline is configured to transport a substance selected from the group consisting of a liquid and a gas.

Ultrasonic based in-line inspection (ILI) tools, sometimes called “smart pigs” are commercially available for use in liquid pipelines for both wall thickness measurement and crack detection. These tools can operate in tethered or free-flowing mode. They characterize the pipe wall by interrogating it with an ultrasonic signal that is coupled through the pipeline liquid and receiving the reflected signals from the inner and outer pipe walls.

However, in gas pipelines impedance matching of acoustic signals to gas or air at both the transducer-gas and gas-pipe interfaces is poor with a 150,000:1 difference between the impedances of steel and gas. Without a liquid couplant, it is difficult to impossible to receive a measurable signal from the back wall of the pipe or a crack tip in the pipe with current technology. The industry need to measure wall thickness accurately and eventually to detect cracks in gas pipelines is well known.

For several decades the material of choice for a wide variety of transducer applications has been lead zirconate titanate (PZT) polycrystalline ceramic of composition near the morphotropic phase boundary. However, ceramics are inherently non-uniform in crystallographic orientation resulting in significantly reduced coupling factors k₃₃.

Single crystal piezoelectric materials are more efficient than ceramics by a factor of three by virtue of being coherent and directional. First generation piezoelectric single crystals have been made from binary solid solution relaxor-PT ferroelectric compositions such as (1-x)Pb(Mg_{1/3}Nb_{2/3})O₃₋ₓPbTiO₃ (PMN-PT or PMNT). These offer high performance with ultra-high electromechanical coupling factors k₃₃>0.9 and improved bandwidths. However, these materials are limited in temperature and acoustic power by a much lower operating temperature range compared to PZT. The dielectric losses of PMN-PT crystals are reported to be on the order of ≤0.4%, similar to the values observed in “hard” PZT based piezoelectrics, however, their mechanical quality factors Q are found to be less than 100, similar to “soft” PZT ceramics. Furthermore, the low coercive field (Ec) of PMN-PT crystals, being only 2-3 kV/cm, restricts their use to low ac voltage applications or devices requiring a “biased” drive level. In ceramics, coercivity can be supplied by grain boundaries, but in defect-free single crystals, it is an intrinsic property of the material.

Single crystal PZT systems with high operating temperatures, high piezoelectric coefficients, high electromechanical coupling factors, and improved coercivities are therefore a major step forward for transducer applications. Single crystal PZT has been realized to date only in limited and non-commercial sizes, quality, and composition. PZT crystals would be uniquely well suited to small dimensional arrays promoting increased miniaturization. It has been demonstrated that miniaturizing array-based transducers reduces artifacts, known as side-lobes, due to inherent aberrations in the acoustic field. This is proposed as an enabling technology for higher power array transducers and higher sensitivity receivers to increase the return signal from the back wall of the pipeline.

The envisaged transducers use lower drive voltages for equivalent signal levels in transduction and can be more sensitive as receivers. Lower drive voltages also mean smaller and lower power electrical components can be used. Improved miniaturization of transducers will be enabled for high density in-line inspection (ILI) tools. Likewise increased miniaturization of electronics will allow both smaller tools for the same number of transducers and higher density tools with the same tool size.

### EXAMPLES

### Comparative Example 1

(R. Clarke and R. W. Whatmore, “The Growth and Characterization of PbZr_{X}Ti_{1-X}O₃ Single Crystals,” J. Cryst. Growth 33:29 (1976))

The charge compositions were as given in TABLE III. 50 g charges of PbO, TiO₂, and ZrO₂ powders were made up and loaded in 30 ml platinum crucibles. The crucibles were sealed with sheet platinum by crimping the edges. The crucible was placed inside an alumina crucible inside a muffle furnace. The charges were heated to 1170° C. and then slow cooled to 950° C. at 3° C. per hour. Loss of PbO was up to 3 g.

The crucible was inverted to decant the flux. The crystals were removed from the residual flux by cleaning in 50% nitric acid-50% water.

Crystal compositions X were as given in TABLE III.

### Comparative Example 2

(Y. Xie, “Synthesis and Characterization of Piezo-ferroelectric Lead Zirconate-Titanate (PZT) Single Crystals and Related Ternary Ceramics,” Ph.D. thesis, Simon Fraser University, 2013)

Top-seeded solution growth was used for growth of PZT single crystals with a PbO/B₂O₃ flux with a molar ratio of 1:4. The addition of B₂O₃ was used to decrease the melting point and prevent the high evaporation of PbO at high temperature by increasing the viscosity of the solution but the B₃+ion is too small to enter the unit cell lattice of PZT. PbZr_{X}Ti₁₋ₓO₃ ceramics with composition X=0:40 were pre-synthesized by mixing and pressing into pellets followed by calcination at 800° C. for 4 hours to form the perovskite phase. The pellets were put into a 100 ml platinum crucible together with the flux powders in a ratio of 1:6 for the most successful run. The mixture was soaked for five days at 1075° C. (5° C. higher than the seeding temperature), which gradually dissolved the PZT solute at bottom and saturation was reached at that temperature. The temperature was lowered 5° C. to the growth temperature 1070° C. to supersaturate the melt. The melt was seeded with a (001)-oriented PZT crystal from a previous growth run attached to an alumina rod with platinum wire. The melt was slow cooled at a rate of 5° C./day to 1000° C. Then the crystal was withdrawn from the melt and the furnace cooled at 20° C./day to avoid cracking of the crystal.

A crystal prepared this way had a composition of X=0.54, which was determined to be the MPB contrary to other literature values. The largest crystal obtained in this study was 8×3×4 mm.

### Comparative Example 3

(J. A. Pérez de la Torre, “Obtaining and characterization of single crystals and ceramics of PZT,” Ph.D. thesis, Universidade de Aveiro, Departamento de Engenharia Cerâmica e do Vidro (2009))

Small PZT single crystals of composition Pb (Zr_{0.525}Ti_{0.475})O₃ in the MPB region were grown using the high-temperature self-flux solution method.

PZT powders were prepared using the reagents PbCO₃, TiO₂, and ZrO₂. The powders were mixed for 3 h in a planetary ball mill, in Teflon™ jars with alcohol medium and zirconia balls, then dried at 120° C. for 24 hours, calcined at 900° C. for 2 hours, and ground in an agate mortar.

The calcined powders were then ground for 16 h and dried again at 120° C. for 24 h. The flux PbO—KF—PbCl₂, in molar ratio of (2:1:2), was then added in varying amounts to the PZT. The powders were mixed for 3 hours in a planetary ball mill in Teflon™ jars, with alcohol medium and zirconia balls then dried at 120° C. for 24 hours. This flux has a melting point around 650° C. 4 wt % of B₂O₃ was added to lower the melting point resulting in a more stable flux with crystals nucleating in an optimum homogeneous and viscous medium.

20 g of 60-35% PZT and 40-65% flux were mixed and placed in a 50 ml platinum crucible covered by a larger alumina crucible sealed with alumina cement to minimize the evaporation of lead oxide. The crucible was placed in a vertical tube furnace with a low vertical temperature gradient,

The furnace was ramped at 120° C. per hour to 1050° C., held for 5 hours, ramped to 950° C. at 10° C./hour and cooled to room temperature at 120° C./hour. The weight loss was 18-22%.

The PZT single crystals were separated from the flux by heating up to ~1000° C. with the crucible inverted over an alumina crucible to decant the melt. The crystals and residual flux were removed mechanically from the crucible, cleaned in hot nitric acid for 6 hours, leached in hot water for 24 hours to dissolve the nitric salt and then annealed at 750° C. for 1 hour.

The grown crystals were up to 3×3×3 mm in dimensions.

### Example 1

Top seeded solution growth with supercooling and slow cooling on a PZT seed from a single-phase PbO—PLP melt.

Calculate a single-phase charge composition by determining the equilibrium liquid composition for growth of a PZT crystal of desired X at a saturation temperature Ts from a given solvent according to the phase diagram.

This melt was comprised of 3.087 g of ZrO₂, 21.001 g of TiO₂ 243.84 g of PbO and 482.42 g of PbLiPO₄ (PLP purchased in pre-reacted form), to form a solution comprising PZT and solvent with a calculated saturation temperature of 1113° C. and a calculated X=0.52.

Weigh and combine the powders in a Teflon™ jar. Add methanol medium and zirconia balls. Cover with a lid and mix for 3 hours in a planetary ball mill. Dry the resultant mixture for 24 hours at 120° C. to remove all the solvent. Remove the zirconia balls. Place all the mixed powders in a rubber bag and knot at the top. Place in a cold isostatic press and press to 100 MPa by the “wet bag” process under hydrostatic pressure. Remove and clean the exterior of the rubber bag. Cut the knot off the bag and remove all the contents to a platinum-5% gold crucible 75 mm in diameter by 100 mm in height comprising a volume of 440 ml. Place the crucible in a vertical tube furnace and cover with a baffle system.

Heat the furnace rapidly to 1193° C., which is 80° C. above the saturation temperature. Thread a platinum-sheathed thermocouple through the keyholes in the baffles and insert in the melt at the side of the crucible to monitor the melt temperature. When the melt is liquid, insert a platinum paddle attached to an alumina rod into a chuck in the lift/rotation system and lower into the furnace until just above the melt. Preheat the paddle above the melt for 15 minutes, initiate rotation, and lower it until immersed in the melt to the desired depth. Stir and equilibrate the melt at the equilibration temperature for 24 hours to put all the constituents in solution. Cool the melt at a rate of 35° C./hour for two hours and the final 10° C. at 10° C./hour to reach the starting growth temperature of 1113° C. Remove the paddle.

Attach a PZT seed grown and fabricated previously to an alumina rod with platinum wire and lower to 1 cm above the surface. Hold for 15 minutes to equilibrate thermally. Lower the seed until it touches the sample surface, then lift 1 mm to form a meniscus. Begin rotating the seed at 40 rpm, reversing direction every rotation. Begin cooling the furnace with a ramp of 0.1° C./hour for 50 hours, then reduce the ramp to 0.04° C./hour for 300 hours. The resultant melt temperature decreased by 17° C.

Terminate the growth run by lifting the crystal above the melt by 2 cm and allowing any residual solution to drip off over a period of 1 hour. Shut off the furnace and allow to cool for 24 hours until the furnace temperature is below 50° C. Raise the crystal slowly to ambient with the lift over a period of 1 hour.

Clean the crystal in a stirred heated mixture of 50% nitric acid, 5% acetic acid and 45% water for 1 hour, remove and rinse, brush lightly with an acid brush with the bristles cut short, and return to the acid for 1 hour more. Remove and clean further in hot water for 1 hour more. A crystal of 3.66 g was grown. The cooled melt was extracted from the furnace and weighed. 20.54 g of solvent had evaporated. To prepare for the next run, these amounts were replenished.

Orient and cut the crystal. The scrap was ground to a powder and the composition was determined by lattice parameters in an XRD system. The resultant composition was X=0.517-0.522.

### Example 2

### Multiple Dipping

The system of EXAMPLE 1 can be used to achieve a larger crystal by re-dipping a previously grown crystal while still on the same supporting wire. The amount of removed crystal from the previous run and evaporated solvent are calculated and added back to the melt, which is then brought to the equilibration temperature and stirred for 16 hours to place all the constituents in solution. The cleaned crystal from the previous run is then used to replace the seed and dipped according to EXAMPLE 1. This was repeated three times to achieve a crystal weighing 10.63 g as pictured in FIG. 20D. The largest crystal achieved by this repeated dipping method was 17 g and more than 2,000 cubic mm in volume.

### Example 3

Top seeded solution growth from a two-phase PbO—Pb₄P melt with a platinum wire seed.

Construct a furnace so there is a gradient of 8° C. between the top and bottom of a melt that is placed therein. The average temperature should be measured by a platinum sheathed thermocouple inserted in the furnace.

Calculate a two-phase charge composition by determining the equilibrium liquid composition for growth of a PZT crystal of desired X at a saturation temperature Ts from a PbO—Pb₄P solvent according to the phase diagram and adding PbO, ZrO₂ and TiO₂ nutrients sufficient to make crystal PZT of an additional quantity.

This melt was comprised of 5.427 g of ZrO₂, 16.585 g of TiO₂, 647.65 g of PbO, and 122.44 g of ammonium dihydrogen phosphate (ADP), which will react with lead oxide to form Pb₂P₂O₇ and evolve ammonia and water. This formed a two-phase system comprising solid PZT and a liquid solution.

Weigh and combine the powders in a Teflon™ jar. Add methanol medium and zirconia balls. Cover with a lid and mix for 3 hours in a planetary ball mill. Dry the resultant mixture for 24 hours at 120° C. to remove all the solvent. Remove the zirconia balls. Place all the mixed powders in a rubber bag and knot at the top. Place in a cold isostatic press and press to 100 MPa by the “wet bag” process under hydrostatic pressure. Remove and clean the exterior of the rubber bag. Cut the knot off the bag and remove all the contents to a platinum-5% gold crucible 75 mm in diameter by 100 mm in height comprising a volume of 440 ml. Place the crucible in a vertical tube furnace and cover with a baffle system.

Heat the furnace rapidly to 1063° C. Thread a platinum-sheathed thermocouple through the keyholes in the baffles and insert in the melt at the side of the crucible to monitor the melt temperature. When the melt is liquid, insert a platinum paddle attached to an alumina rod into a chuck in the lift/rotation system and lower into the furnace until just above the melt. Preheat the paddle above the melt for 15 minutes, initiate rotation, and lower it until immersed in the melt to the desired depth. Stir and equilibrate the melt at the equilibration temperature for 24 hours to reach a thermodynamic equilibrium between the liquid and solid nutrient at the bottom of the crucible. Remove the paddle.

Fabricate a piece of platinum wire with a sharp tip to seed the melt and attach it to the end of an alumina rod. Place the rod in the chuck of the lift/rotation system and lower to 1 cm above the surface. Hold for 15 minutes to equilibrate thermally. Lower the wire until it touches the melt surface, then lift to form a meniscus to within 0.2 mm of separation. Repeated contact/separation may be used to determine this point accurately. Begin rotating the seed at 40 rpm unidirectionally as the reversal step of bidirectional motion can break the small meniscus. A seed crystal will start to form by isothermal transport of nutrient material from the bottom of the crucible to the surface. Over the next day, manually pull the formed seed crystal upward progressively at 6 to 8-hour intervals as it grows downward from the end of the wire to get within 0.2 mm of separation each time to reduce the number of nuclei orientations to 1-2. Stop lifting at this point, start bidirectional rotation, and allow the crystal to grow at this height for three days to spread in diameter. Then lower the crystal downward into the melt at a rate of 0.3 mm/day until the height is 2 mm below the initial melt contact point. Hold the crystal at this point for one day. Then lift the crystal until the seed separates and re-lower it so it just touches the melt. Grow the crystal at this point for 227 hours at constant average temperature of 1063° C. to within ±3° C. during the growing period.

Terminate the growth run by lifting the crystal above the melt by 2 cm and allowing any residual solution to drip off over a period of 1 hour. Shut off the furnace and allow to cool for 24 hours until the furnace temperature is below 50° C. Raise the crystal slowly to ambient with the lift over a period of 1 hour.

Clean the crystal in a stirred heated mixture of 50% nitric acid, 5% acetic acid and 45% water for 1 hour, remove and rinse, brush lightly with an acid brush with the bristles cut short, and return to the acid for 1 hour more. Remove and clean further in hot water for 1 hour more. A crystal of 3.43 g was grown. The cooled melt was extracted from the furnace and weighed. 7.20 g of solvent had evaporated. To prepare for the next run, these amounts were replenished.

Orient and cut the crystal. The scrap was ground to a powder and the composition was determined by lattice parameters in an XRD system. The resultant composition was X=0.523. The crystal is pictured in FIG. 21c.

### Example 4

Top seeded solution growth from a two-phase PbO—B₂O₃ melt with a platinum wire seed.

Construct a furnace so there is a gradient of 8° C. between the top and bottom of a melt that is placed therein. The average temperature should be measured by a platinum sheathed thermocouple inserted in the furnace.

Calculate a two-phase charge composition by determining the equilibrium liquid composition for growth of a PZT crystal of desired X at a saturation temperature Ts from a PbO—B₂O₃ solvent according to the phase diagram and adding PbO, ZrO₂ and TiO₂ nutrients sufficient to make crystal PZT of an additional quantity.

This melt was comprised of 29.94 g of ZrO₂, 47.428 g of TiO₂, 959.94 g of PbO, and 10.287 g of B₂O₃ (in large glassy chunks), to form a two-phase system comprising solid PZT and a liquid solution.

Weigh and combine the powder chemicals (excluding the B₂O₃) in a Teflon™ jar. Add methanol medium and zirconia balls. Cover with a lid and mix for 3 hours in a planetary ball mill. Dry the resultant mixture for 24 hours at 120° C. to remove all the solvent. Remove the zirconia balls. Place all the mixed powders in a rubber bag and knot at the top. Place in a cold isostatic press and press to 100 MPa by the “wet bag” process under hydrostatic pressure. Remove and clean the exterior of the rubber bag. Cut the knot off the bag and remove all the contents and the B₂O₃ to a platinum-5% gold crucible 75 mm in diameter by 100 mm in height. Place the crucible in a vertical tube furnace and cover with a baffle system.

Heat the furnace rapidly to 1071° C. Thread a platinum-sheathed thermocouple through the keyholes in the baffles and insert in the melt at the side of the crucible to monitor the melt temperature. When the melt is liquid, insert a platinum paddle attached to an alumina rod into a chuck in the lift/rotation system and lower into the furnace until just above the melt. Preheat the paddle above the melt for 15 minutes, initiate rotation, and lower it until immersed in the melt to the desired depth. Stir and equilibrate the melt at the equilibration temperature for 24 hours to reach a thermodynamic equilibrium between the liquid and solid nutrient at the bottom of the crucible. Remove the paddle.

Fabricate a piece of platinum wire with a sharp tip to seed the melt and attach it to the end of an alumina rod. Place the rod in the chuck of the lift/rotation system and lower to 1 cm above the surface. Hold for 15 minutes to equilibrate thermally. Lower the wire until it touches the melt surface, then lift to form a meniscus to within 0.2 mm of separation. Begin rotating the seed at 40 rpm unidirectionally as the reversal step of bidirectional motion can break the small meniscus. A seed crystal will start to form by isothermal transport of nutrient material from the bottom of the crucible to the surface. Over the next day, manually pull the formed seed crystal upward progressively at 6 to 8-hour intervals as it grows downward from the end of the wire to get within 0.2 mm of separation each time to reduce the number of nuclei orientations to 1-2. Stop lifting at this point, start bidirectional rotation, and allow the crystal to grow at this height for three days to spread in diameter. Then lower the crystal downward into the melt at a rate of 0.3 mm/day until the height is 2 mm below the initial melt contact point. Hold the crystal at this point for one day. Then lift the crystal until the seed separates and re-lower it to just touch the melt. Grow the crystal at this point for 216 hours at constant average temperature of 1071° C. to within ±3° C. during the growing period.

Terminate the growth run by lifting the crystal above the melt by 2 cm and allowing any residual solution to drip off over a period of 1 hour. Shut off the furnace and allow to cool for 24 hours until the furnace temperature is below 50° C. Raise the crystal slowly to ambient with the lift over a period of 1 hour.

Clean the crystal in a stirred heated mixture of 50% nitric acid, 5% acetic acid and 45% water for 1 hour, remove and rinse, brush lightly with an acid brush with the bristles cut short, and return to the acid for 1 hour more. Remove and clean further in hot water for 1 hour more. A crystal of 7.76 g was grown. The cooled melt was extracted from the furnace and weighed. 7.89 g of solvent had evaporated. To prepare for the next run, these amounts were replenished.

Orient and cut the crystal. The scrap was ground to a powder and the composition was determined by lattice parameters in an XRD system. The resultant composition was X=0.526.

### Example 5

Top seeded solution growth from a two-phase PbO—Li₂O melt with a platinum wire seed.

Construct a furnace so there is a gradient of 5° C. between the top and bottom of a melt that is placed therein. The average temperature should be measured by a platinum sheathed thermocouple inserted in the furnace.

Calculate a two-phase charge composition by determining the equilibrium liquid composition for growth of a PZT crystal of desired X at a saturation temperature Ts from a PbO—Li₂O solvent according to the phase diagram and adding PbO, ZrO₂ and TiO₂ nutrients sufficient to make crystal PZT of an additional quantity.

This melt was calculated to be comprised of 7.017 g of ZrO₂, 29.114 g of TiO₂, 710.98 g of PbO, and 7.010 g of Li₂(CO₃) (which will decompose to form LizO and evolve carbon dioxide) to form a two-phase system comprising solid PZT and a liquid solution.

Weigh and combine the powder chemicals in a Teflon™ jar. Add methanol medium and zirconia balls. Cover with a lid and mix for 3 hours in a planetary ball mill. Dry the resultant mixture for 24 hours at 120° C. to remove all the solvent. Remove the zirconia balls. Place all the mixed powders in a rubber bag and knot at the top. Place in a cold isostatic press and press to 100 MPa by the “wet bag” process under hydrostatic pressure. Remove and clean the exterior of the rubber bag. Cut the knot off the bag and remove all the contents to a platinum-5% gold crucible 75 mm in diameter by 100 mm in height. Place the crucible in a vertical tube furnace and cover with a baffle system.

Heat the furnace rapidly to 1068° C. Thread a platinum-sheathed thermocouple through the keyholes in the baffles and insert in the melt at the side of the crucible to monitor the melt temperature. When the melt is liquid, insert a platinum paddle attached to an alumina rod into a chuck in the lift/rotation system and lower into the furnace until just above the melt. Preheat the paddle above the melt for 15 minutes, initiate rotation, and lower it until immersed in the melt to the desired depth. Stir and equilibrate the melt at the equilibration temperature for 24 hours to reach a thermodynamic equilibrium between the liquid and solid nutrient at the bottom of the crucible. Remove the paddle.

Fabricate a piece of platinum wire with a sharp tip to seed the melt and attach it to the end of an alumina rod. Place the rod in the chuck of the lift/rotation system and lower to 1 cm above the surface. Hold for 15 minutes to equilibrate thermally. Lower the wire until it touches the melt surface then lift to form a meniscus to within 0.2 mm of separation. Begin rotating the seed at 40 rpm unidirectionally as the reversal step of bidirectional motion can break the small meniscus. A seed crystal will start to form by isothermal transport of nutrient material from the bottom of the crucible to the surface. Over the next day, manually pull the formed seed crystal upward progressively at 6 to 8-hour intervals as it grows downward from the end of the wire to get within 0.2 mm of separation each time to reduce the number of nuclei orientations to 1-2. Stop lifting at this point, start bidirectional rotation and allow the crystal to grow at this height for three days to spread in diameter. Then lower the crystal downward into the melt at a rate of 0.3 mm/day until the height is 2 mm below the initial melt contact point. Hold the crystal at this point for one day. Then lift the crystal until the seed separates and re-lower it to just touch the melt. Grow the crystal at this point for 250 hours at constant average temperature of 1068° C. to within ±3° C. during the growing period.

Terminate the growth run by lifting the crystal above the melt by 2 cm and allowing any residual solution to drip off over a period of 1 hour. Shut off the furnace and allow to cool for 24 hours until the furnace temperature is below 50° C. Raise the crystal slowly to ambient with the lift over a period of 1 hour.

Clean the crystal in a stirred heated mixture of 50% nitric acid, 5% acetic acid and 45% water for 1 hour, remove and rinse, brush lightly with an acid brush with the bristles cut short, and return to the acid for 1 hour more. Remove and clean further in hot water for 1 hour more. Extract the cooled melt from the furnace and weigh to determine the amount of solvent evaporated. To prepare for the next run replenish the removed crystal and evaporated solvent.

Orient and cut the crystal. Grind the scrap to a powder and determine the composition by lattice parameters in an XRD system.

While illustrative embodiments have been illustrated and described, it will be appreciated that various changes can be made therein without departing from the spirit and scope of the invention.

1. (canceled)

2. A system comprising:
a solid comprising lead zirconate titanate (PZT) PbZr_{X}Ti₍₁₋ₓ₎O₃ in thermodynamic equilibrium with a high-temperature solution,
wherein
the high-temperature solution is in a state of saturation at a saturation temperature T_{S},
X in the solid is in a range of 0.30 and 0.65,
an average temperature of the high-temperature solution is constant to within ±3° C.,
a ratio X_{L}=[Zr]_{L}/([Ti]_{L}+[Zr]_{L}) in the high-temperature solution is in a range of 0.06 and 0.15,
the high-temperature solution comprises lead oxide, zirconium oxide (ZrO₂), and titanium oxide (TiO₂), and
the high-temperature solution does not comprise a fluoride or chloride constituent.

3. (canceled)

4. The system of claim 1, wherein a solvent composition of the high-temperature solution comprises lead oxide and a Lewis acid or Lewis base component selected from the group consisting of B₂O₃, P₂O₅, V₂O₅, MoO₃, Li₂O, Na₂O, K₂O, or a combination thereof.

5. (canceled)

6. The system of claim 4, wherein the solvent composition is selected from PbO, Pb₃O₄, PbO—B₂O₃, Pb₃O₄—B₂O₃, PbO—Li₂O, Pb₃O₄—Li₂O, PbO—Li₂O—B₂O₃, Pb₃O₄—Li₂O—B₂O₃, PbO—Li₂O—MoO₃, Pb₃O₄—Li₂O—MoO₃, PbO—Pb₂P₂O₇, and PbO—PbLiPO₄.

7. (canceled)

8. The system of claim 1, wherein the saturation temperature T_{S} is in a range of about 950° C. to about 1150° C.

9. The system of claim 1, wherein the system is contained in an inert crucible with low solubility in the high-temperature solution at the saturation temperature Ts.

10. (canceled)

11. The system of claim 1, wherein the PbZr_{X}Ti_{(1-X)}O₃ solid comprises a higher density than the high-temperature solution.

12. The system of claim 1, wherein the saturation temperature T_{S} is a function of [TiO₂]_{L}.

13. The system of claim 1, wherein the saturation temperature T_{S} is constant, wherein the solidus composition X in the solid PbZr_{X}Ti₍₁₋ₓ₎O₃ is a function of [TiO₂]_{L}.

14. (canceled)

15. A method of growing a PbZr_{X}Ti₍₁₋ₓ₎O₃ crystal from the system of claim 2 by isothermal liquid phase transport in a temperature gradient in the high-temperature solution, the method comprising:
a. mixing powders comprising the composition of the two-phase system of claim 2 to form a charge, wherein the composition comprises a sum of the solid comprising an amount of excess PbZr_{X}Ti₍₁₋ₓ₎O₃ components [ZrO₂]s, [TiO₂]s, and [PbO]ₛ in proportions to form a solid of composition PbZr_{X}Ti₍₁₋ₓ₎O₃ and a liquid composition that is in thermodynamic equilibrium with the solid at a temperature T_{S};
b. bringing the charge to equilibrium at T_{S} by:
i. heating the charge in a crucible in a vertical furnace to a temperature greater than the saturation temperature T_{S} of the entire charge including the excess PZT; mixing the fully melted system for a time sufficient to achieve thermodynamic equilibrium with all components in solution; and cooling with stirring to an average melt temperature of T_{S} to allow precipitation of the excess PZT to provide a melted two-phase system; or
ii. heating the charge in a crucible in a vertical furnace to an average melt temperature of T_{S} to provide a melted two-phase system; and mixing the melted two-phase system for a time sufficient to achieve thermodynamic equilibrium;
c. establishing a temperature gradient between the system and a growing region;
d. introducing a seed in the growing region;
e. holding the average temperature constant to within ±3° C. during a growing period to provide a grown crystal; and
f. separating the grown crystal from the liquid.

16. (canceled)

17. (canceled)

18. The method of growing a PbZr_{X}Ti₍₁₋ₓ₎O₃ crystal according to claim 15, wherein a temperature gradient between a nutrient solid phase and a growing crystal is less than 10° C.

19-23. (canceled)

24. The method of growing a PbZr_{X}Ti₍₁₋ₓ₎O₃ crystal according to claim 15, wherein the seed comprises platinum, a platinum alloy, gold, a gold alloy, a perovskite comprising an average lattice parameter of 4.07±0.01 at room temperature, or PbZr_{X}Ti₍₁₋ₓ₎O₃ wherein X is the same as in claim 1 within ±0.1.

25-27. (canceled)

28. The method of growing a PbZr_{X}Ti₍₁₋ₓ₎O₃ crystal according to claim 15, wherein a dopant is incorporated into the solution and the crystal.

29. The method of claim 28, wherein the dopant is selected from iron, manganese, niobium, or a rare earth.

30. The method of claim 15, wherein a resultant PbZr_{X}Ti₍₁₋ₓ₎O₃ single crystal of mass greater than 10 g.

31. The method of claim 30, wherein X is uniform within ±0.02.

32. A piezoelectric device comprising a PZT single crystal formed according to claim 15.

33. The piezoelectric device of claim 32, wherein the piezoelectric device is selected from the group consisting of a transducer, a receiver, a sensor, and an actuator.

34. The system of claim 4, where the Lewis acid or Lewis base is in a cation fraction range of 0 and 0.2.

35. The method of growing a PbZr_{X}Ti₍₁₋ₓ₎O₃ crystal according to claim 15 wherein a growth technique is selected from:
top seeded solution growth;
isothermal liquid phase transport in a temperature gradient in the high-temperature solution using a cold finger;
traveling heater method; and
traveling solvent floating zone method.
